(19) United States
(12) Patent Application Publication
(10) Pub. No.: US 2006/0094859 A1
(43) Pub. Date: May 4, 2006

(54) Class of bridged biphenylene polymers

(76) Inventors: Matthew L. Marrocco III, Fontana, CA (US); Virgil J. Lee, Upland, CA (US)

Correspondence Address: CHRISTIE, PARKER & HALE, LLP, PO BOX 7068, PASADENA, CA, 91109-7068, US

(21) Appl. No.: 11/064,173

(22) Filed: Feb. 22, 2005

Related U.S. Application Data
(60) Provisional application No. 60/625,047, filed on Nov. 3, 2004.

(51) Int. Cl. C08G 61/00; C09K 11/06; H01L 51/54; H05B 33/14; H01L 31/0256

(52) U.S. Cl. 528/394; 528/397; 528/398; 528/40; 528/9; 528/395; 528/423; 257/40; 257/E51.028; 428/1.1; 428/690; 428/917; 313/506; 313/504; 252/301.35; 136/263

(57) ABSTRACT

Luminescent polymers having doubly- or multiply-bridged biphenylene repeat units are provided, which are particularly suited as electroluminescent polymers. Monomers necessary for the synthesis of the multiply bridged biphenylene polymers are provided, as are electroluminescent devices utilizing these polymers.

### CROSS-REFERENCE TO RELATED APPLICATION(S)

This is an ordinary application of U.S. Provisional Application Ser. No. 60/625,047, filed on Nov. 3, 2004, the content of which is expressly incorporated herein by reference as if set forth in full herein.

### BACKGROUND OF INVENTION

Organic Light Emitting Diodes (OLEDs) are useful in electronic displays, building lighting, signage, and other applications where efficient, lightweight, thin form-factor light sources are needed. An OLED is formed by sandwiching a fluorescent or phosphorescent organic film between two electrodes, at least one of which is transparent. Holes from the anode and electrons from the cathode recombine in the organic film and produce light. If the organic film is a polymer film the device is a polymer-OLED or p-OLED. It is known in the art how to improve efficiency of OLEDs and p-OLEDs by inclusion of various other layers in the sandwich structure, including but not limited to hole injection layers, hole transport layers, buffer layers, electron injection layers, electron transport layers, hole blocking layers, electron blocking layers, exciton blocking layers, optical layers to increase light extraction efficiency, and the like. It is also known in the art that the properties of the organic film, or emissive layer, must be carefully designed to 1) allow transport of holes, 2) allow transport of electrons, 3) prevent non-radiative decay of the excited state, and 4) ensure that no irreversible chemical reactions occur during device operation. Requirements 1-3 relate to device efficiency and requirement 4 relates to device lifetime. The emissive layer will often be comprised of several substances or components, including one or more charge carriers, a fluorescent or phosphorescent material, and a more or less inert matrix.

While theory suggests that OLEDs and p-OLEDs can have high efficiencies, commercial devices still have lower efficiencies than conventional fluorescent bulbs. In practice, the efficiency of a device is dependent on color and is related to the sensitivity of the human eye, so that green devices are inherently more efficient than red or blue emitting devices. However, improvement in the efficiencies of all colors is desired. One cause of low efficiency is energy transfer from the excited emissive compound (whether it be fluorescent or phosphorescent, small molecule or polymer) to a material having a lower energy excited state. Materials with lower energy excited states may be, for example, impurities, defects, or excimers. It often occurs that the matrix has a first triplet excited state that is lower in energy, or only slightly above, the emissive material's excited state and a first singlet-excited state that is higher than the emissive material's excited state. It would be desirable to reduce or eliminate energy transfer from both the desired excited state to other lower energy excited states and from the desired excited state to the triplet state of the matrix material.

The decreasing brightness of OLEDs and p-OLEDs as a function of time is the major obstacle to their commercial application. Many factors affect lifetime. An important factor appears to be the redox stability of the emissive layer (that is, the stability of the reduced and oxidized states of the materials in the emissive layer). While not wishing to be bound by theory, it is believed that holes take the form of cations or radical cations as they propagate through the emissive layer. A radical is a molecule having an odd number of electrons and may be charged (an anion or cation) or neutral (a free radical). Radicals are generally more reactive than molecules with an even number of electrons. As electrons propagate through the emissive layer, they take the form of anions or radical anions. Radical cations may dissociate into a cation and a free radical, while radical anions may dissociate into an anion and a free radical. Cations, radical cations, anions, radical anions, and free radicals are all reactive species that may undergo unwanted chemical reactions with one another or with nearby neutral molecules. Such chemical reactions may alter the electronic properties of the emissive layer and can lead to decreases in brightness, decreases in efficiency, and (ultimately) device failure. For this reason, it would be desirable to reduce or eliminate chemical reactions of these active species in OLEDs and p-OLEDs.

Even the most promising p-OLED materials are limited by short lifetimes. For example, copolymers of methylene-bridged polyphenylenes (polyfluorenes,

[image]

FIG. 1) and other conjugated units, G, such as 4,4′-triphenylamine, 3,6-benzothiazole, 2,5-(1,4-dialkoxyphenylene), or a second bridged biphenyl unit are frequently used in p-OLED applications. While green emitting p-OLEDs based on such polyfluorene copolymers have been reported to have lifetimes of over 10,000 hours, red and blue emitting p-OLEDs based on these systems are shorter lived. Lifetime is generally measured as the time to half brightness at a set current density, starting at 100 cd/m². In fact, the lifetimes of the best polyfluorene blue phosphors are not suitable for commercial p-OLED applications. For this reason, it would be desirable to improve the stability of p-OLED emitter materials, especially those that emit in the blue color range.

Blue emitters generally function differently than red and green emitters. In polyphenylene systems, the emissive center in green and red emissive polymers is typically a special repeat unit that has a first singlet-excited state of appropriate energy to emit green or red. However, in blue emissive polyphenylene systems, including bridged polyphenylenes, the emissive center is typically one or more adjacent phenylene (or bridged biphenylene) repeat units. In this case, the phenylene (or bridged biphenylene) backbone has the lowest singlet-excited state of all the repeat units or other materials present. That is, the majority repeat unit is the emitter.

### SUMMARY OF THE INVENTION

In one aspect, the present invention relates to a polymer composition comprising one type of repeat unit represented by: 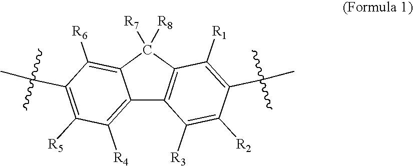
where R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl; adjacent R groups may or may not form a ring structure; R₇ and R₈ taken together may or may not form a ring structure; any R₁-R₈ may or may not form ring structures with adjacent repeat units in the polymer; any Rₐ and R_{b} (if present) taken together may or may not form one or more ring structures; and either (1) R₇ forms a ring system with R₆ or (2) R₇ forms a ring system with R₆ and R₈ forms a ring system with R₁ in which the two ring systems may or may not share more than one atom.

In another aspect, the present invention relates to a polymer material having at least one doubly- or triply-bridged biphenyl unit that has first singlet- and/or triplet-excited states that are higher than comparable polymers that do not feature such fused-ring structures.

In yet another aspect, the present invention comprises a polymer material having doubly- and triply-bridged biphenyl units that are suitable as host matrixes for fluorescent and phosphorescent emitters for use in p-OLED applications.

In yet another aspect, the present invention comprises an oligomeric material comprising doubly- and triply-bridged biphenyl units that are suitable as host matrixes for fluorescent and phosphorescent emitters for use in p-OLED applications.

In yet another aspect, the present invention comprises a copolymer material comprising doubly- and triply-bridged biphenyl repeat units and fluorescent or phosphorescent repeat units.

In yet another aspect, the present invention comprises a copolymer material comprising 1) doubly- and triply-bridged biphenyl repeat units, 2) fluorescent or phosphorescent repeat units, and 3) hole and/or electron transport repeat units.

In yet another aspect, practice of the present invention provides OLED and p-OLED devices with improved brightness and/or lifetime.

In yet another aspect, the present invention provides processes for producing luminescent polymers having doubly- or multiply-bridged biphenylene repeat units which are particularly suited for use in electroluminescent devices comprising said polymers.

### DETAILED DESCRIPTION OF THE INVENTION

One object of the present invention is to provide a blue emissive polymer with a long lifetime. The lifetime to half brightness starting at 100 cd/m² should be greater than 1,000 hours, preferably greater than 2,000 hours, more preferably greater than 5,000 hours, even more preferably greater than 10,000 hours, an yet more preferably greater than 20,000 hours. P-OLED devices are often tested at higher initial brightness as an accelerated ageing test. The lifetime to half brightness starting at 1,000 cd/m² should be greater than 100 hours, preferably greater than 200 hours, more preferably greater than 500 hours, even more preferably greater than 1,000 hours, an yet more preferably greater than 2,000 hours.

While not wishing to be bound by theory, the short lifetime of current state-of-the-art blue emissive polyphenylenes and bridged polyphenylene is likely due to the polymer serving as the emissive center. If the polymer itself has the lowest lying singlet level, then it must carry the exciton (excited state) for a longer period of time than it would if it could transfer its energy to an emitter with a lower excited state energy level. Having this exciton reside on the polymer for long periods of time has several deleterious effects. First, since the excited state is a very chemically reactive species, an opportunity is provided for the majority of repeat units in the polymer backbone to react irreversibly. Second, the time that the excited state spends on the main polymer repeat unit is increased, further increasing the chance of side reactions. Third, it is more difficult to protect an excited state that is spread across the whole polymer backbone than one isolated on an occasional (typically from 10 mol % to 1 mol % or less) emissive repeat unit. Forth, it is more difficult to change the color of light emitted from a polymer where the majority polymer repeat unit functions as the emitting element than it is in systems where the minority polymer repeat unit serves as the emitter.

Designing a useful polymer in which the bulk of the backbone structure does not serve as the emitting unit in p-OLED applications has met with limited success. Lower energy green and red phosphors have been achieved from methylene-bridged polyphenylene copolymers because the lower energy lowest lying singlet-energy levels of the individual polymer units are higher than that of the emissive repeat unit. This suggests that excitons that are formed on the polymer units within these green or red systems are short lived because they quickly transfer their energy to the lower energy emissive repeat units. This results in longer lifetimes. This is not the case with higher energy blue phosphors because the lowest singlet-energy levels of the individual polymer units are comparable to those of the emissive repeat units. This means that excitons reside for longer periods on the backbone units of blue phosphors leading to deleterious side reactions, which accounts for the shorter lifetimes of these systems.

Electronic conjugation is a key component to the energy level of polymer repeat units with more conjugated systems having lower energies. In this context, there are two contributing factors to conjugation: 1) the conjugation of the repeat unit itself, and 2) the conjugation of the repeat unit with adjacent aromatic units. Both of these contributing factors can be seen in polyfluorene copolymers (FIG. 2). In these systems, the methylene bridge of the fluorene unit holds two adjacent phenylene units in a planar configuration giving rise to the maximum possible conjugation between these two units and the lowest possible energy. Additionally, the fluorene units in these systems generally have only small hydrogen substituents at positions ortho to the polymer backbone, allowing for a high degree of conjugation between these two units. A key aspect of this invention are bridge-polyarylene polymer systems that offer higher energy repeat units. This is accomplished by decreasing both the conjugation of the bridged-polyarylene repeat unit and the conjugation of bridged-polyarylene unit with adjacent arylene segments. The materials that are the subject

[image]

of this invention are polyarylene polymers and copolymers containing at least one set of adjacent arylene units having a single atom bridging group connecting the ortho positions of the arylene units and one or two additional bridging group(s) between the first bridging group and the meta position(s) of the two arylene units (FIG. 3).

[image]

The method by which this invention works is illustrated by a copolymer containing alternating bridged fluorene units and phenylene units (FIG. 4). In this case, the secondary bridge connecting the 9 and 1 positions of the fluorene unit imparts an increased steric interaction (relative to an unbridged fluorene unit) with the adjacent phenylene repeat unit that is linked at the 2-position of the fluorene. This steric interaction induces a greater twist between the bridged-fluorene unit and the phenylene repeat unit, thereby decreasing conjugation and increasing the singlet energy of this polymer segment. The second bridge also causes ring strain in the fluorene repeat unit that serves to lower its conjugation and increase its singlet level.

[image]

This effect is even more pronounced with triply-bridged polyarylene structures, as is evidenced in the triply-bridged polyfluorene systems (FIG. 5). The addition of a third bridge from the 9-position to the 8-position adds to the effects of the first bridge, causing a greater twist of the phenylene unit attached to the 7-fluorene position and creating a strain in the second phenyl unit of the fluorene system.

[image]

[image]

The singlet and triplet states of polymers comprising doubly- and/or triply-bridged biphenylene repeat units are higher than those of the singly bridged polymers. The singlet energy may be greater than approximately 3 eV (413 nm), preferably greater than about 3.1 eV (400 nm), and more preferably greater than about 3.2 eV (388 nm).

Polymers comprising doubly- and triply-bridged biphenylene segments may also contain emissive repeat units with singlet energy in the visible, IR or UV range. For example, the emissive repeat unit may have peak emission of about 410 nm to 450 nm that will emit blue light. These blue emissive repeat units may be present at a relatively small mole fraction, preferable less than 10 mole %, more preferably less than 8 mole %, even more preferably less than about 6 mole %, yet more preferably less than 5 mole %. Lower levels of blue emissive repeat units may also be practical, including less than 4 mole %, less than 2 mole %, less than 1 mole % and even less than 0.5 mole %.

There are various ways to improve the stability of emissive units of the proposed invention. Such emissive repeat units may be protected, using methods known in the art, to prevent reaction of these units with one another or other components of the emissive layer. For example, the emissive repeat unit may have large inert substituents including but not limited to alkyl, aryl, heteroalkyl, and heteroaryl. Particular examples of such inert substituents include but are not limited to t-butyl, phenyl, pyridyl, cyclohexyloxy, and trimethylsilyl. Attaching inert substituents at reactive positions on the unit can also stabilize emissive units. For example, it is known that the triphenylamine cations reacts primarily at the 4-, 4′-, and 4″-positions of the phenylene units (those para to the nitrogen). It is also known that substituting these positions with, for example, alkyl groups prevents these reactions and greatly increases the lifetime of the radical cation. Emissive units can also be made stable if they are able to delocalize charge over a larger number of atoms. For example, a triphenylamine cation is more stable than an alkyldiphenylamine cation since the charge on the former delocalizes over three phenyl rings, as opposed to only two phenyl rings in the latter. Finally, incorporating bulky groups on adjacent repeat units can protect emissive repeat units.

This combination of double and triple bridging of adjacent phenylene units, transfer of energy to a minority emissive repeat unit, and protection of emissive units leads to longer OLED and p-OLED device lifetimes. Additionally, raising the singlet- and triplet-energy levels of the polymer or oligomer by doubly- or triply-bridging reduces or eliminates non-radiative pathways and increases brightness and efficiency.

One embodiment of this invention involves a homopolymer having a molecular weight of greater than about 1,000 comprising a bridged-biphenyl unit having the formula 1 below: 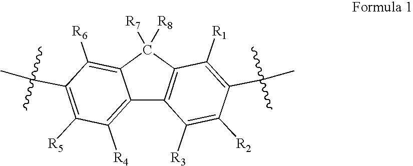
wherein R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
   adjacent R groups may or may not form a ring structure;
   R₇ and R₈ (if present) taken together may or may not form a ring structure;
   any R₁-R₈ may or may not form ring structures with adjacent repeat units in the polymer;
   any Rₐ and R_{b} (if present) taken together may or may not form one or more ring structures;
and either (1) R₇ forms a ring system with R₆ or (2) R₇ forms a ring system with R₆ and R₈ (if present) forms a ring system with R₁ wherein the two ring systems may or may not share more than one atom.
   Specific, non-limiting examples of polymer repeat units that are included in this invention are provided in FIG. 6.

[image]

Another embodiment of this invention involves a copolymer having two or more of the types of repeat units represented by the formula 1
where R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
   adjacent R groups may or may not form a ring structure;
   R₇ and R₈ taken together may or may not form a ring structure;
   any R₁-R₈ may or may not form ring structures with adjacent repeat units in the polymer;
   any Rₐ and R_{b} (if present) taken together may or may not form one or more ring structures;
and either (1) R₇ forms a ring system with R₆ or (2) R₇ forms a ring system with R₆ and R₈ forms a ring system with R₁ in which the two ring systems may or may not share more than one atom.

Another embodiment of this invention involves a copolymer having two or more of the types of repeat units represented by the formula 1
wherein R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
   adjacent R groups may or may not form a ring structure;
   R₇ and R₈ (if present) taken together may or may not form a ring structure;
   any R₁-R₈ may or may not form ring structures with adjacent repeat units in the polymer;
   any Rₐ and R_{b} (if present) taken together may or may not form one or more ring structures;
and either (1) R₇ forms a ring system with R₆ or (2) R₇ forms a ring system with R₆ and R₈ forms a ring system with R₁ wherein the two ring systems may or may not share more than one atom;
   and comprising 1-99% by weight of one or more types of conjugated repeat units. Conjugated repeating units may be independently selected from, but are not limited to, the group of conjugated units of the formulas 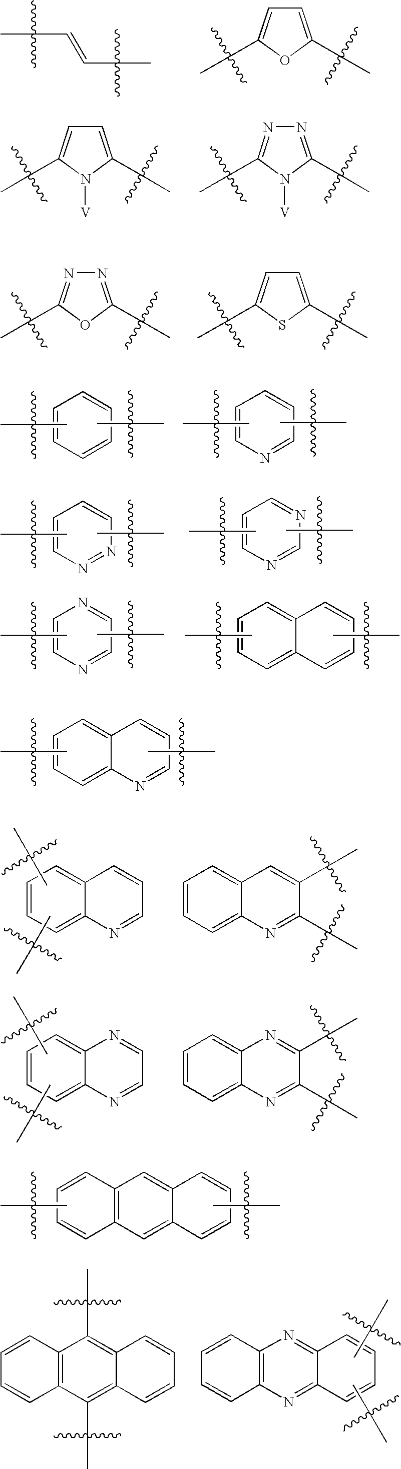 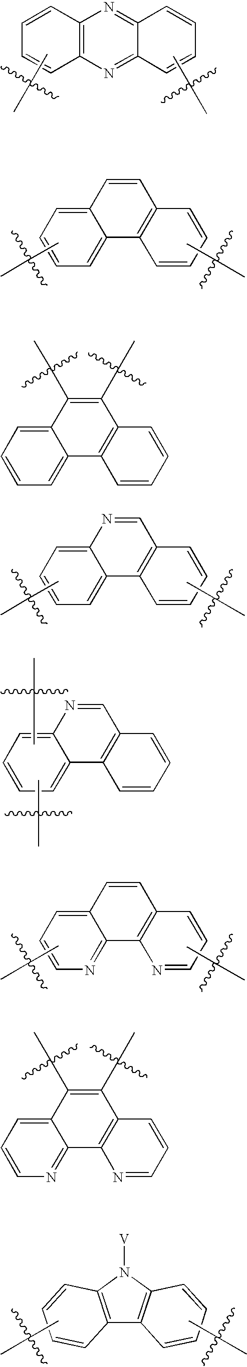 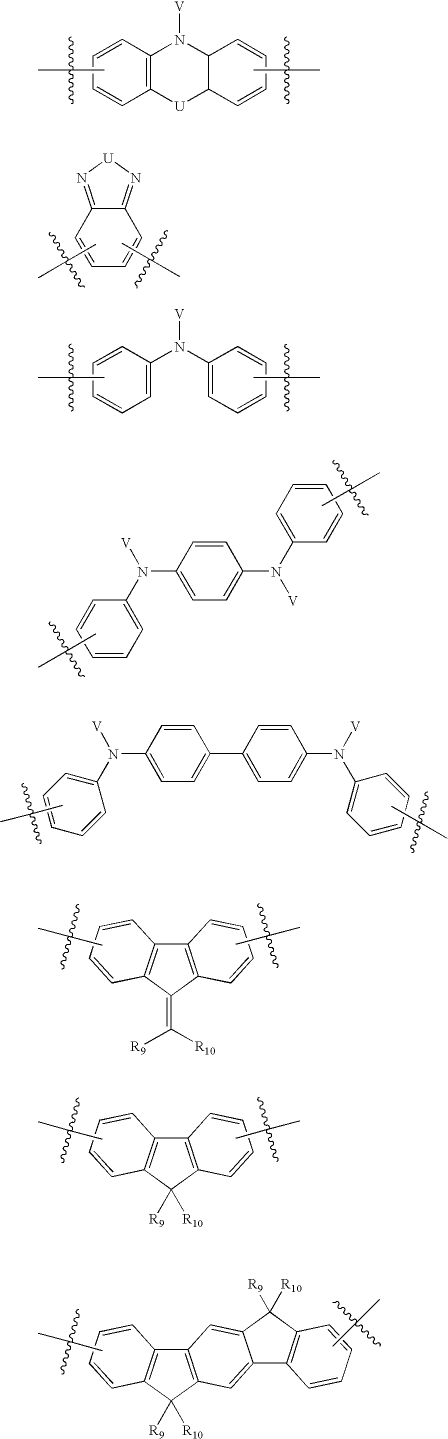 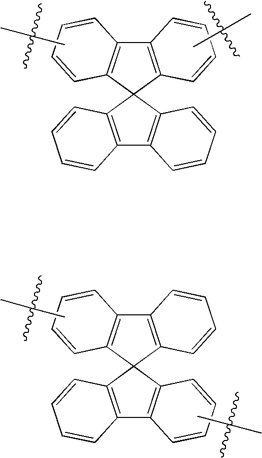
   wherein the conjugated units may bear substitutents independently chosen from the group consisting alkyl, substituted alkyl, perfluoro alkyl, alkoxy, substituted alkoxy, aryl, substituted aryl, aryloxy, substituted aryloxy, heteroaryl, substituted heteroaryl, alkyl carbonyloxy, cyano, and fluoro;
U is independently selected from —O— and —S—;
and V, R₉, and R₁₀ are each independently chosen from the group consisting of alkyl, substituted alkyl, aryl, substituted aryl, heteroaryl, or substituted heteroaryl.

Another embodiment of this invention involves a copolymer composition comprising 1-99% by weight of two or more types of repeat units represented by the formula 1
wherein R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —POR_{R}_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
   adjacent R groups may or may not form a ring structure;
   R₇ and R₈ (if present) taken together may or may not form a ring structure;
   any R₁-R₈ may or may not form ring structures with adjacent repeat units in the polymer;
   any Rₐ and R_{b} (if present) taken together may or may not form one or more ring structures;
and either (1) R₇ forms a ring system with R₆ or (2) R₇ forms a ring system with R₆ and R₈ forms a ring system with R₁ in which the two ring systems may or may not share more than one atom;
   and comprising 1-99% by weight of one or more types of conjugated repeat units. Conjugated repeating units may be independently selected from, but are not limited to, conjugated units of the formulas 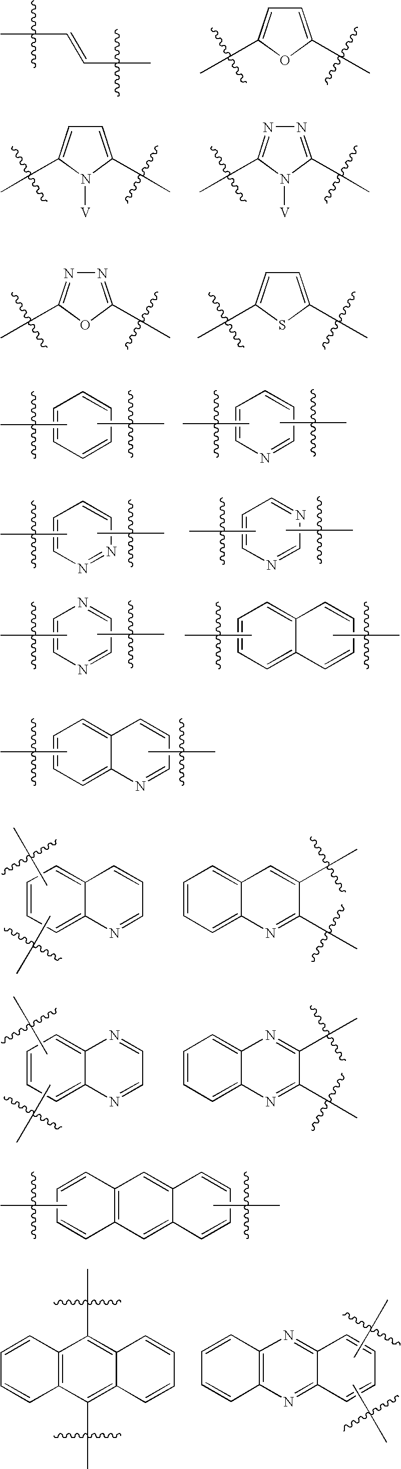 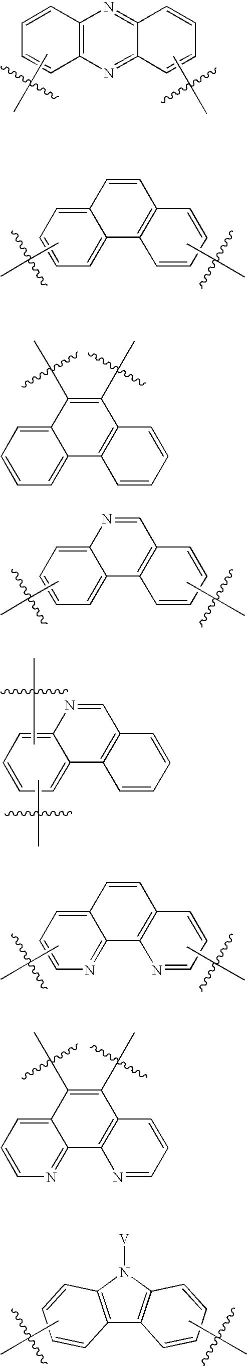 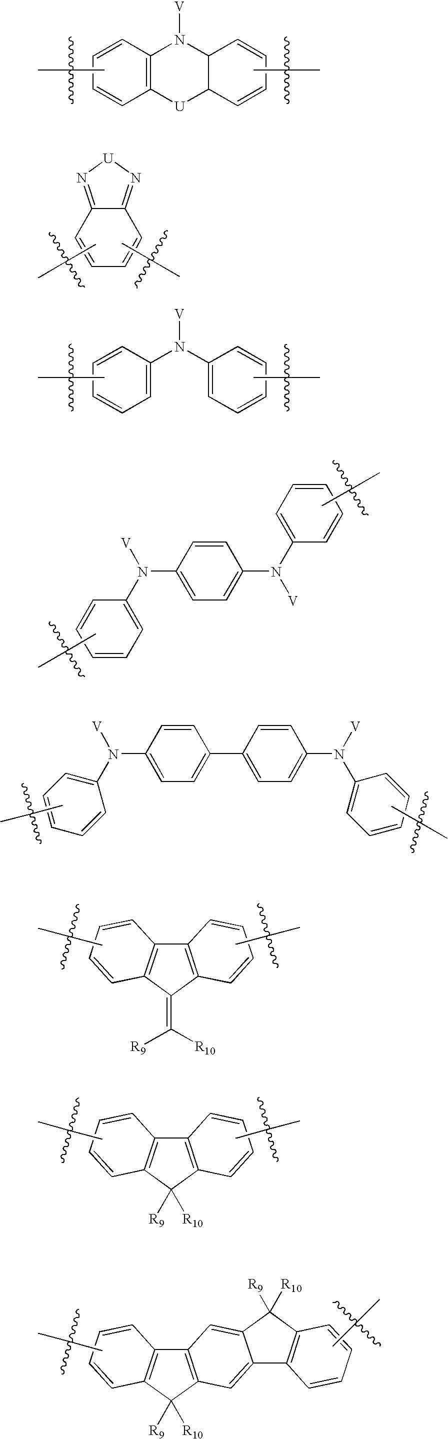 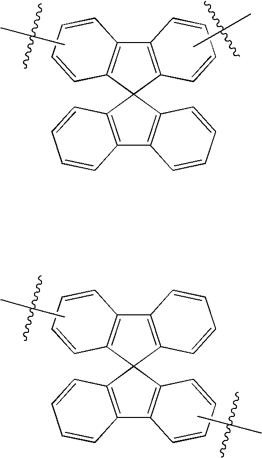
   wherein the conjugated units may bear substitutents independently chosen from the group consisting alkyl, substituted alkyl, perfluoro alkyl, alkoxy, substituted alkoxy, aryl, substituted aryl, aryloxy, substituted aryloxy, heteroaryl, substituted heteroaryl, alkyl carbonyloxy, cyano, and fluoro;
U is independently selected from —O— and —S—;
and V, R₉, and R₁₀ are each independently selected from the group consisting of alkyl, substituted alkyl, aryl, substituted aryl, heteroaryl, or substituted heteroaryl.

Another embodiment of this invention is a polymer composition comprising one or more repeat units represented by the formula 2 below 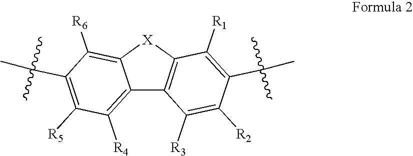
where X is selected from the group consisting of 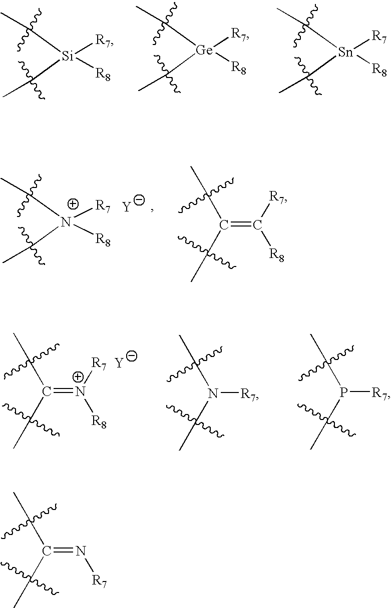
wherein R₁-R₈ are independently selected from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently selected from the group consisting of H, alkyl, substituted alkyl, aryl, substituted aryl, heteroaryl, and substituted heteroaryl;
   adjacent R groups may or may not form a ring structure;
   R₇ and R₈ (if present) taken together may or may not form a ring structure;
   any R₁-R₈ may or may not form ring structures with adjacent repeat units in the polymer;
   any Rₐ and R_{b} (if present) taken together may or may not form one or more ring structures;
   Y⁻ is any mono-valent anionic atom or group;
and either (1) R₇ forms a ring system with R₆ or (2) R₇ forms a ring system with R₆ and R₈ (if present) forms a ring system with R₁ wherein the two ring systems may or may not share more than one atom.

Another embodiment of this invention is a copolymer composition comprising 1-99% by weight of one or more types of repeat units represented by the formula 2
where X is selected from the group consisting of 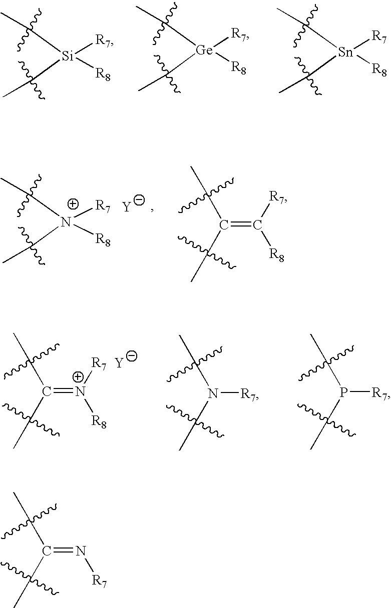
wherein R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
   adjacent R groups may or may not form a ring structure;
   R₇ and R₈ (if present) taken together may or may not form a ring structure;
   any R₁-R₈ may or may not form ring structures with adjacent repeat units in the polymer;
   any Rₐ and R_{b} (if present) taken together may or may not form one or more ring structures;
   Y⁻ is any mono-valent anionic atom or group;
and either (1) R₇ forms a ring system with R₆ or (2) R₇ forms a ring system with R₆ and R₈ forms a ring system with R₁ wherein the two ring systems may or may not share more than one atom;
   and comprising 1-99% by weight of one or more types of conjugated repeat uints. Conjugated repeating units may be independently selected from, but are not limited to, the group of conjugated units of the formulas 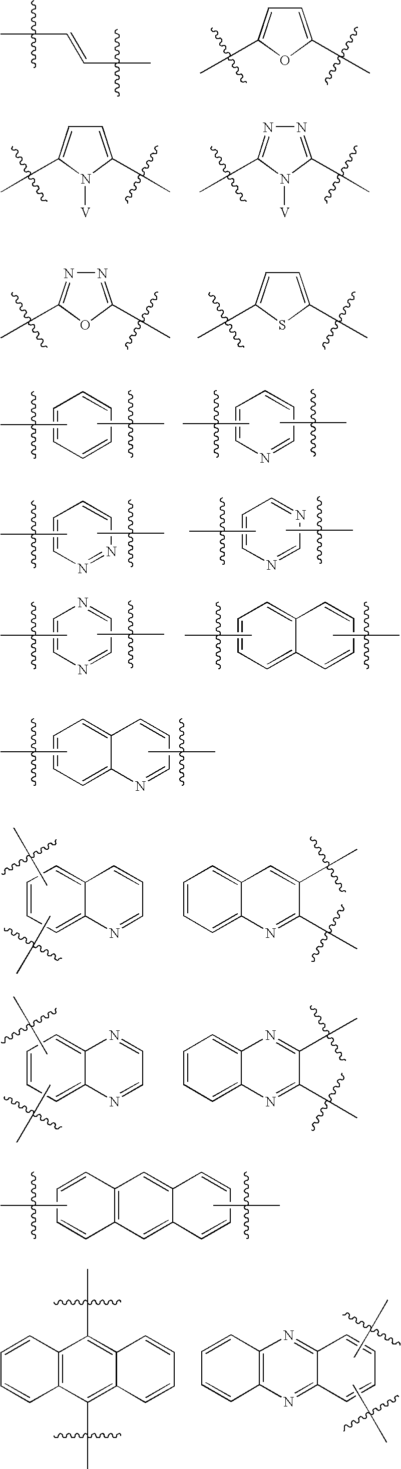 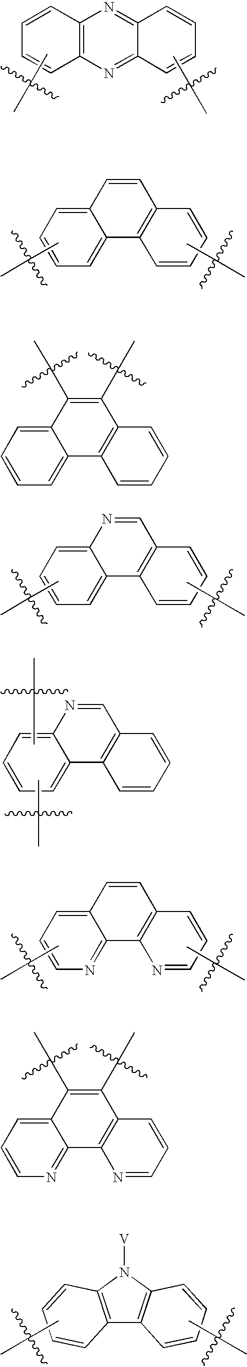 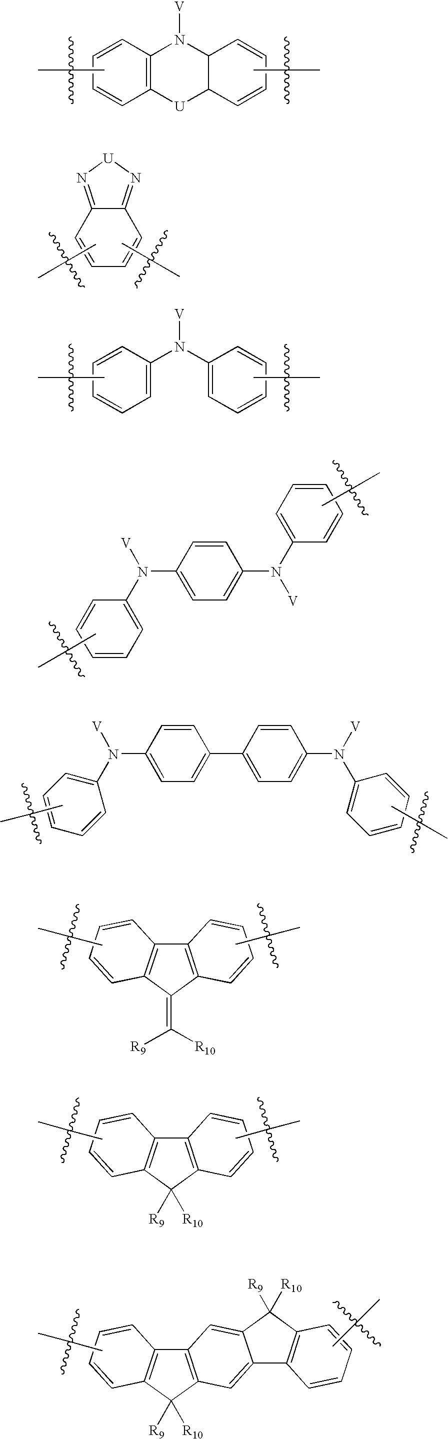 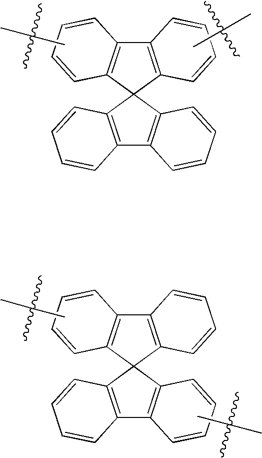
   wherein the conjugated units may bear substitutents independently selected from the group consisting alkyl, substituted alkyl, perfluoro alkyl, alkoxy, substituted alkoxy, aryl, substituted aryl, aryloxy, substituted aryloxy, heteroaryl, substituted heteroaryl, alkyl carbonyloxy, cyano, and fluoro;
U is independently selected from —O— and —S—;
and V, R₉, and R₁₀ are each independently selected from the group consisting of alkyl, substituted alkyl, aryl, substituted aryl, heteroaryl, or substituted heteroaryl.

In another aspect, the invention is directed to a composition comprising a polymer formed from arylamine monomers of the formula: 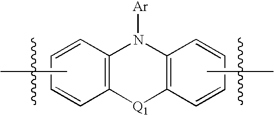
where Q₁ is O, S, SO₂, C(R³)₂ or N—R³ wherein R³ is aryl or substituted aryl of C₆-C₄₀ aryalkyl of C₆-C₂₄ or alkyl of C₁-C₂₄. Preferably R³ is aryl of C₆-C₂₄ and more preferably R³ is an akylated aryl group of C₆-C₂₄. Ar is an aryl or heteroaryl group of C₆-C₄₀ or substituted aryl or heteroaryl group of C₆-C₄₀. Preferably, the aryl, heteroaryl or substituted aryl or heteroaryl group is C₆-C₂₄.

In another embodiment, the invention is a composition comprising a polymer represented by Formula 3: 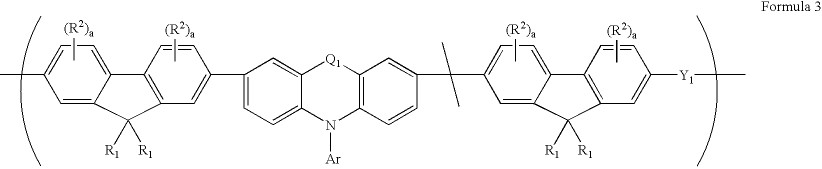
where the copolymer may have from 1 to 100% tricyclic arylamine units and 0 to 99% Y₁ repeat units in which the tricyclic arylamine containing repeat units are shown to the left of the slash symbol (“\”) in formula 3 and R¹ is independently in each occurrence H, C₃₋₄₀ hydrocarbyl or C₃₋₄₀ hydrocarbyl containing one or more heteroatoms of S, N, O, P or Si. Alternatively, both of R¹ together with the 9-carbon on the fluorene may form a C₅₋₂₀ aliphatic or aromatic ring structure or a C₄₋₂₀ aliphatic or aromatic ring structure which may contain one or more heteroatoms of S, N, or O, and, either or both of R¹ independently form a bridge with the 9-carbon to a position adjacent to the 9-carbon on either or both aromatic rings of the fluorene. Preferably R¹ is C₁₋₁₂ alkyl, C₆₋₁₀ aryl, C₆₋₄₀ hydrocarbyloxyaryl or alkyl-substituted aryl, C₄₋₁₆ hydrocarbyl carboxylate or C₉₋₁₆ aryl trialkylsiloxy moiety. More preferably R¹ is C₄₋₁₀ alkyl or C₆₋₄₀ hydrocarbyloxyaryl.

In the embodiment where the two R¹ form a ring structure with the 9-carbon atom of the fluorene ring, the ring structure formed is preferably a C₅₋₂₀ straight- or branched-ring structure or a C₄₋₂₀ straight- or branched-ring structure containing one or more heteroatoms of S, N or O; even more preferably a C₅₋₁₀ aliphatic or aromatic ring or a C₄₋₁₀ aliphatic or aromatic ring containing one or more of S or O; and most preferably a C₅₋₁₀ cycloalkyl or C₄₋₁₀ cycloalkyl containing oxygen.

R² is independently in each occurrence C₁₋₂₀ hydrocarbyl, C₁₋₂₀ hydrocarboxyloxy, C₁₋₂₀ thioether, C₁₋₂₀ hydrocarbyloxycarbonyl, C₁₋₂₀ hydrocarbylcarbonyloxy or cyano. R² is preferably C₁₋₁₂ alkyl, C₆₋₁₀ aryl or alkyl-substituted aryl, C₆₋₁₀ aryloxy or alkyl-substituted aryloxy, C₁₋₁₂ alkoxycarbonyl, C₆₋₁₀ aryloxycarbonyl or alkyl-substituted aryloxycarbonyl, C₁₋₁₂ alkoxy, C₁₋₁₂ alkylcarbonyloxy, C₆₋₁₀ arylcarbonyloxy or alkyl-substituted arylcarbonyloxy, cyano or C₁₋₂₀ alkylthio. Even more preferably, R² is C₁₋₄ alkoxy, phenoxy, C₁₋₄ alkyl, phenol, sulfone or cyano.

“a” is independently in each occurrence from about 0 to 1. Preferably, a is 1.

The term “hydrocarbyl” as used herein means any organic moiety containing only hydrogen and carbon unless specified otherwise, and may include aromatic, aliphatic, cycloaliphatic and moieties containing two or more alphatic, cycloaliphatic and aromatic moieties.

Q, is preferably O, S, SO₂, C(R³)₂ or N—R³.

R³ is aryl of C₆ to C₄₀, substituted aryl of C₆ to C₄₀, alkyl-substituted aryl of C₆ to C₂₄, or alkyl of C₁ to C₂₄. Preferably R³ is aryl of C₆ to C₂₄ and more preferably R³ is an alkylated aryl group of C₆ to C₂₄.

Ar is an aryl or heteroaryl group of C₆ to C₄₀ or substituted aryl or heteroaryl group of C₆ to C₄₀. Preferably, the aryl, heteroaryl or substituted aryl or heteroaryl group is C₆-C₂₄, and more preferably C₆-C₁₄ Most preferably Ar is phenyl, alkylated phenyl, 2-fluorenyl, anthracenyl, phenantherenyl, pyrenyl, pyridine, isoquinoline, quinoline, triazine, triazole, benzotriazole, or phenanthridine.

Y₁ is a conjugated unit that can vary in each occurrence of the repeat unit.

The term “conjugated unit” means a moiety containing overlapping π orbitals.

In a preferred embodiment, additional conjugated units including hole transporting moieties, electron transporting moieties, and/or light emitting moieties are present. The additional units are used to optimize one or more of the following: charge injection, charge transport, electroluminescent device efficiency and lifetime. In this preferred embodiment, the conjugated unit Y, is selected from the group consisting of conjugated units of the formulas: 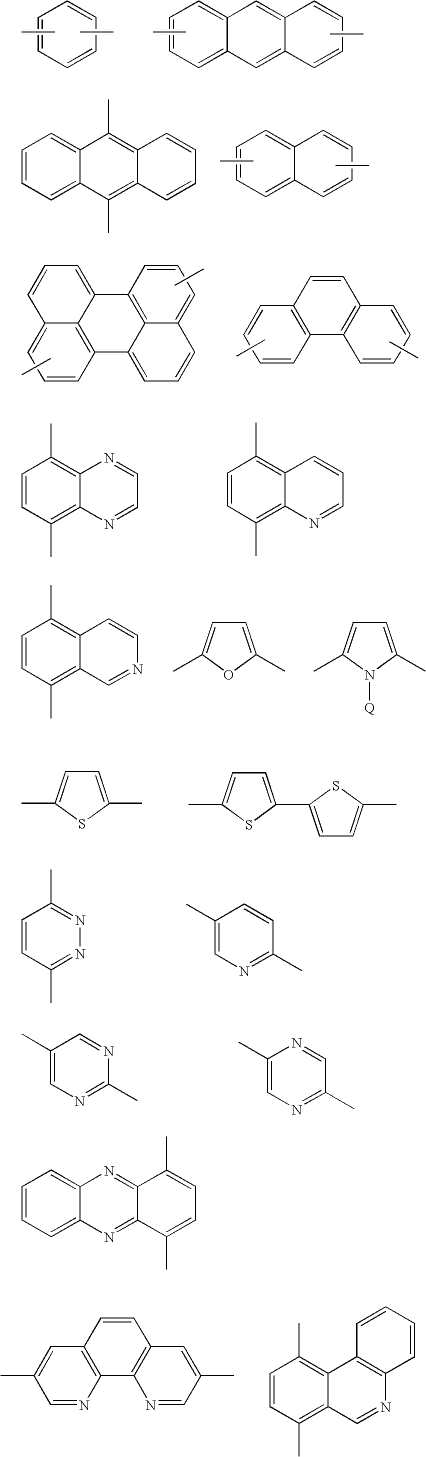 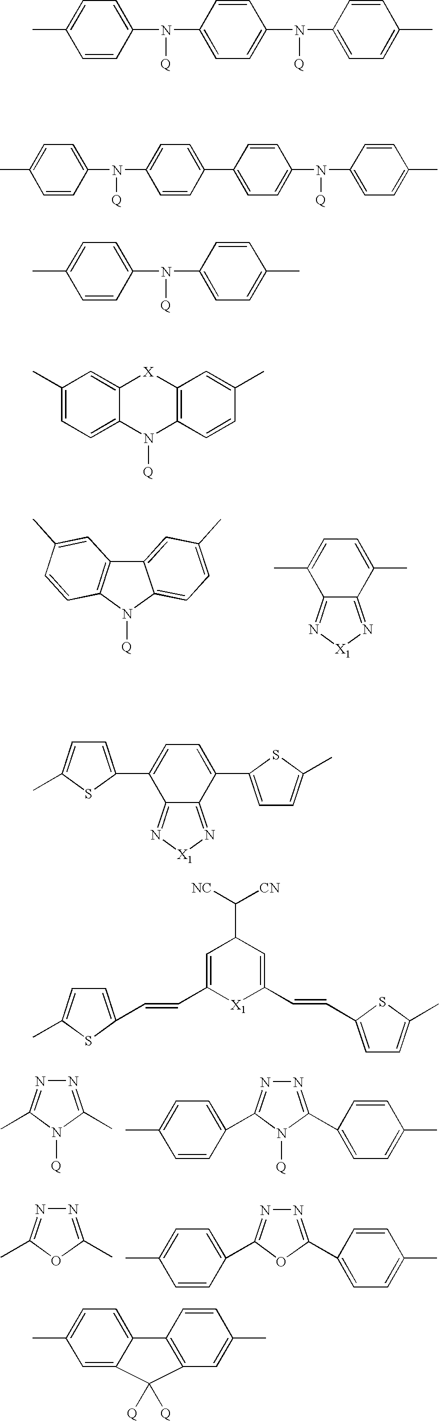 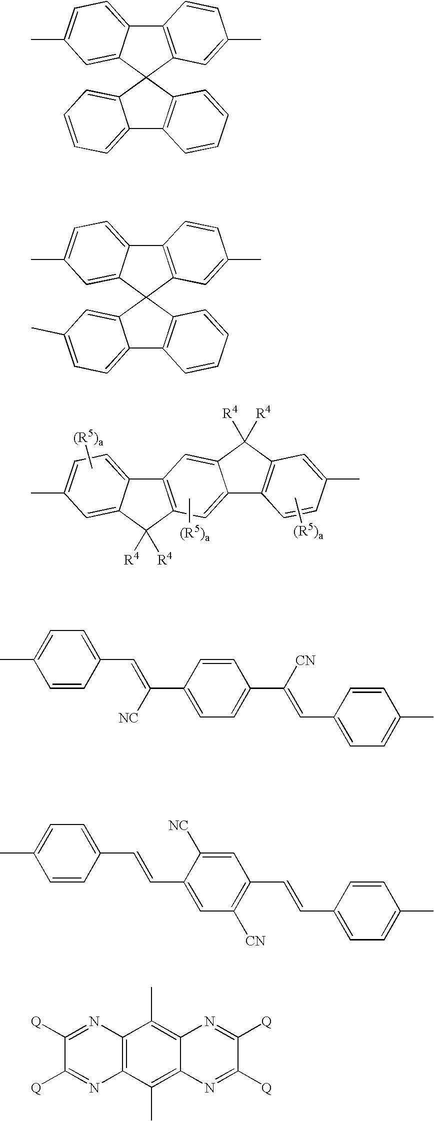
where each of the above structures are divalent moieties noted by the bonds leaving the aromatic rings and wherein the conjugated unit may bear substituents, such substituents being independently in each occurrence C₁₋₂₀ hydrocarbyl, C₁₋₂₀ hydrocarboxyloxy, C₁₋₂₀ thioether, C₁₋₂₀ hydrocarboxycarboxyl, C₁₋₂₀ hydrocarbylcarbonyloxy, cyano, or fluoro group.

X₁ is O or S.

Q is C₁ to C₂₀ alkyl or Ar

Ar is an aryl or heteroaryl group of C₆ to C₄₀ or substituted aryl or heteroaryl group of C₆ to C₄₀. Preferably Ar is phenyl, alkylated phenyl, 2-fluorenyl, anthracenyl, phenanthrenyl, pyrenyl, pyridine, isoquinoline, quinoline, triazine, triazole, benzotria-zole, or phenanthridine.

R⁴ is independently in each occurrence H, C₁₋₄₀ hydrocarbyl or C₃₋₄₀ hydrocarbyl containing one or more S, N, O, P, or Si atoms or both R⁴ together with carbon to which both R⁴are bonded may form a C₅₋₂₀ ring structure which may contain one or more S, N, or O atoms. R⁵ is independently C₁₋₂₀ hydrocarbyl, C₁₋₂₀ hydrocarbyloxy, C₁₋₂₀ thioether, C₁₋₂₀ hydrocarbyloxycarbonyl, C₁₋₂₀ hydrocarbylcarbonyloxy or cyano.

In one aspect of the present invention, the multiply-bridged biphenyl polymers are non-linear and contain branch points. One advantage of non-linear polymers is that polymer mixtures or blends are easier to prepare. For example, if two dendrimeric or hyperbranched polymers have dissimilar cores but similar shells they will tend to be miscible. Another advantage is that the central core is protected by an outer shell structure. A further advantage is that the electronic properties of the core and one or more shells may be varied independently, such as a hyperbranched polymer might have an emissive core, a hole transporting inner shell, and an electron transporting outer shell. Light branching or crosslinking also may be advantageous for molecular weight control and viscosity. A non-limiting example of a multiply-bridged biphenyl polymer having a branched structure is represented by the formula 4:

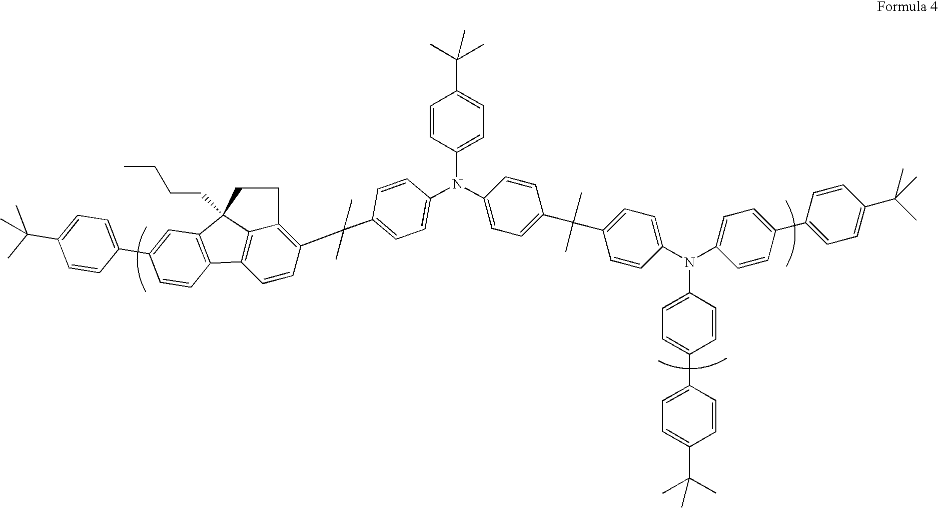

The branched polymers of the present invention may be prepared by the inclusion of a trifunctional or polyfunctional monomer along with the difunctional monomers. For example, the formula 4 polymer may be prepared by Suzuki coupling using monomers and endcapping reagents shown in FIG. 7. The degree of branching may be controlled by adjusting the relative amount of tribromophenylamine. It will be also understood that the molecular weight is controlled by the relative amount of endcapping agent and the diboronic ester/dibromo monomer ratio. One unusual feature of Suzuki polymerization is that the monomer ratio giving the highest molecular weight is often offset in favor of the diboronic ester. This is likely due to some homocoupling of boronic esters. One reasonably skilled in the art will know how to adjust the monomer ratio, the amount of endcapping agent, and the amount of crosslinking monomer to obtain a higher or lower molecular weight.
FIG. 7. Examples of Monomers and Endcapping Reagents that May Be Used to Prepare the Formula 4 Polymer

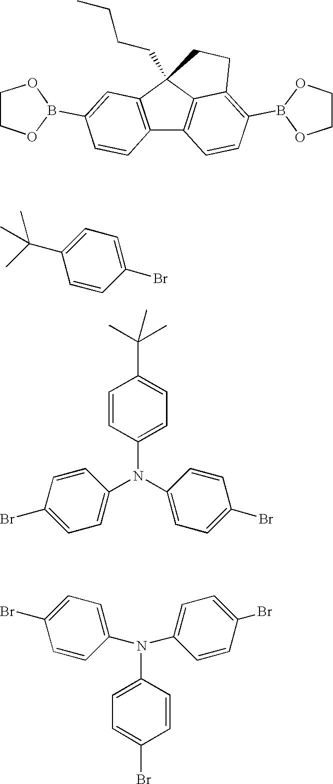

The present invention also relates to linear polymers comprising multiply bridged biphenylene units and reactive end groups or side groups that may be induced to form non-linear structures through reaction at the reactive end groups or side groups. Polymers having reactive side groups are disclosed in U.S. Pat. Nos. 5,539,048 and 5,830,945 incorporated herein in full by reference. Polymers having reactive end groups are disclosed in U.S. Pat. Nos. 5,670,564; 5,824,744; 5,827,927; and 5,973,075 all incorporated herein in full by reference. Non-limiting examples of multiply bridged biphenylene (MBB) polymers having a reactive side group or end group are represented by the structures below: 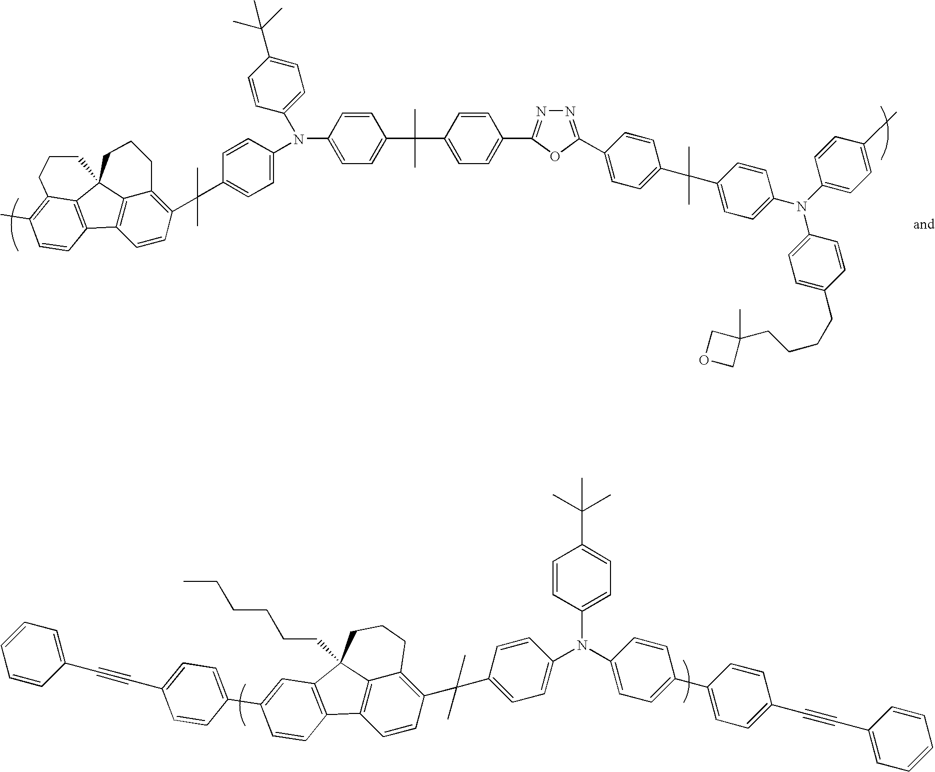
The branched, hyperbranched, and dendritic polymer may also have reactive groups.

The polymers and copolymers of the present invention having reactive side groups or reactive end groups may be crosslinked into an insoluble network, sometimes called thermosets. Crosslinked polymers offer several advantages over uncrosslinked polymers, especially for applications in the area of OLEDs and p-OLEDs. For example, p-OLEDs typically consist of multiple polymer layers, each of which is very thin (typically between 50 nm and 1,000 nm). During fabrication, polymer layers must be deposited over previously formed polymer layers, and the underlying layer must not dissolve in or be disturbed by the polymer solution being applied to form the upper layer. One method to prevent disturbance of the lower layers is to crosslink the lower layers prior to application of upper layers. The non-linear, crosslinked layers afford this feature since they are impervious to solvent and subsequent processing steps.

Polymers and co-polymers of the present invention can have a variety of structures. They may be linear, branched, hyperbranched, dentritic, graft, comb, star, combinations of these, or any other polymer structure. Polymers of the present invention may be regio-regular, regio-random, or some combination thereof. Polymers of the present invention may be head-to-head, head-to-tail, or mixed head-to-head/head-to-tail. Co-polymers of the present invention may be alternating, random, block, or combination of these. Polymers of the present invention may be chiral or contain chiral repeat units. Any combination of chiral repeat units is contemplated, including all chiral units of a single handedness, a racemic mixture of units, or a mixture (e.g., from partially resolved chiral monomers). Chiral units may be desirable to induce polarization of the emitted light. Polarized OLEDs and p-OLEDs may have application in LCD backlighting, eliminating the need for one of the LCD display polarizers. Since polarizers absorb some the incident light elimination of a polarizer can increase efficiency.

In one embodiment of the present invention a polymer comprises at least one multiply bridged biphenylene repeat unit, at least one luminescent compound (L) and optionally other repeat units (Q₂). A luminescent dye may be incorporated into the polymer in any fashion. Non-limiting examples of structural types are provided in FIG. 8 below.

FIG. 8. Non-Limiting Examples of Luminescent Compositions that Are Included In this Invention 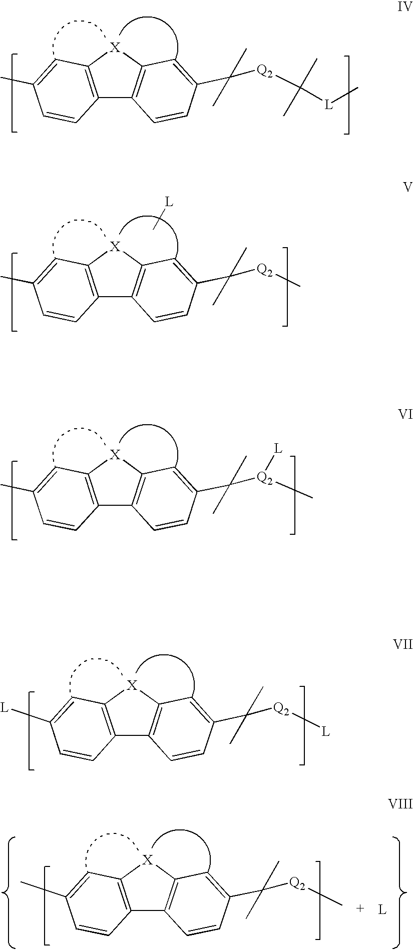
where X is selected from the group consisting of 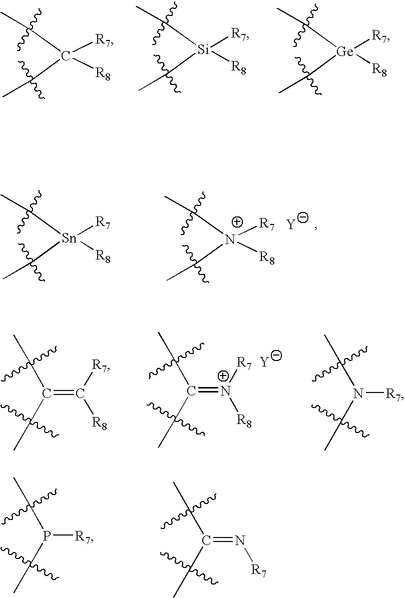
wherein R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO2Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
   adjacent R groups may or may not form a ring structure;
   R₇ and R₈ (if present) taken together may or may not form a ring structure;
   any R₁-R₈ may or may not form ring structures with adjacent repeat units in the polymer;
   any Rₐ and R_{b} (if present) taken together may or may not form one or more ring structures;
   Y⁻ is any mono-valent anionic atom or group;
and either (1) R₇ forms a ring system with R₆ or (2) R₇ forms a ring system with R₆ and R₈ forms a ring system with R₁ wherein the two ring systems may or may not share more than one atom;
the solid semicircle represents a bridging linkage;
the dotted semicircle represents an optional bridging linkage;
Q₂ is nil or any conjugated repeat unit; and
L is any luminescent compound or group.

Non-limiting examples of bridging, linkages of formulae IV-VIII are optionally substituted alkyl, aryl, heteroalkyl, heteroaryl, fluoroalkyl, and fluoroaryl. Particular examples of bridging linkages are given herein, for example, in FIG. 6, and in the Examples section below.

The polymers of FIG. 8 can have a variety of configurations. They can be alternating, block, or random. Additionally, they may be homopolymers (e.g., the multiply-bridged biphenyl unit and conjugated repeat units, Q₂, are perfectly alternating) or copolymers comprising any number of types of repeat units, random, block, regioregular, regiorandom, graft, comb, branched, hyperbranched, dendritic, crosslinked or any combination of structures. Non-limiting examples of Q₂ include: 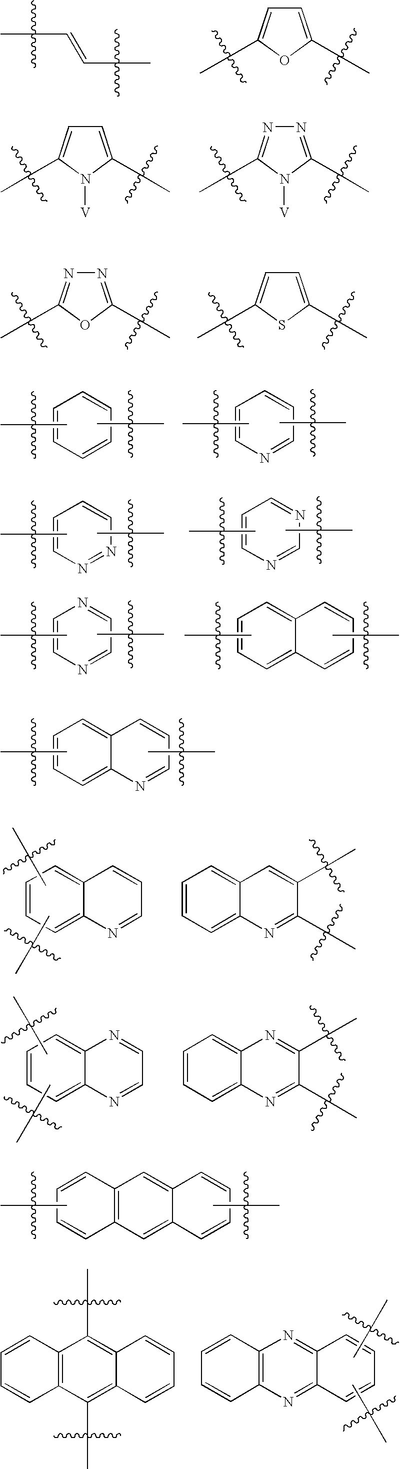 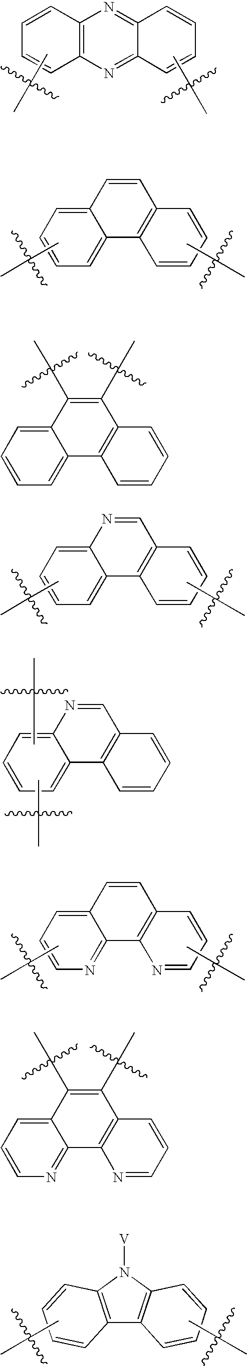 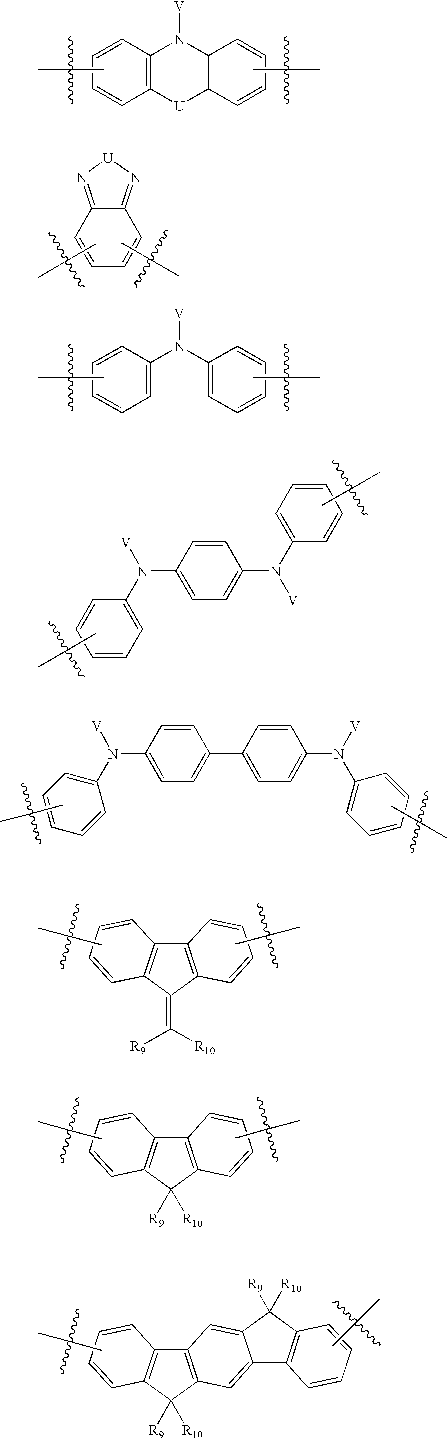 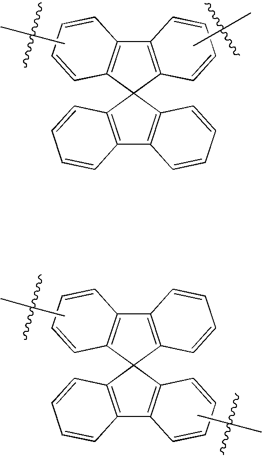
wherein the conjugated units may bear substitutents independently chosen from the group consisting alkyl, substituted alkyl, perfluoro alkyl, alkoxy, substituted alkoxy, aryl, substituted aryl, aryloxy, substituted aryloxy, heteroaryl, substituted heteroaryl, alkyl carbonyloxy, cyano, and fluoro;
U is independently selected from —O— and —S—;
and V, R₉, and R₁₀ are each independently chosen from the group consisting of alkyl, substituted alkyl, aryl, substituted aryl, heteroaryl, or substituted heteroaryl.

The luminescent component (L) of these systems is either attached to or mixed with the polymer. In the formula IV, L is divalent and is part of the main chain. In the formula V, L is monovalent and appended from any position of the multiply-bridged biphenyl unit, including any position on the biphenylene moiety and any position on any of the bridging moieties. In the formula VI, L is monovalent and appended from at least one of the repeat units, Q₂. In the formula VII, L is an end group. In the formula VIII, L is not chemically attached to the polymer, but rather is present as a component of a polymer blend or mixture. In one embodiment of the formula VIII, the luminescent component is a small molecule that is dissolved in the polymer matrix. In another embodiment of the formula VIII, the luminescent compound is an oligomer or polymer blended in with the multiply-bridged biphenylene-containing polymer. In either of these embodiments, other compounds may be present to increase solubility or compatibility of L with the MBB containing polymer. However, L may not need not be fully soluble or compatible with the MBB containing polymer if the fabrication method results in a non-equilibrium state wherein L is trapped in the polymer and kinetically prevented from crystallizing or separating.

This invention relates to homo- and copolymers containing multiply-bridged biphenylene units. The invention requires at least one multiply-bridged biphenylene unit (on average) in each polymer chain. However, preferably there are at least 10 mol % multiply-bridged biphenylene units, more preferably at least 20 mol % multiply-bridged biphenylene units, and most preferably at least 25 mol % multiply-bridged biphenylene units. Additionally, the compositions of this invention may consist entirely of multiply-bridged biphenylene units. The copolymer of this invention may contain 0-99% of other conjugated repeat units (Q₂), preferably between 0 and 50 mol %. The copolymers of this invention may also contain 0 to 50 mol % of luminescent units (L), preferably between about 0.1 and 25 mol %, more preferably between about 0.2 and 15 mol % of L units, and most preferably between about 0.5 mol % and 5 mol % of L units.

In one embodiment of the present invention, the compositions will have a luminescent component (L) featuring an emission at longer wavelength (lower energy) than the multiply-bridged biphenylene polymer component. As is known in the art (see for example, M. D. McGehee, T. Bergstedt, C. Zhang, A. P. Saab, M. B. O'Regan, G. C. Bazan, V. I. Srdanov, and A. J. Heeger, Adv. Materials, 1999, 11(6), 1349-1354) if a luminescent component of lower energy is embedded in a matrix that luminesceses at higher energy (in the absence of L), then the energy can be transferred from the matrix to the luminescent component, which dominates the emission. This is especially important in electroluminescent devices featuring luminescent compositions where the matrix transfers all of its energy to the to L (even if photoluminescence spectrum of this composition features luminescence from both the matrix and L). It is sometimes said that the luminescence of the matrix is quenched by L. The transfer of energy to a luminescent component is desirable because 1) the luminescent component may be protected to reduce or eliminate chemical reactions of the excited state, 2) energy does not reside on the majority backbone repeat unit making undesirable chemical reaction of the majority repeat units less likely, and 3) a single matrix repeat unit may be used with various luminescent repeat units to generate many colors.

For the practice of the present invention, all or part of the luminescence of the matrix may be quenched by L, preferably 20%, more preferably 40%, even more preferably 60%, yet more preferably 80 %, even yet more preferably 90%, even more preferably 95%, and most preferably more than 99% of the matrix luminescence is quenched (or otherwise reduced) by the presence of L. It may be that within experimental error 100% of the luminescence of the matrix is quenched by L.

The luminescent component of the present invention may be a luminescent materal, luminescent group, dye, or pigment or be any other luminescent material that is known in the art. A non-limiting example of a luminescent dye is stilbene (formula IX): 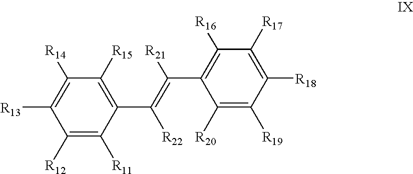
where any of the R (R₁₁-R₂₂) may be monovalent or divalent, or may provide a link to a polymer, and where any two R taken together may be bridging. Monovalent R means the group R has only one linking bond. Non-limiting examples of monovalent R are hydrogen, methyl, hexyloxy, and 4-t-butylphenyl. A specific stilbene derivative featuring monovalent and divalent R substituents (formula IX where R₁₃ is (monovalent) alkyloxy, R₂₂ is a (monovalent) cyano, and R₁₈ is a (divalent) ethylenyl group providing a link to the polymer chain) is: 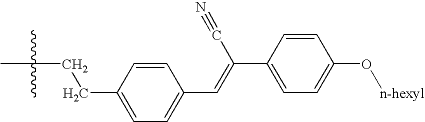
Divalent R means the group R has two linking bonds. Non-limiting examples of divalent R are —CH₂—, —CH₂CH₂CH₂—, 1,2-phenylenyl, and —OCH₂CH₂O—. A specific example of a stilbene derivative featuring divalent R groups (formula IX where R₁₅ and R₂₁ taken together form a substituted bridging methylenyl group and R₁₃ and R₁₈ provide links to the polymer chain) is: 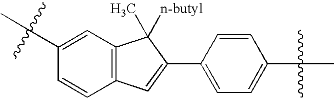
Other non-limiting examples of luminescent dyes that may be included in the compositions of this invention include anthracene, tetracene, phenanthrene, naphthalene, fluorene, bisnaphthalene, biphenyl, terphenyl, quaterphenyl, bisthiophene, bisquinoline, bisindene, and the like, where any of the hydrogens may be independently substituted by monovalent or divalent R, or may provide a link to a polymer, where any two R taken together may be bridging. Other non-limiting examples of dye units that may be incorporated into, or with, the luminescent compositions of this invention include: 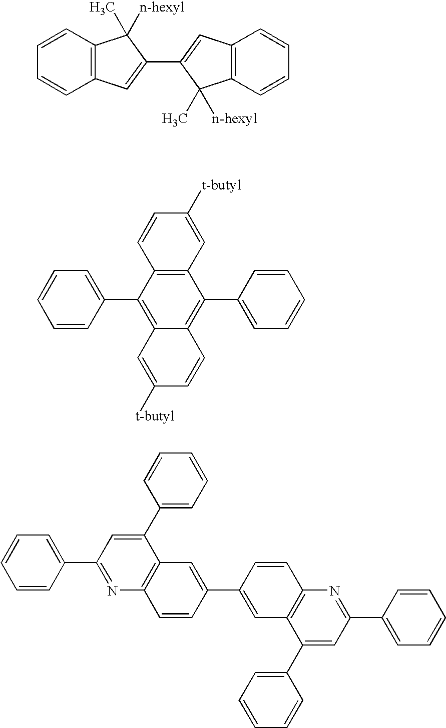
Additional luminescent dyes are disclosed in U.S. Pat. No. 6,723,811 which is incorporated herein in its entirety by this reference.

A key feature of the multiply-bridged biphenylene compositions provided in accordance with practice of this invention is that they emit at higher energies than the corresponding systems offering single or no bridges between adjacent arylene units. It will be understood by one reasonably skilled in the art that for luminescent materials that are phosphorescent (i.e., those that emit from a triplet level) the relevant energy level of the multiply-bridged biphenylene polymer is also the triplet level. The higher energies of these multiply-bridged polymers allow for “bluer” or higher energy triplet emitters. For example, it may be possible to realize a green triplet emitter with a multiply-bridged biphenylene polymer where the corresponding singly bridged polymer does not emit green light because the triplet energy level of the latter is too low. Thus, in one embodiment of the present invention a phosphorescent emitter is bound to or mixed with a multiply-bridged biphenylene polymer. For example, a green emitting iridium bisphenylpyridine emitter is coordinated to an acetylacetone group linked to a multiply-bridged biphenylene polymer to provide a green emitting electroluminescent phosphor: 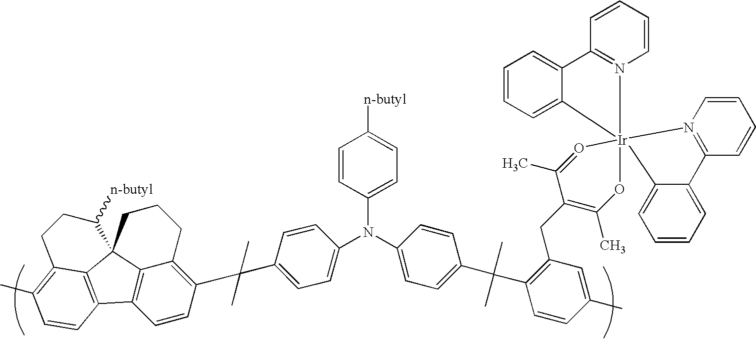
where the mole ratio of (multiply-bridged biphenylene unit)/triphenylamine/(iridium complex) repeat units is 74/22/4, and the multiply-bridged biphenylene repeat units and iridium complex containing repeat units are regiorandom.

One way of determining if a luminescent compound is useful in the practice of the present invention is to compare the visible emission spectrum of the polymer both in the presence and absence of the luminescent component (L). A useful L will effectively quench the polymer matrix photoluminescence or electroluminescence. Thus, the emission spectrum of the polymer in the presence of L will have average energy in the visible range (400 nm to 650 nm) that is red-shifted by at least 4 nm from that of the polymer without L, more preferably red-shifted by at least 8 nm, even more preferably red-shifted by at least 12 nm, and most preferably red-shifted by at least 20 nm. Although the wavelength scale is not linear in energy, it may be preferable to use energy units where the emission spectrum of the polymer in the presence of L will have average energy in the visible range (400 nm to 650 nm) that is red-shifted by at least 0.025 eV from that of the polymer without L, more preferably red-shifted by at least 0.050 eV, even more preferably red-shifted by at least 0.075 eV, and most preferably at least red-shifted by 0.125 eV. An example of such a comparison is given in McGehee et al. where a europium complex quenches the emission of a polyphenylene polymer. Examples are given of poor quenching and essentially complete quenching of photoluminescence (see FIG. 3 in McGehee et al.).

In other words, since the luminescent compound emits at lower energy than the multiply-bridged biphenylene repeat units, excited versions of the latter will transfer their energy to the luminescent compound. The reverse process is thermodynamically unfavorable. Thus, the excited state energy of the system is funneled to the luminescent compound. If the multiply-bridged biphenylene repeat units have the lowest excited state energy of any of the repeat units in the chain then they may emit.

To determine the effectiveness of an L that is part of the polymer structure (for example, as a repeat unit, a side group, or an end group) the comparison will necessarily be to a different polymer lacking any L groups or units. For example, if L is a side group or end group it may be replaced with H or phenyl. In the case that L is part of the polymer, the emission spectrum might be effected by other changes in the polymer such as molecular weight or distance between multiply-bridged biphenylene units. However, such effects will be minimal since only small amounts of L are generally used in these systems.

Model compounds provide another way to determine whether a luminescent compound, group, or repeat unit (L) is useful in the practice of the present invention. This can be achieved, for example, by comparing the visible emission spectra of an unsubstitued L molecule with that of the an unsubstituted multiply-bridged biphenylene monomer unit. Alternatively, visible emission spectra of a diphenyl-substituted L (Ph-L-Ph or L′) can be compared to that of a diphenyl-substituted multiply-bridged biphenylene unit (Ph-MBB-Ph) (in both cases the phenyl groups are substituted at positions where the unit is attached to the polymer chain). If L is monovalent then model compound L′ is Ph-L, and if L is “zero-valent” i.e. not chemically attached to the polymer chain, then L′=L. To be useful, L or L′ must have a lower emission energy than the comparable multiply-bridged biphenylene system. It may also be, useful to compare a model polymer devoid of L groups (MBB-/-Q₂) with the corresponding polymer having formula IV-VIII above.

The above methods for determining the if an L compound is useful in the practice of the present invention does not depend on any particular theory or mechanism of EL device operation. One theoretical argument suggests that in an EL device comprised of a high energy emitter and a low energy emitter, emission solely from the low energy emitter may result from transfer of excited state energy from high energy emitter to low energy emitter. An alternative theoretical argument suggests that emission solely from the low energy emitter may result from recombination of holes and electrons directly on the low energy emitter (i.e., transfer of excited state energy from high energy emitter to low energy emitter is not important). Regardless of whether the emission mechanism is explained by these or some other theory, useful L components may be selected by the methods described above.

In another embodiment, the luminescent compound, unit, or group L, will be protected through incorporation of sterically bulky groups. The bulky groups protect L by preventing it from coming in close proximity with other L -groups or the polymer. The stabilizing effect of bulky groups is well known and the design a molecule L having steric bulk will be understood by one reasonably skilled in the art.

In another embodiment the luminescent compound, unit or group L, will be protected through the placement of inert groups at active positions. For example, it is well known that the radical cation of triphenylamine is very reactive and reacts rapidly with neutral triphenylamine to form tetraphenylbenzidene. However, substitution of the three hydrogens para to the nitrogen with methyl results in the very stable tri-p-tolylamine radical cation. It will be understood by one reasonably skilled in the art how to determine active positions in a material, for example, by alkylation and location of the alkyl groups, and to prepare protected versions of those materials. Protective groups include but are not limited to, alkyl, aryl, halo (preferably F and Cl), cyano, alkoxy, aryloxy, heteroalkyl, and heteroaryl. Additionally, L may be protected with relatively stiff repeat units and side chains (avoiding flexible groups such as long alkyl chains) to allow for higher use temperatures, since polymer degradation may be promoted if the polymer is used above its glass transition temperature.

The multiply-bridged biphenylene polymers of the instant invention may have repeat units, side groups, or end groups that aid in charge transport. These repeat units or groups may aid electron transport or hole transport. Non-limiting examples of hole transport units are triarylamines, benzidenes, and dialkoxyarenes. Some of the non-limiting examples of repeat unit (Q₂) shown above are good hole transport units. Non-limiting examples of electron transport units are oxadiazoles, benzoxazoles, perfluoroarenes, and quinolines. Some of the non-limiting examples of repeat unit Q₂ shown above are also good electron transport units. Any of the divalent structures shown for Q₂ may be used as monovalent groups (e.g., end groups or side groups with only one attachement tot he the polyme chain). The amount of charge transport units or groups may vary from zero to 99%, preferably less than 75%, more preferably less than 50%. Useful amounts of charge transport groups include about 5 mol %, 10 mol %, 15 mol %, 20 mol %, 25 mol %, 30 mol % and 35 mol %. One skilled in the art will know how to prepare a series of polymers incorporating various amounts of charge transport units and be able to evaluate their properties by measuring their charge mobilities. (i.e., by time-of-flight mass spectrometry) or luminescent efficiencies of p-OLED devices prepared from them. It has been suggested that a good luminescent layer will carry electrons and holes equally well, and it is desirable to equalize the hole and electron mobilities through addition or subtraction of charge transport units or groups.

The multiply-bridged biphenylene polymers provided in accordance with the present invention may be used in layers of OLEDs and p-OLEDs other than the luminescent layer, for example, in a charge transport layer. As is known in the art, the charge carrying ability of a conjugated polymer may be enhanced by the incorporation of easily reducible repeat units (enhanced electron transport), easily oxidizable repeat units (enhanced hole transport), or both. Polymer compositions comprising easily oxidizable triarylamines are disclosed in U.S. Pat. No. 6,309,763, which is incorporated herein in its entirety by this reference. Polymer compositions comprising electron transport units are disclosed in U.S. Pat. No. 6,353,083, incorporated herein in its entirety by this reference. Additional carrier transporting repeat units useful in the practice of the present invention are disclosed in U.S. 2002/0064247 and U.S. 2003/0068527, both of which incorporated herein in their entirety by this reference. Additionally, the charge carrying layers of OLEDs and p-OLEDs may have additional functionality, for example, but not limited to, blocking charge carriers of the opposite type, blocking excitons, planarizing the structure, providing means for light to escape the device, and as buffer layers.

When used as any layer in an OLED-or p-OLED the polymers and oligomers of the present invention may be blended or mixed with other materials, including but not limited to, polymeric or small molecule charge carriers, light scatterers, crosslinkers, surfactants, wetting agents, leveling agents, Tg modifiers, and the like. For example, it may be desirable to blend an emissive polymer of the present invention with a hole transporting polymer. Or it may be desirable to blend a polymer of the present invention that emits at relatively high energy with a small molecule emitter or a polymeric emitter that also functions as an electron transport material.

The monomers of the present invention may be prepared by any methods known it the art. Patent application U.S. 2004/0135131 discloses many aryl compounds and their synthesis and is incorporated herein in its entirety by reference.

The polymers of the instant invention may be prepared by any method of aryl coupling polymerization, including but not limited to: Colon reductive coupling of aryldihalides with zinc or other reducing metals catalyzed by nickel or other transition metals; Yamamoto reductive coupling of aryldihalides with an stoichiometric quantities of nickel(0); Yamamoto coupling of aryl halides and aryl Grignard reagents by a nickel catalyst; Stille coupling of aryl halides and aryl tin reagents typically catalyzed by palladium; Suzuki coupling of aryl halides with aryl boronic acids or aryl boronic esters catalyzed by palladium metal, palladium complexes, or palladium salts; Negishi coupling of aryl halides and aryl zinc reagents (typically catalyzed by palladium), Kumada catalytic coupling of aryl halides with either aryl Grignards or aryl lithium reagents; oxidative coupling of electron rich arylenes as for example described in a review by Kovacic and Jones (Chemical Reviews, 1987, vol. 87, pp 357-379); and the like. Examples of Yamamoto and Colon couplings are disclosed in U.S.2004/0170839 and U.S. 2002/0177687, both of which are incorporated herein by reference.

The polymers of the instant invention also may be prepared by any other methods known in the art, including but not limited to Diels-Alder condensations of bis-diene with bis-dienophiles, as disclosed for example by Schilling, et al. (Macromolecules, Vol. 2, pp 85-88, 1969), incorporated herein by reference.

The polymers of the instant invention also may be prepared by graft and block methods. In these cases, an intermediate polymer or oligomer is first formed and arms or chain extensions of another type of polymer are grown off the intermediate polymer. Graft co-polymers and block co-polymers may be useful, for example, to control the polymer morphology, to prevent close approach of polymer chains, or to decrease crystallinity. Graft and block copolymer segments also may be used to control charge transport by, for example, the incorporation of graft or block segments that serve as hole and/or electron transporting chains. Additionally, luminescent groups may be incorporated through the use of grafting or block copolymerization.

Monomers useful for the practice of the present invention include, but are not limited to those shown below as formulas X and XI below. 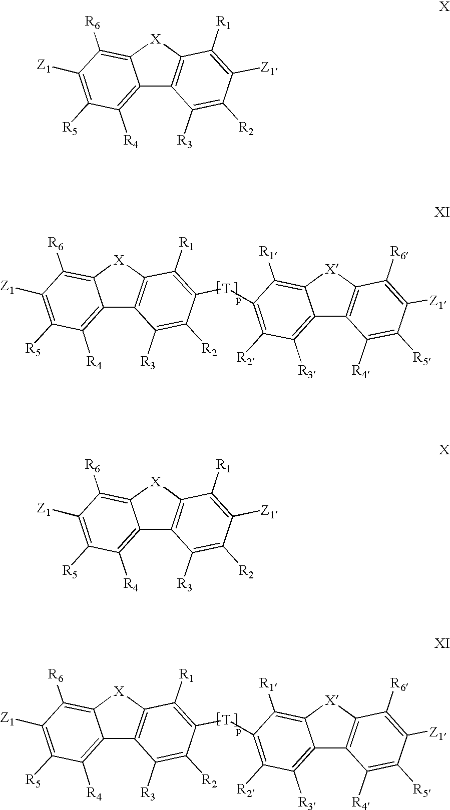
where X is independently selected from the group consisting of 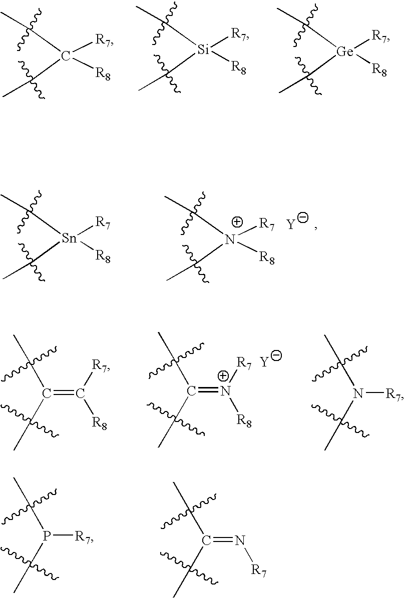
X′ is independently selected from the group consisting of 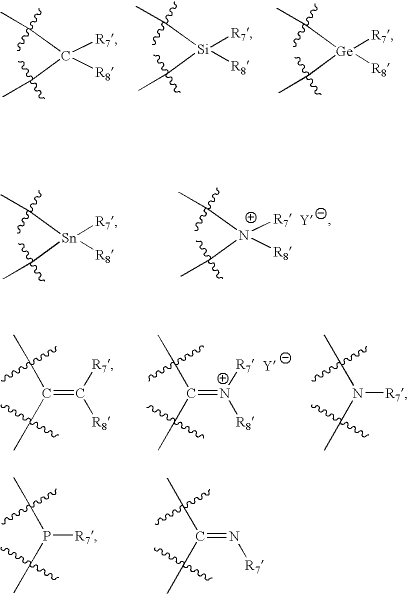
R₁-R8 and R_{1′}-R_{8′} are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
   adjacent R groups may be mutually connected to form a ring structure;
   either or both R₇ and R₈ (if present) or R₇ and R₈, (if present) may or may not form a ring structure;
   any Rₐ and R_{b} (if present) may or may not form one or more ring structures;
   Y⁻ is any mono-valent anionic atom or group;
   p=0-2;
Z₁ and Z_{1′} are independently chosen from the group consisting of halogen atoms, —ArCl, —ArBr, —ArI, —CORₘ, —ArCOₘ, —B(ORₘ)₂, —ArB(ORₘ)₂, 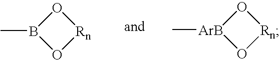
   and T and Ar are independently selected from the group consisting of conjugated units of the formulas: 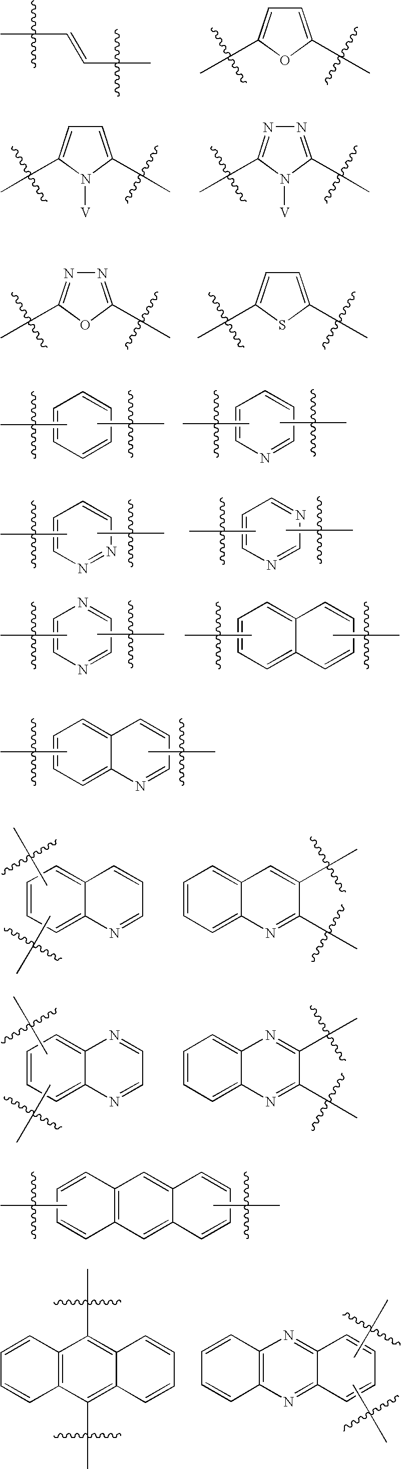 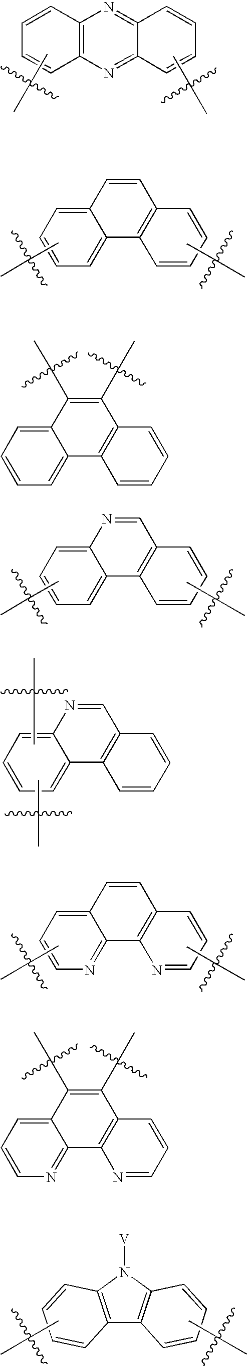 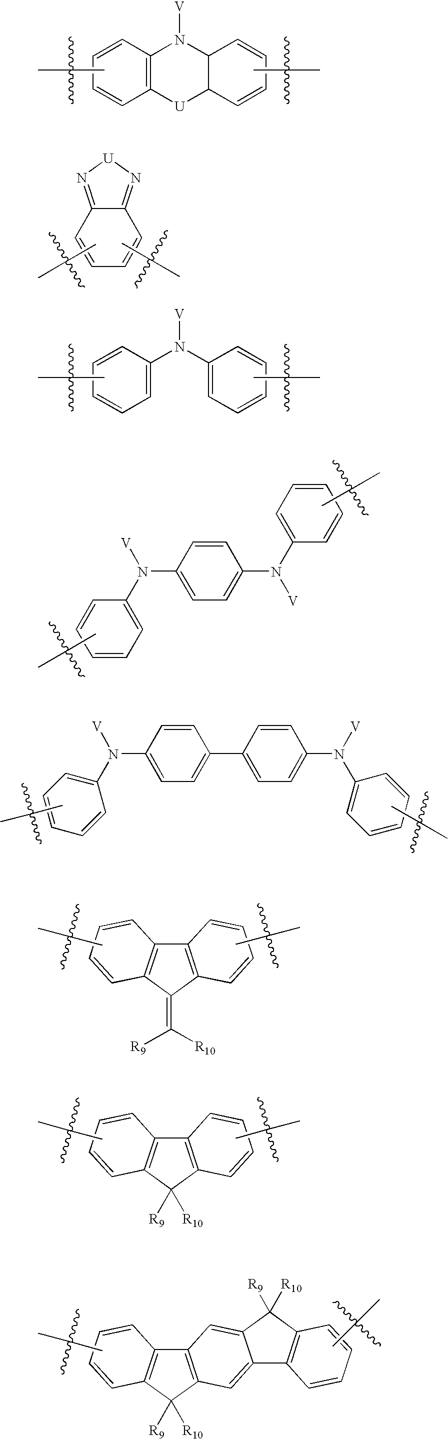 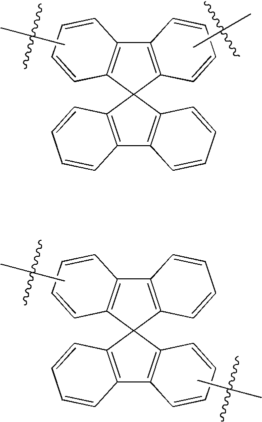
wherein the conjugated units may bear substitutents independently chosen from the group consisting alkyl, substituted alkyl, perfluoro alkyl, alkoxy, substituted alkoxy, aryl, substituted aryl, aryloxy, substituted aryloxy, heteroaryl, substituted heteroaryl, alkyl carbonyloxy, cyano, and fluoro in which
   U is independently selected from —O— and —S—
   and V, R₉, and R₁₀ are each independently selected from the group consisting of alkyl, substituted alkyl, aryl, substituted aryl, heteroaryl, or substituted heteroaryl;
Rₘ is independently chosen from the group consisting of hydrogen, alkyl, substituted alkyl, aryl, substituted aryl, heteroaryl, and substituted heteroaryl;
Rₙ is independently chosen from the group consisting of alkylene, substituted alkylene, and 1,2-phenylene;
and one or more R₇, R₈, R₇, or R₈ is mutually connected to R₁, R₆R_{1′}, or R_{6′} to form a ring system.

Monomers may be prepared by any method. For example, the monomer of formula X, where X is —CR₇R₈—, and Z₁ and Z_{1′} are bromide, may be prepared by the sequence: 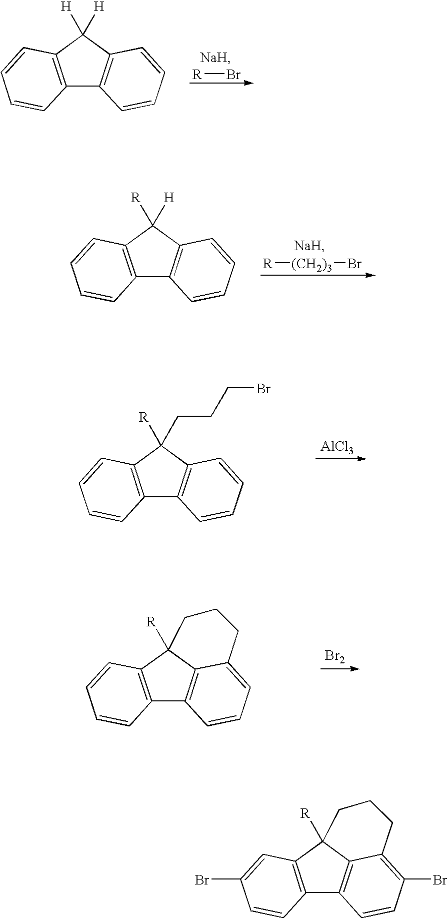
Triply-bridged monomers may be prepared by similar procedures:

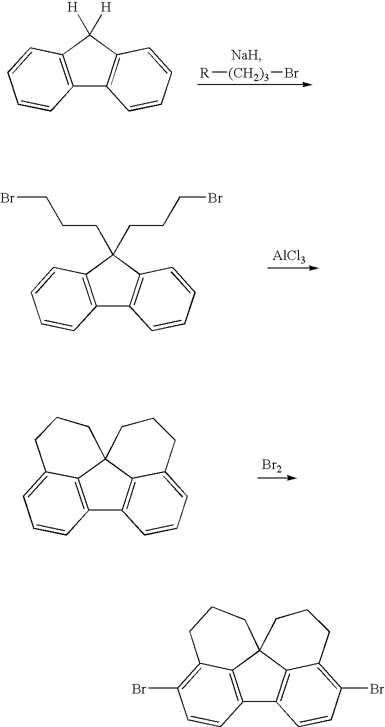

One skilled in the art will know how to replace the 1,3-dibromopropane in the above schemes with another compound having two good leaving groups to form analogous doubly- and triply-bridged monomers.

In one embodiment of the present invention an electroluminescent device is provided having at least one electroluminescent layer comprising a polymer comprising a multiply bridged biphenylene repeat unit provided in accordance with practice of the present invention. Such a device is commonly known as a polymer Organic Light Emitting Diode (p-OLED) and any of the various methods of fabrication and manufacture of such devices may be used. As a non-limiting example, a substrate (for example, glass sheet or polyester film) is coated with a transparent, conducting layer of indium tin oxide (ITO) (commercial ITO on glass or plastic may be used), the ITO is cleaned (for example, by treatment with aqueous peroxide, or treatment in an oxygen plasma), the ITO is coated with a hole injection layer by spin coating and baking (for example, Baytron PO, Bayer), an optional hole transport layer is applied by spin coating and optionally cured or crosslinked, the electroluminescent layer comprising the multiply bridged biphenylene polymer of the present invention and optional additional components, such as hole transport materials, electron transport materials, emissive materials, phosphors or fluorophors, is applied by spin coating (or alternatively by printing (for example, ink jet printing, offset printing, screen printing, flexographic printing and the like), spray coating, curtain coating, roll coating, electrospray coating, or electrodeposition, an optional second EL layer is applied, an optional electron transport layer is applied (for example, aluminum tri(8-hydroxyquinoline), 2-(4-biphenylyl)-5-phenyl-1,3,4-oxadiazole (PBD), or a polymer comprising oxadiazole repeat units, or other electron poor repeat units, by printing, spin coating, spray coating, electrospray coating or vacuum evaporation), an optional buffer layer is applied (for example, lithium fluoride or cesium fluoride by vacuum evaporation), an electrode is applied (for example, Al, Ca, Ba, Mg—Ag alloy and the like, by vacuum evaporation, sputtering or other techniques known in the art), and optionally a hermetic sealing layer or container is applied.

P-OLED structures useful for the present invention include, but are not limited to the following layer sequences:
A. 1. glass, 2. ITO, 3. PEDOT/PSS (e.g. Baytron P®, Bayer), 4. EL layer, 5. CsF, 6. Al, 7. metal cap sealed with epoxy thermoset glue.
B. 1. plastic substrate, 2. ITO, 3. PEDOT/PSS (e.g. Baytron P®, Bayer), 4. EL layer, 5. LiF, 6. Al, 7. hermetic sealing layer.
C. 1. glass, 2. ITO, 3. hole transport layer comprising an arylamine compound, either as a small molecule, oligomer or polymer, 4. EL layer, 5. CsF, 6. Al, 7. metal cap sealed with epoxy thermoset glue.

In these structures, the electroluminescent layer is sandwiched between the transparent (typically ITO) electrode and the rear (typically metal) electrode, with additional optional layers for hole injection, hole transport, electron injection, electron transport and buffer layer. The entire p-OLED structure is a multilayer electroluminescent device. Means for connecting to external circuitry are provided.

The EL layer in p-OLEDs is preferably between 5 and 500 nm thick, more preferably between 10 and 250 nm, and most preferably between 20 and 100 nm. The EL layer is preferably applied by a coating technique, preferably spin coating or spray coating. The EL layer may be patterned to form shapes or pixels by any technique known in the art, including lithography, ink jet printing, or screen printing.

The p-OLEDs of the present invention may be used as a flat light source, often referred to as Solid State Lighting (SSL). In this application each p-OLED element has a relatively large area, typically between 1 cm² and 1 m², although larger or smaller devices may be useful. A large flat light source or panel may be divided into more than one smaller sub-panels or p-OLEDs for ease of manufacture or installation, or to achieve different color or variable color light output by controlling power to differently colored sub-panels or p-OLEDs.

A segmented display, for example, a numeric or alphanumeric display, will have several small p-OLED devices arranged such that activation of particular subsets of the p-OLEDs will produce a light output in the form of a letter or number. One skilled in the art will know how to use the p-OLEDs of the present invention to produce segmented displays.

A dot-matrix display is any display, monochrome, or color, having individually addressable pixels or picture elements, each appearing as a small dot, whose light output can be controlled to form a picture or display information. The polymers and p-OLED devices of the present invention may be used with any display architecture known in the art. The displays may be passive matrix or active matrix. Each pixel or dot may be controlled by a transistor or multiple transistors, which may be polycrystalline silicon, amorphous silicon, or organic.

An LCD is a liquid crystal display, which is typically comprised of the following elements: a backlight, a polarizer, an array or matrix of liquid crystal cells each with associated transparent electrodes and driving transistors, and a second polarizer or analyzer. The p-OLEDs of the present invention may be used as the backlight of a LCD, or, if the p-OLED emits polarized light, as the backlight and polarizer.

A field effect transistor is a transistor that makes use of the field established in a p-type or n-type channel semiconductor material to control the flow of current through the channel. An organic field effect transistor is an electronic device comprised of an organic material channel, typically as a thin layer, having three electrodes, a source, a drain and a gate, where the gate is separated from direct contact with the organic material by a thin insulating layer. An electric field applied to the gate electrode can control a current through the source and drain electrodes. The multiply bridged biphenylene polymers of the present invention may be used as the organic material in an organic field effect transistor. An organic thin film transistor may be an organic field effect transistor or an organic bipolar transistor.

A bipolar transistor is a three-terminal semiconductor component with a three-layer structure of alternate negative and positive type materials (NPN or PNP). It provides current gain and voltage amplification in a circuit. The MBB containing polymers of the present invention may be used as N- or P-type layers in bipolar transistors.

A photovoltaic device is any structure that produces an electrical voltage in response to irradiation by light. A non-limiting example of an organic photovoltaic device is a transparent electrode, (e.g. ITO on glass), one or more organic layers, and a back electrode (e.g. Al). The organic layer(s) is typically chosen such that one side is more electron rich and the other side more electron poor. This may be accomplished by addition or inclusion of electron donating compounds or repeat units or electron accepting compounds or repeat units. The multiply bridged biphenylene polymers of the present invention may be used as the organic layers in an organic photovoltaic device. One skilled in the art will know how to incorporate or include electron donors or acceptors into the MBB polymers to make them electron rich or electron poor. For example, the hole transport units discussed above are generally good donors and the electron transport units generally good acceptors. Photovoltaic devices have use a solar cells, supplying electricity from sunlight.

A photodetector device is a photovoltaic device, typically having high efficiency, used for detection of light.

An electrical switching device is any device wherein a small applied electric potential is used to control a large electric current. One skilled in the art will know how to construct electrical switching devices from one or more transistors. The MBB polymers of the present invention may be used to form organic transistors that may be used as electrical switching devices.

An optoelectric device is any device that may be used to control a light, typically in a beam or confined to a fiber optic or wave-guide channel, through application of an electric field. Optoelectric devices may be used a optical switches, modulators, amplifiers, and the like, and have application in the area of telecommunications.

Preparation of p-OLED devices is described in US 2003/0045642 and US 2004/0127666, both incorporated herein by reference, and one with reasonable skill in the art will know how to prepare analogous devices using the compositions of the present invention.

Zheng et al, US 2004/0241496, incorporated herein if full by reference, discloses methods of fabrication of p-OLED devices useful in the practice of the present invention in Example 36 as follows:

An EL device satisfying the requirements of the invention was constructed in the following manner. The organic EL medium has a single layer of the organic compound described in this invention.
a) An indium-tin-oxide (ITO) coated glass substrate was sequentially ultra-sonicated in a commercial detergent, rinsed with deionized water, degreased in toluene vapor and exposed to ultraviolet light and ozone for a few minutes.
b) An aqueous solution of PEDOT (1.3% in water, Baytron P Trial Product Al 4083 from H. C. Stark) was spin-coated onto ITO under a controlled spinning speed to obtain thickness of 500 Angstroms. The coating was baked in an oven at 110° C. for 10 min.
c) A toluene solution of a compound (300 mg in 30 mL of solvent) was filtered through a 0.2 μm Teflon filter. The solution was then spin-coated onto PEDOT under a controlled spinning speed. The thickness of the film was between 500-700 Ang-stroms.
d) On the top of the organic thin film was deposited a cathode layer consisting,of 15 angstroms of a CsF salt, followed by a 2000 angstroms of a 10:1 atomic ratio of Mg and Ag.

The above sequence completed the deposition of the EL device. The device was then hermetically packaged in a dry glove box for protection against ambient environment.

US 2004/0241496 also discloses various small molecules, monomers, and polymers that when incorporated into electroluminescent devices emit light, including blue light. For example, the following fluorescent dopants may be used to dope the MBB polymers of the present invention:

Such useful fluorescent dopants (FD) include but are not limited to derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, and carbostyryl compounds. Useful phosphorescent dopants (PD) include but are not limited to organometallic complexes of transition metals of iridium, platinum, palladium, or osmium. Illustrative examples of useful dopants include, but are not limited to, the following:

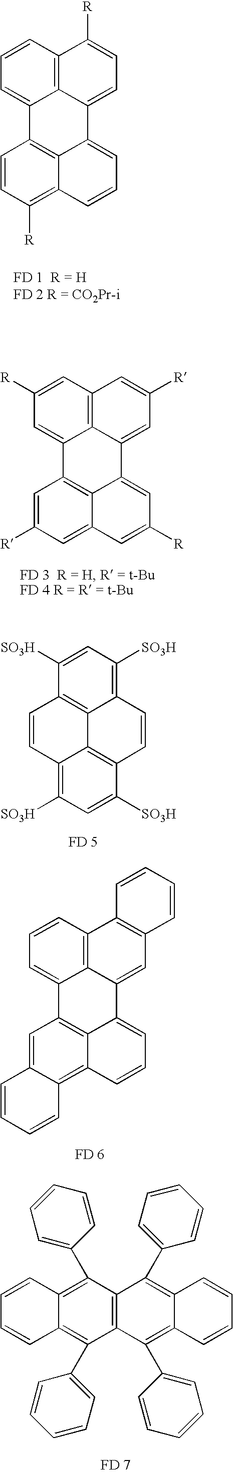

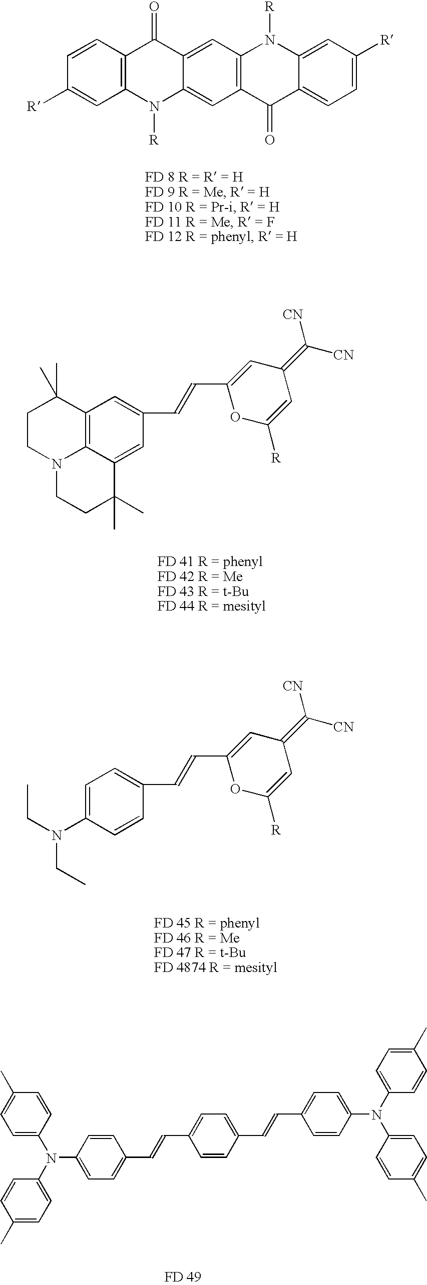

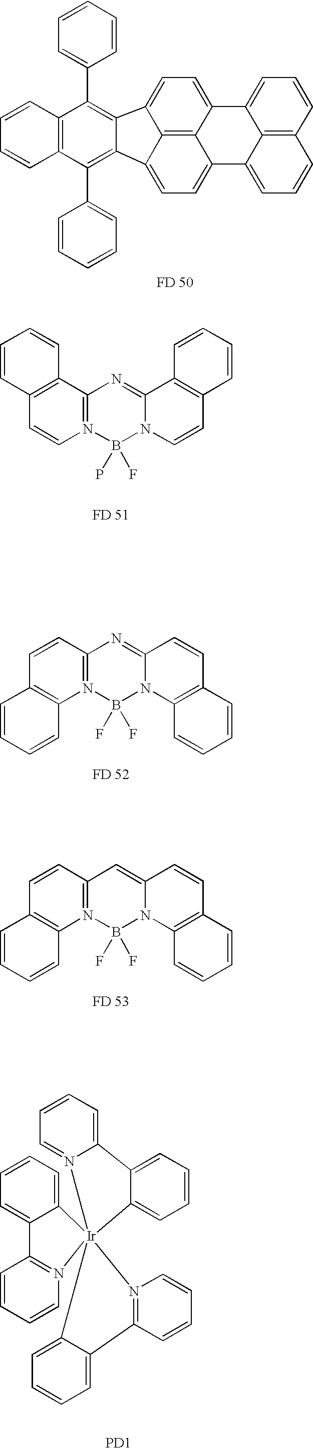

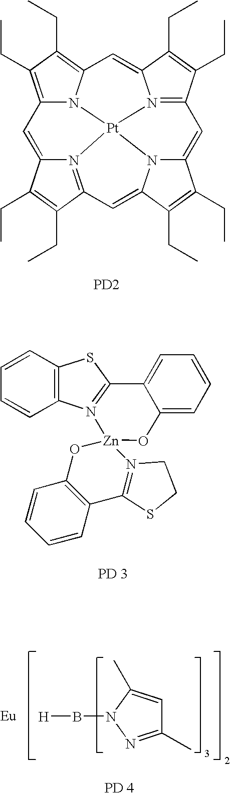

One skilled in the art will know how to use these small molecules, monomers and polymers in conjunction with the present invention. For example, the light emitting small molecules or polymers, particularly those disclosed in US 2004/0241496, may be blended with the MBB polymers of the present invention and the blend used as the emissive layer in a p-OLED), or the monomers, particularly the bisboronic esters, dibromides, and bistriflates disclosed in US 2004/0241496 may be used as co-monomers with the MBB monomers of the present invention to prepare co-polymers comprising MBB repeat units and blue emitcting repeat units. Anodes, cathodes, hole transport materials and other p-OLED components disclosed in US 2004/0241496 are also useful in conjunction with the MBB polymers of the present invention.

Another aspect of this invention are the films formed from the polymers provided in accordance with practice of the present invention. Such films can be used in polymeric light emitting diodes, photovoltaic cells and field effect transistors. Preferably such films are used as emitting layers or charge carrier transport layers. The films may also be used as protective coatings for electronic devices and as fluorescent coatings. The thickness of the film or coating is dependent upon the use.

Generally, such film thickness can be from about 0.005 to 200 micron. When the coating is used as a fluorescent coating, the coating or film thickness is preferably from about 50 to about 200 microns. When the coatings are used as electronic protective layers, the thickness of the coating can be from about 5 to about 20 microns. When the coatings are used in a polymeric light-emitting diode, the thickness of the layer formed is preferably from about 0.005 to 0.2 microns. The polymers of the invention form good pinhole and defect-free films.

The films are readily formed by coating the polymer composition provided- in accordance with the present invention wherein the composition comprises such a polymer and at least one organic solvent. Preferred solvents are aliphatic hydrocarbons, chlorinated hydrocarbons, aromatic hydrocarbons, ketones, ethers and mixtures thereof. Additional solvents which can be used include 1,2,4-trimethylbenzene, 1,2,3,4-tetramethyl benzene, pentylbenzene, mesitylene, cumene, cymene, cyclohexylbenzene, diethylbenzene, tetralin, decalin, 2,6-lutidine, 2-fluoro-m-xylene, 3-fluoro-o-xylene, 2-chlorobenzotrifluoride, dimethylformamide, 2-chloro-6-fluorotoluene, 2-fluoroanisole, anisole, 2,3-dimethylpyrazole, 4-fluoroanisole, 3-fluoroanisole, 3-trifluoromethylanisole, 2-methylanisole, phenetol, 4-methylansiole, 3-methylanisole, 4-fluoro-3-methylanisole, 2-fluorobenzonitrile, 4-fluoroveratrol, 2,6-dimethylanisole, 3-fluorobenzonitrile, 2,5-dimethylanisole, 2,4-dimethylanisole, benzonitrile, 3,5-dimethylanisole, N,N-dimethylaniline, ethyl benzoate, 1-fluoro-3,5-dimethoxybenzene, 1-methylnaphthalene, N-methylpyrrolidinone, 3-fluorobenzotrifluoride, benzotrifluoride, dioxane, trifluoromethoxybenzene, 4-fluorobenzotrifluoride, 3-fluoropyridine, toluene, 2-fluorotoluene, 2-fluorobenzotrifluoride, 3-fluorotoluene, 4-isopropylbiphenyl, phenyl ether, pyridine, 4-fluorotoluene, 2,5-difluorotoluene, 1-chloro-2,4-difluorobenzene, 2-fluoropyridine, 3-chiorofluorobenzene,- 3-chIorofluorobenzene, 1-chloro-2,5-difluoro-benzene, 4-chlorofluorobenzene, chlorobenzene, o-dichlorobenzene, 2-chlorofluorobenzene, p-xylene, m-xylene, o-xylene or mixture of o-, m-, and p-xylene isomers. It is preferable that such solvents have relatively low polarity. High boiling solvents and solvent mixtures are better for ink jetting, but xylenes and toluene are best for spin coating. Preferably the solution contains from about 1 to 5 percent of a polymer comprising a repeat unit of Formula 1 and/or a repeat unit of Formula 1 and a repeat unit of Formula 2.

Films can be prepared by means well known in the art including spin-coating, spray-coating, dip-coating, roll-coating, offset printing, ink jet printing, screen printing, stamp-coating or doctorblading.

As used herein, luminescent means the property of emitting light upon stimulation. Stimulation may be by electromagnetic radiation of any frequency, including visible light (photoluminescent), X-rays, gamma rays, infra-red, and ultra-violet, by electron beam, by heat or by any other energy source. Luminescent and photoluminescent include fluorescent and phosphorescent. Fluorescence is luminescence having a shorter decay time and generally refers to luminescence from an excited singlet state to the ground state, or any highly allowed transition. Phosphorescence is luminescence having a longer decay time and generally refers to luminescence from an excited triplet state to a singlet ground state or to a forbidden transition.

As used herein, the term transition metals includes group IIIB, IVB, VB, VIB, VIIB, VIII, IB and IIB elements.

### EXAMPLES

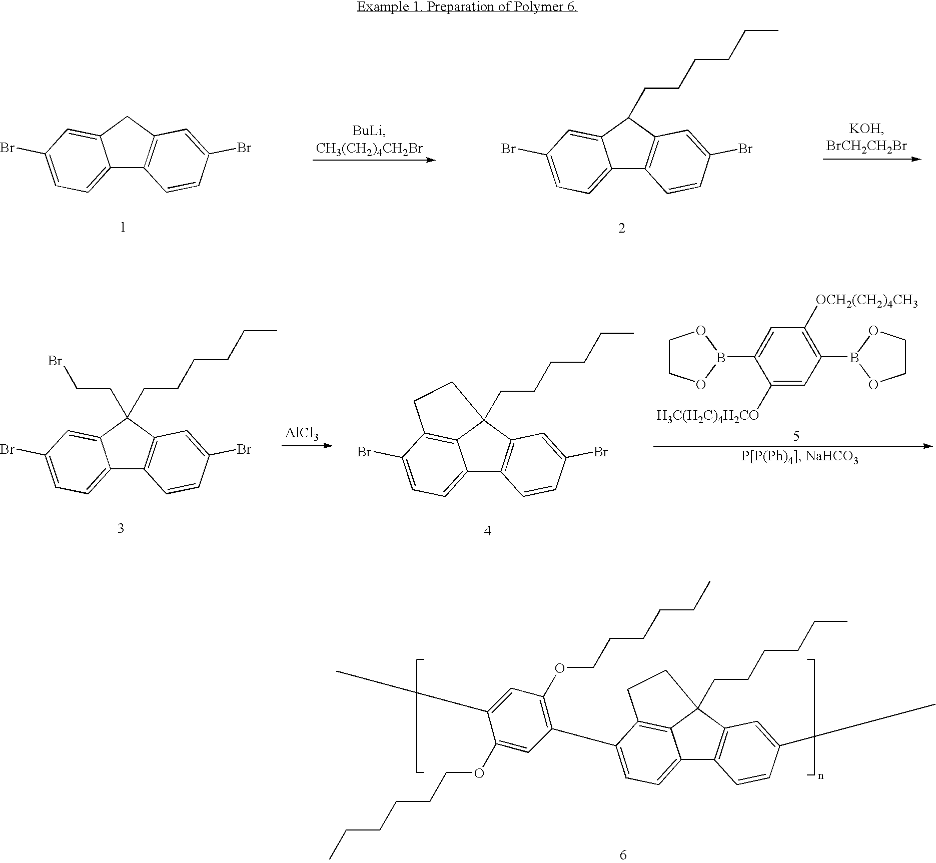

Preparation of 2,7-dibromo-9-hexylfluorene (2): To a solution of 2,7-dibromofluorene (1, 0.060 mol) in dry THF (200 mL), under argon and at −78° C., is added 1.5 M solution of n-butyllithium in THF (0.060 mol) over a 45 min period. After the addition, the temperature of the reaction mixture is allowed to rise to room temperature and stirred for 1 h. The mixture is then cooled to −78° C. and a solution of n-hexylbromide (0.060 mol) in THF (10 mL) is added over a 45-min period. The temperature of the reaction mixture is then allowed to rise to room temperature and allowed to stir for 12 h. The solution is neutralized with a 10% HCl solution and the THF is removed in vacuo. The resulting oil is purified by chromatography.

Preparation of 2,7-dibromo-9-hexyl-9-(2-bromoethyl)fluorene (3): To a mixture containing aqueous potassium hydroxide (50 mL, 50%), tetrabutylammonium bromide (1 mmol), and 1,2-dibromoethane (25 mmol) at 75° C. is added 2 (5 mmol). After 15 min, the mixture is cooled to room temperature. After extraction with CH₂Cl₂, the organic layers are successively washed with water, aqueous HCl (1 M), water, and brine. The final organic layer is dried over magnesium sulfate and filtered. The mother liquor is condensed in vacuo, and the resulting oil is purified by chromatography.

Preparation of 4: To a solution containing 3 (0.75 mmol) and CH₂Cl₂ (15 mL) is added aluminum trichloride (0.75 mmol), and the resulting mixture is stirred at room temperature for 16 h. The solution is then diluted with 2 M aqueous HCl (15 mL) and water (15 mL). The organic layer is separated, diluted with CH₂Cl₂ (20 mL), and washed with water (20 mL), dried over magnesium sulfate, and filtered. The final mother liquor is condensed in vacuo, and the resulting oil is purified by chromatography.

Preparation of 6: A two-necked, round-bottomed flask is charged with 4 (1.5 mmol), 5 (1.5 mmol), tetrakis(triphenylphosphino)palladium (0.2 mmol), and sodium bicarbonate (20.2 mmol). The flask is sealed with a septum and de-aerated with nitrogen. Degassed water (20 mL) and degassed THF (20 mL) are successively added to the mixture via syringe. The resulting mixture is allowed to stir at reflux for 3 days and then poured into methanol. The resulting precipitate is collected by filtration and washed with copious amounts of water, methanol, and acetone. The crude product is redissolved in chloroform and the product is coagulated by adding methanol to the solution. The product is collected by filtration and dried in vacuo.

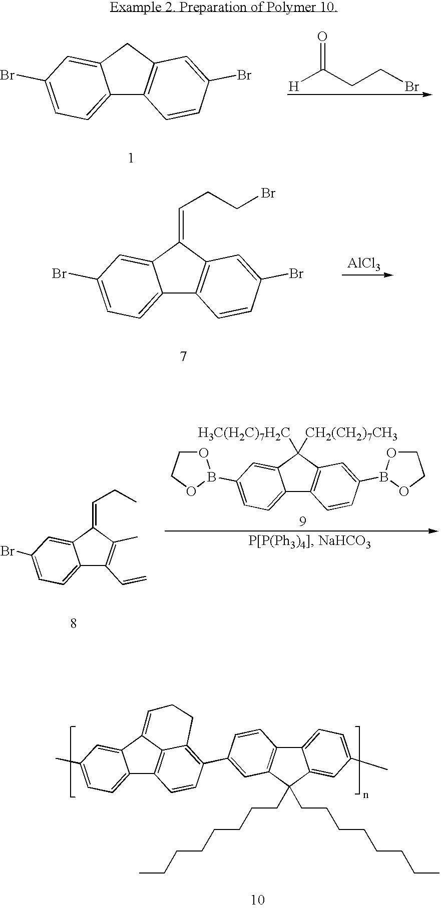

Preparation of 2,7-dibromo-9-(3-bromopropylidenyl)fluorene (7): To a stirred suspension of 2,7-dibromofluorene (1, 27 mmol) in pyridine (30 mL) at 0° C. under nitrogen is added a 1 M solution of tetrabutylammonium hydroxide in methanol (6 mL). A solution of 3-bromopropanal (32 mmol) in pyridine (25 mL) is then added over a ten-minute period, and the solution is allowed to stir at room temperature for 2 h. The mixture is poured into 300 mL of ice water, stirred for 3 h, and the resulting solid is collected by filtration and purified by chromatography.

Preparation of 8: To a solution containing 7 (0.75 mmol) and CH₂Cl₂ (15 mL) is added aluminum trichloride (0.75 mmol) and the resulting mixture is stirred at room temperature for 16 h. The solution is then diluted with 2 M aqueous HCl (15 mL) and water (15 mL). The organic layer is separated, diluted with CH₂Cl₂ (20 mL), and washed with water (20 mL). The final organic layer is condensed in vacuo, and the resulting oil is purified by chromatography.

Preparation of 10: A two-necked, round-bottomed flask is charged with 8 (1.5 mmol), 9 (1.5 mmol), tetrakis(triphenylphosphino)palladium (0.2 mmol), and sodium bicarbonate (20.2 mmol). The flask is sealed with a septum and de-aerated with nitrogen. Degassed water (20 mL) and degassed THF (20 mL) are successively added to the mixture via syringe. The resulting mixture is allowed to stir at reflux for 3 days and then poured into methanol. The resulting precipitate is collected by filtration and washed with copious amounts of water, methanol, and acetone. The crude product is redissolved in chloroform and the product is coagulated by adding methanol to the solution. The product is collected by filtration and dried in vacuo.

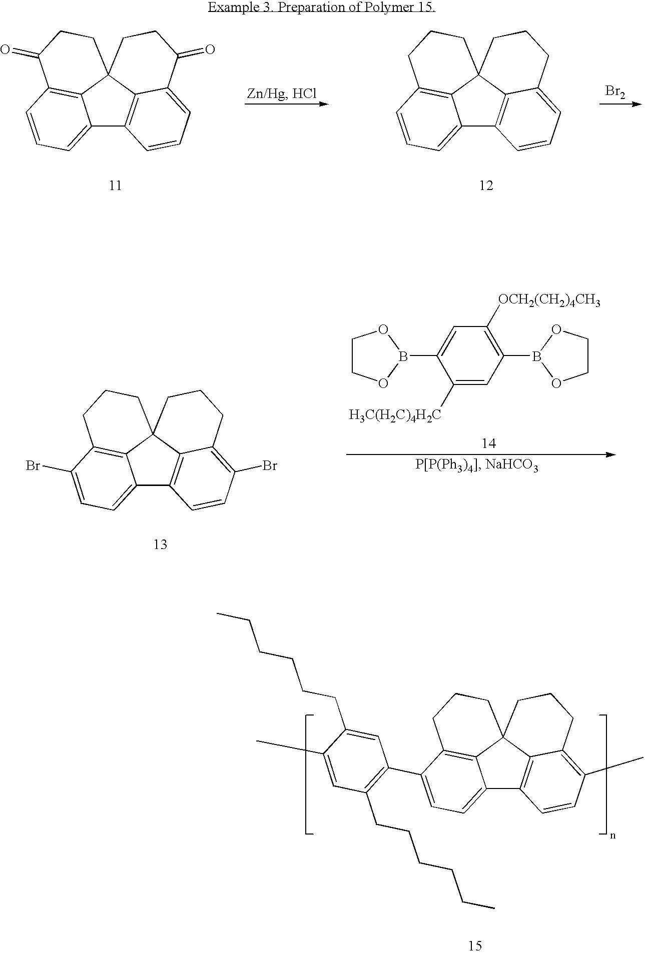

Preparation of 1,2,11,12-tetrahydro-benzo[h,i]fluoranthene (12): To a mixture of concentrated HCl (50 mL), water (10 mL), and amalgamated zinc (200 g) is added 1,2,11,12-tetrahydro-benzo[h,i]fluoranthene-3,10-dione (11, 83 mmol). The reaction flask is fitted with a gas inlet tube, and HCl gas is bubbled through the solution while the mixture is slowly heated to reflux. After refluxing for 16 h, the solvent is removed in vacuo, and the product is purified by chromatography.

Preparation of 13: To a solution of 12 (158 mmol) in chloroform (200 mL) at −78° C. are added ferric chloride (400 mg) and 2,6-di-t-butyl-4-methylphenol (20 mg). Bromine (335 mmol) is added drop wise to the mixture while the reaction set up is protected from light. The mixture is warmed to room temperature and allowed stirred for 16 h. The resulting slurry is then poured into water, and the aqueous layer is separated and extracted with chloroform. The combined organic layers are then washed with aqueous sodium thiosulfate, dried over magnesium sulfate, filtered, and condensed. The product is purified by chromatography.

Preparation of 15: A two-necked, round-bottomed flask is charged with 13 (1.5 mmol), 14 (1.5 mmol), tetrakis(triphenylphosphino)palladium (0.2 mmol), and sodium bicarbonate (20.2 mmol). The flask is sealed with a septum and de-aerated with nitrogen. Degassed water (20 mL) and degassed THF (20 mL) are successively added to the mixture via syringe. The resulting mixture is allowed to stir at reflux for 3 days and then poured into methanol. The resulting precipitate is collected by filtration and washed with copious amounts of water, methanol, and acetone. The crude product is redissolved in chloroform and the product is coagulated by adding methanol to the solution. The product is collected by filtration and dried in vacuo.

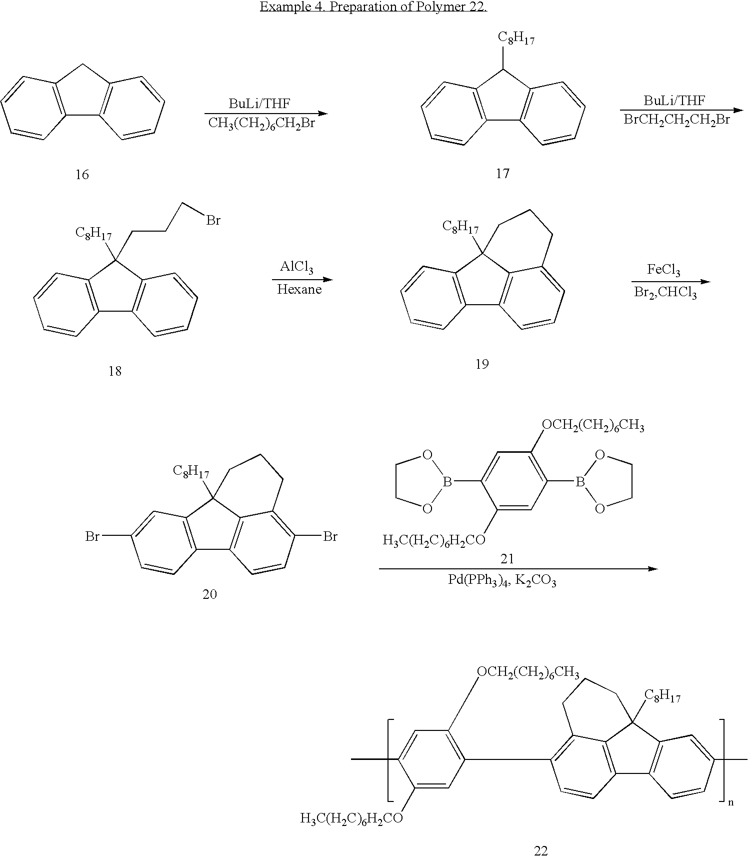

Preparation of 9-octylfluorene (17) To a solution of fluorene (16, 0.060 mol) in dry THF (90 mL), under nitrogen and at −80° C., was added 2.5 M solution of n-butyllithium in hexane (0.060 mol) over a 15 min period. After the addition, the temperature of the reaction mixture was allowed to rise to room temperature. The mixture was then cooled to −80° C. and a solution of n-octylbromide (0.060 mol) in THF(10 mL) was added dropwise. After the addition, the reaction mixture was allowed to stir at this low temperature for 1 h and was then allowed to rise to room temperature for 3.5h. Water was added to the reaction mixture. The product was extracted with CH₂Cl₂ (3×50 mL) and purified by chromatography. A pale solid was collected (14 g).

Preparation of 9-bromopropyl-9-octylfluorene (18) To a solution of 9-octylfluorene (17, 0.013 mol) in dry THF (30 mL), under nitrogen and at −80° C., was added a 2.5 M solution of n-butyllithium in hexane (0.015 mol) over a 15 min period. After the addition, the temperature of the reaction mixture was allowed to rise to room temperature. The mixture was then cooled to −80° C. and 1,3-dibromopropane (0.015 mol) was added slowly. After the addition, the reaction mixture was allowed to stir at this low temperature for 20 min and was then allowed to rise to room temperature overnight. After the addition of water to the reaction mixture, the product was extracted with CH₂Cl₂ (3×40 mL) and dried over magnesium sulfate. After removal of CH₂Cl₂, the unreacted 1,3-dibromopropane was distilled off under vacuum to give the desired product (5.1 g).

Preparation of 10b-octyl-1,2,3,10b-tetrahydrofluoranthene (19) To a solution of 9-bromopropyl-9-octylfluorene (18, 0.013 mol) in hexane (150 mL), under nitrogen and at room temperature, was added aluminum trichloride powder (0.013 mol). The resulting mixture was allowed to stir at room temperature for 16 h before addition of water to quench the reaction. The product was extracted with CH₂Cl₂ (3×50 mL). After removal of CH₂Cl₂, the crude product was purified by flash column chromatography. White solid was collected (3.65 g).

Preparation of 4,9-dibromo-10b-octyl-1,2,3,10b-tetrahydrofluoranthene (20) A 250 mL flask was charged with 10b-octyl-1,2,3,10b-tetrahydrofluoranthene (19, 0.005 mol), chloroform (20 mL), iron(III) chloride (36 mg), BHT (10 mg) and a magnetic stir bar. To the resulting solution, under nitrogen and at 0° C., bromine (0.010 mol) was added over a 15 min period whle stirring. After the addition, the temperature of the reaction mixture was allowed to rise to room temperature and stirred over night (15 h). The reaction was quenched with aqueous sodium thiosulfate and the product was extracted with CH₂Cl₂ (3×35 mL) and dried over magnesium sulfate. The pure product was collected after column chromatography (1.13 g).

Polymer (22) To a 40 mL of glass vial, was added 2,5-dihexyloxybenzene-1,4-diboronic acid ethylene glycol ester (37, 0.229 g, 0.506 mmol) and 4,9-dibromo-10b-octyl-1,2,3,10b-tetrahydrofluoranthene (36, 0.241 g, 0.506 mmol). The vial was transferred to a glove box. In the glove box, toluene (1.16 mL), Aliquat 336 in toluene (60%, 0.35 mL) and tetrakis (triphenylphosphine) palladium in toluene (0.0104 M, 0.49 mL) were added to the vial. The vial was sealed and transferred out of glove box. Subsequently, 0.8 mL of 2M degassed aqueous potassium carbonate was injected into the vial. The vial was heated on an orbital shaker at 95° C. for 24 hours. After cooling to room temperature, the polymer dope was diluted with toluene into 7 mL and filtered by a 0.2μ syringe filter. The resulted solution was added to a stirred solution of 180 mL of methanol and 20 mL of water.

The collected polymer was dissolved in 5 mL of toluene and poured into a stirred solution of 140 mL of methanol and 50 mL of acetone. The polymer was dried in a vacuum oven at 65° C. overnight. The molecular weight was determined by gel permeation chromatography against polystyrene standards to be Mw=42,419; Mn=19,687.

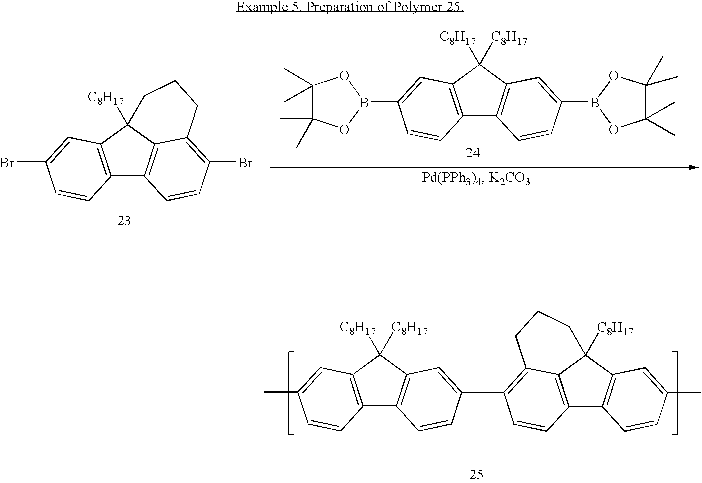

Preparation of Polymer (25) To a 40 mL of glass vial was added 9,9-dioctylfluorene, 2,7-diboronic acid pinacol ester (24, 0.341 g, 0.520 mmol), 4,9-dibromo-10b-octyl-1,2,3,10b-tetrahydrofluoranthene (23, 0.248 g, 0.520 mmol). The vial was transferred to a glove box, and toluene (1.15 mL), Aliquat 336 in toluene (60%, 0.35 mL) and tetrakis(triphenylphosphine) palladium in toluene (0.0104 M, 0.50 mL) were added. The vial was sealed, transferred out of the glove box, and 2M degassed aqueous potassium carbonate (0.8 mL) was injected into the vial. The vial was heated on an orbital shaker at 95° C. for 17 hours.

After cooling to room temperature, the polymer dope was diluted to a total volume of 7 mL with toluene and filtered through a 0.2μ syringe filter. The solution was added to a stirred solution of 180 mL of methanol and 20 mL of water and the resulting precipitate was collcted by filtration. The solid was dissolved in 5 mL of toluene and poured into a stirred solution of 140 mL of methanol and 50 mL of acetone. The solid was again collected by filtration and dried in vacuo at 65° C. (16 h). The molecular weight was determined by gel permeation chromatography against polystyrene standards to be Mw=74,007 ; Mn=28,778.

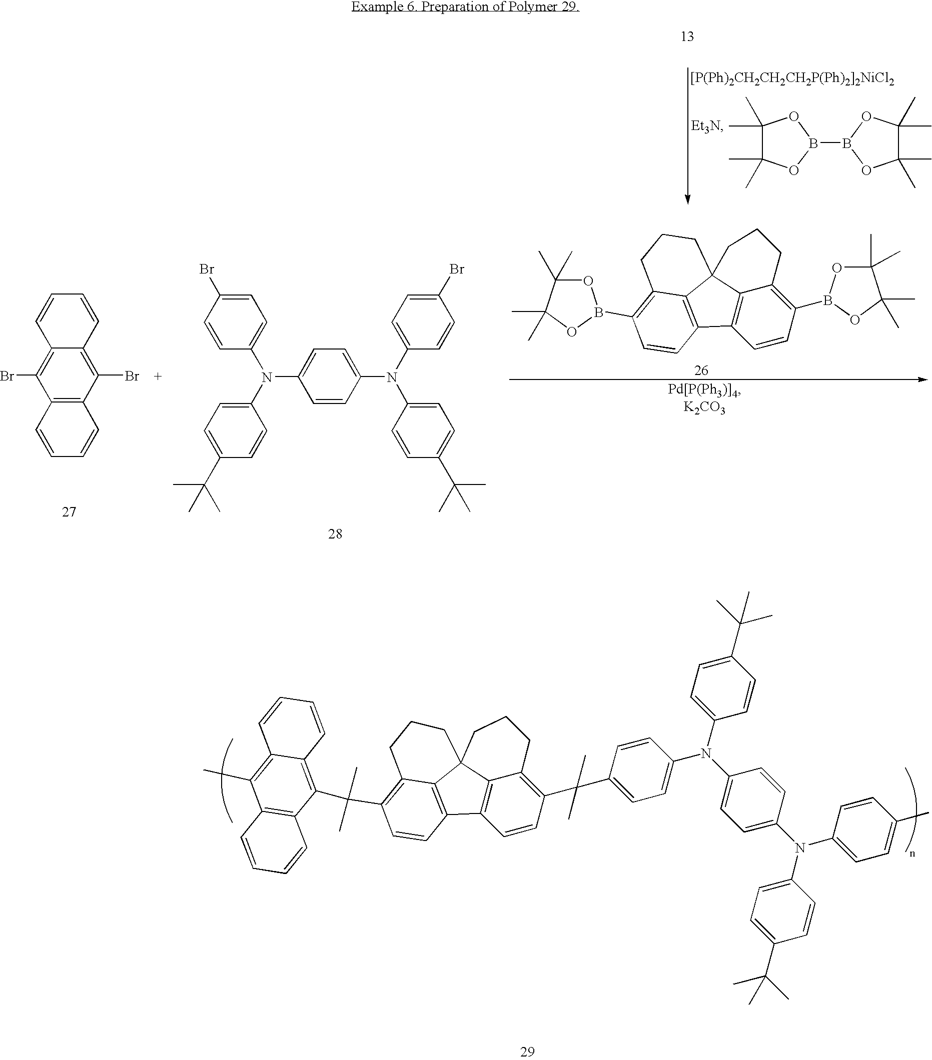

Preparation of 26: In an inert atmosphere box a three neck round bottom flask is charged with pinacol borane (4.4 mL, 30 mmol), 13 (10 mmol), 1,3-bis(diphenylphosphino)propane nickel (II) dichloride (0.33 g, 6 mol %), triethylamine (11.2 mL), and 35 mL anhydrous toluene. The flask is removed from the inert atmosphere box and connected to a nitrogen flushed condenser. The mixture was heated under nitrogen for 18 hr at 95° C. The reaction is cooled to room temperature, water added and extracted with toluene. Toluene is removed under vacuum and the residue recrystallized from methanol.

Preparation of Co-Polymer 29: A 40 mL glass vial is charged with 26 (0.52 mmol), 9,10-dibromoanthracene 27 (0.1 mmol), 28 (0.4 mmol), palladium tetrakistriphenylphosphine (0.0052 mmol, 1 mol % based on bisboronic ester), three 5mm glass beads, 0.8 mL 2M aqueous potassium carbonate, Aliquat 336 (0.2 mL), and toluene (1.8 mL), sealed with a septum cap, flushed with nitrogen, and heated in an orbital shaker at 95° C. for 24 hr. The toluene layer is diluted to 10 mL, filtered through 0.2 micron filter, coagulated into 9/1 methanol/water, the coagulated polymer is then twice redissolved and coagulated into methanol/acetone 75/25, then dried in a vacuum oven at 60° C. overnight.

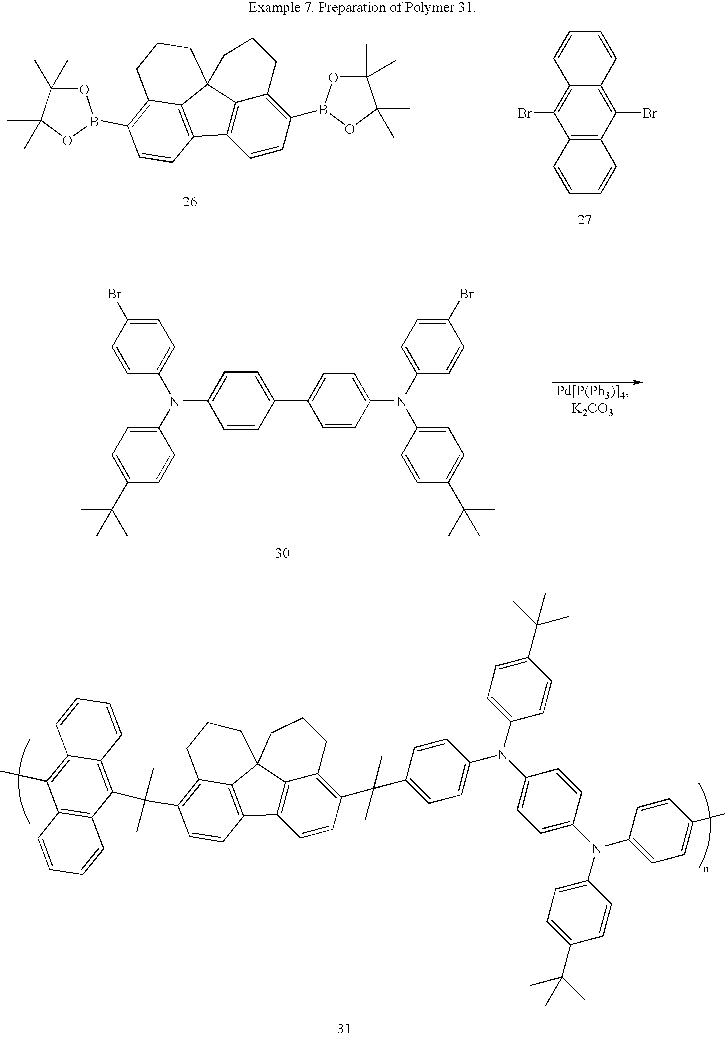

Preparation of Co-Polymer 31: In an inert atmosphere box, a 40 m glass vial is charged with 26 (0.52 mmol), 9,10-dibromoanthracene 27 (0.1 mmol), 30 (0.4 mmol), palladium tetrakistriphenylphosphine (0.0052 mmol, 1 mol % based on the bisboronic ester), three 5mm glass beads, Aliquat 336 (0.2 mL), and toluene (1.8 mL), and sealed with a septum cap. The vial is removed from the inert atmosphere box and 0.8 mL degassed (with nitrogen) 2M aqueous potassium carbonate is added by syringe. The vial is heated in an orbital shaker at 95° C. for 24 hr. The toluene layer is separated, diluted to 10 mL, filtered through 0.2 micron filter, and coagulated into 9/1 methanol/water. The coagulated polymer is then twice redissolved and coagulated into methanol/acetone 75/25, then dried in a vacuum oven at 60° C. overnight.

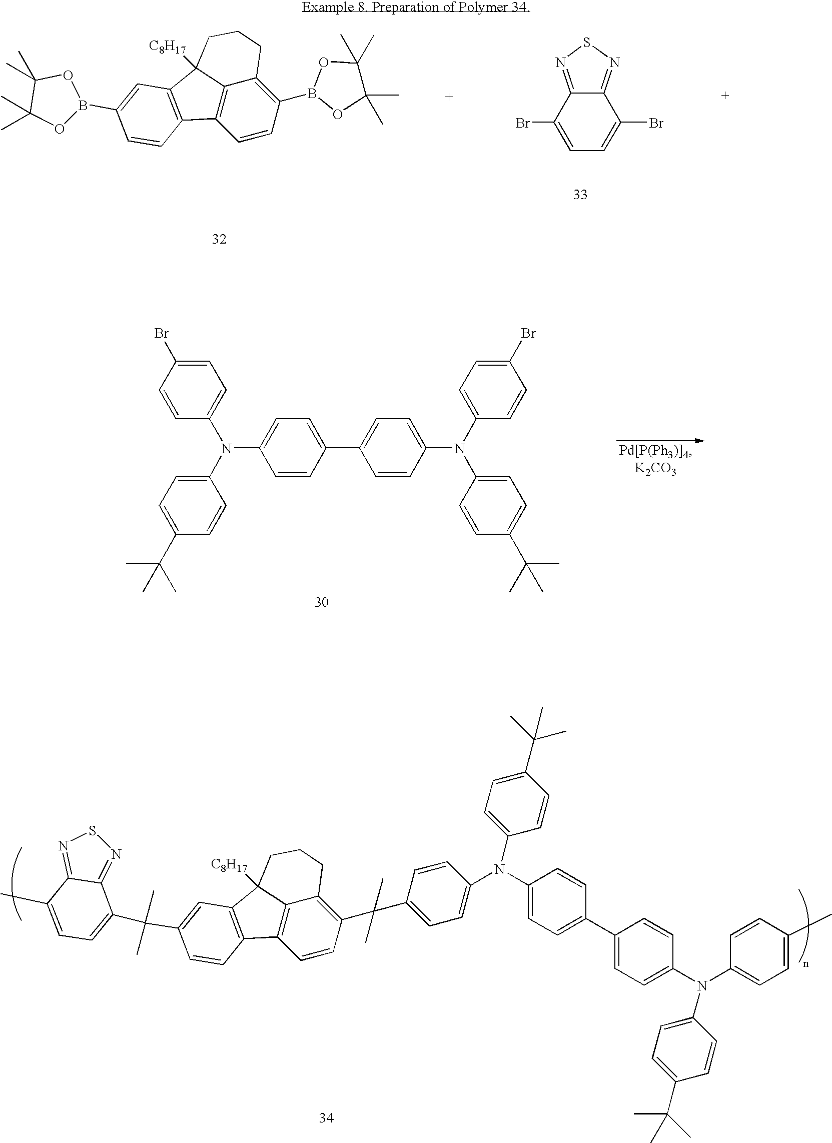

Preparation of 32: The boronic ester is prepared from 23 by lithiation with n-butyl lithium, boronation with trimethylborate, hydration to the diboronic acid and esterification with pinacol, using the same techniques as for compound 42 below.

Preparation of Co-Polymer 34: In an inert atmosphere box a 40 mL glass vial is charged with 32 (0.52 mmol), 3,6-dibromobenzothiadiazole 33 (0.1 mmol), 30 (0.4 mmol), palladium tetrakistriphenylphosphine (0.0052 mmol, 1 mol % based on the bisboronic ester), three 5 mm glass beads, Aliquat 336 (0.2 mL), and toluene (1.8 mL), and sealed with a septum cap. The vial is removed from the inert atmosphere box and 0.8 mL degassed (with nitrogen) 2M aqueous potassium carbonate is added by syringe. The vial is heated in an orbital shaker at 95° C. for 24 hr. The toluene layer is separated, diluted to 10 mL, filtered through 0.2 micron filter, and coagulated into 9/1 methanol/water. The coagulated polymer is then twice redissolved and coagulated into methanol/acetone 75/25, then dried in a vacuum oven at 60° C. overnight.

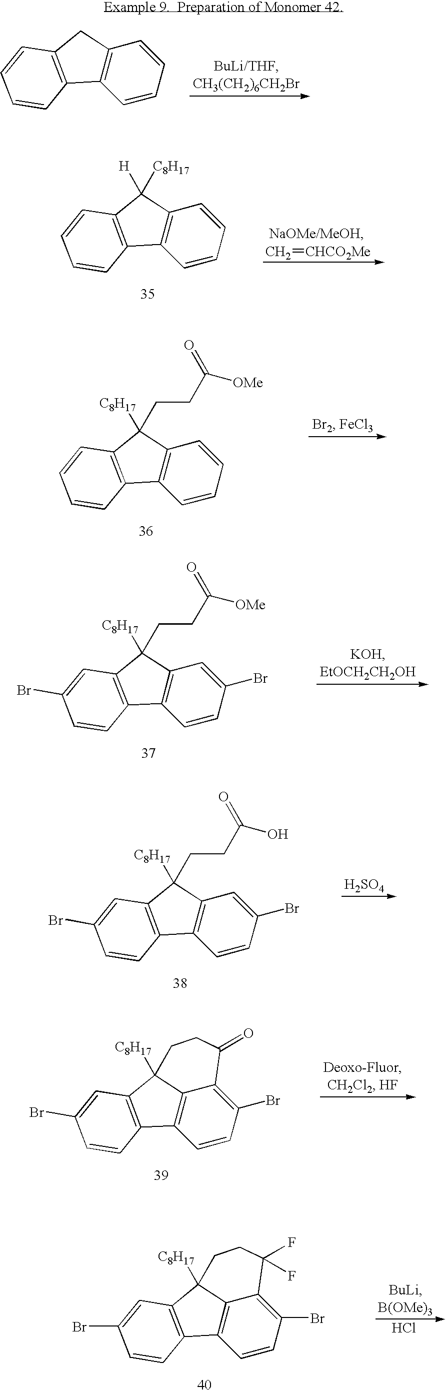

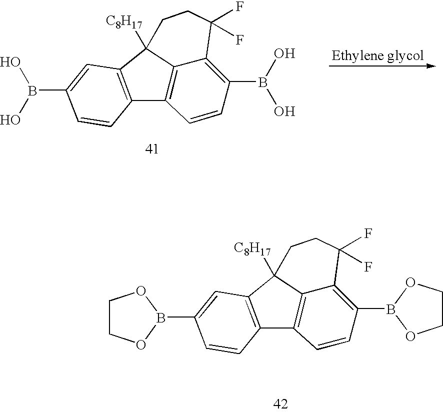

Preparation of 9-octylfluorene (35): To a solution of fluorene (20g, 0.12 mol) in dry THF (180 mL), under nitrogen and at −80° C., was added a 10 M solution of n-butyllithium in hexane (0.12 mol) over a 15 min period. After the addition, the temperature of the reaction mixture was allowed to rise to room temperature. The mixture was then cooled to −80° C. and a solution of n-octylbromide (0.12 mol) was added dropwise. After the addition, the reaction mixture was allowed to stir at this low temperature for 1 h and was then allowed to rise to room temperature over night. Water (180 mL) was added to the reaction mixture. The product was extracted with DCM (3×60 mL) and purified by chromatigraphy. A pale oil was collected (32g).

Preparation of 9-octylfluorene-9-propanoate (36) A mixure containing 35 (0.018 mol), sodium methoxide (0.022 mol), and methyl acrylate (0.022 mol) in 250 mL of dry methanol is stirred at 0° C. for 3 h, after which the solution became clear and then the product 36 separates as a white solid which is collected by filtration.

Preparation of 37: To a solution of 36 (0.05 mol) in CHCl₃ (100 mL) is added FeCl₃ (0.005 mol) and bromine (0.10 mol). The mixture is stirred 3 hours at room temperature. The reaction is quenched with aqueous sodium thisulfate, separated, and the organic layer washed with water. Solvent is removed under vacuum and product purifed by flash chromatography on silica gel.

Preparation of 38: Compound 37 (0.027 mol), ethoxyethanol (100 mL), and 20 mL of 30% aqueous KOH is heated under reflux for 3 h. The mixture is cooled to room temperature and extracted with DCM (2×50 mL). The DCM layer is washed with water and the combined aqueous phase is cooled and acidified with HCl. The product is obtained after extraction with DCM and standard workup.

Preparation of 39: The acid 38 (0.043 mol) is dissolved in concentrated sulfuric acid and heated under nitrogen to 80° C. for 4 hr. The reaction mixture is poured into ice water, and isolated by filtration. The product is purified by recrystallization.

Preparation of 40: To a solution of 39 (0.1 mol) in DCM is added a solution of Deoxy-Fluor (Bis-(2-methoxyethyl)aminosulfur trifluoride, Air Products) in DCM (0.1 mol), and HF (0.02 mol). The mixture is stirred for 16 hr at room temperature. DCM and HF are removed under vacuum. The residue is purified by chromatography on a silica gel column.

Preparation of 41: An oven dried, 500 mL, three-necked, round bottom flask is equipped with a stir bar, rubber septum and an addition funnel. The flask is charged with 40 (0.05 mol). The flask is flushed with nitrogen and 250 mL anhydrous THF added. The solution is cooled to −80° C. and n-butyl lithium (16 mL, 10M in THF) added dropwise. The mixture is stirred for one hour at −80° C. and allowed to warm to room temperature. The mixture is cooled again to −80° C. and 50 mL of B(OMe)₃ added. The mixture is warmed to room temperature and stirred overnight. The mixture is hydrolyzed by addition of 150 mL of 2M HCl. The precipitate is filtered and washed with deionized water. The crude product is recrystallized from ethanol and dried under vacuum overnight.

Preparation of 42: In a 100 mL flask fitted with a Dean-Stark trap, 41 (10 g) and ethylene glycol (25 mL) are heated to 130° C. under nitrogen for 1.5 hr. Subsequently 30 mL toluene is added and refluxed until the toluene and any byproduct water are removed in the Dean-Stark trap. On cooling to room temperature the product is separated by filtration and washed with methanol. The product may be recrystallized from DCM-hexane.

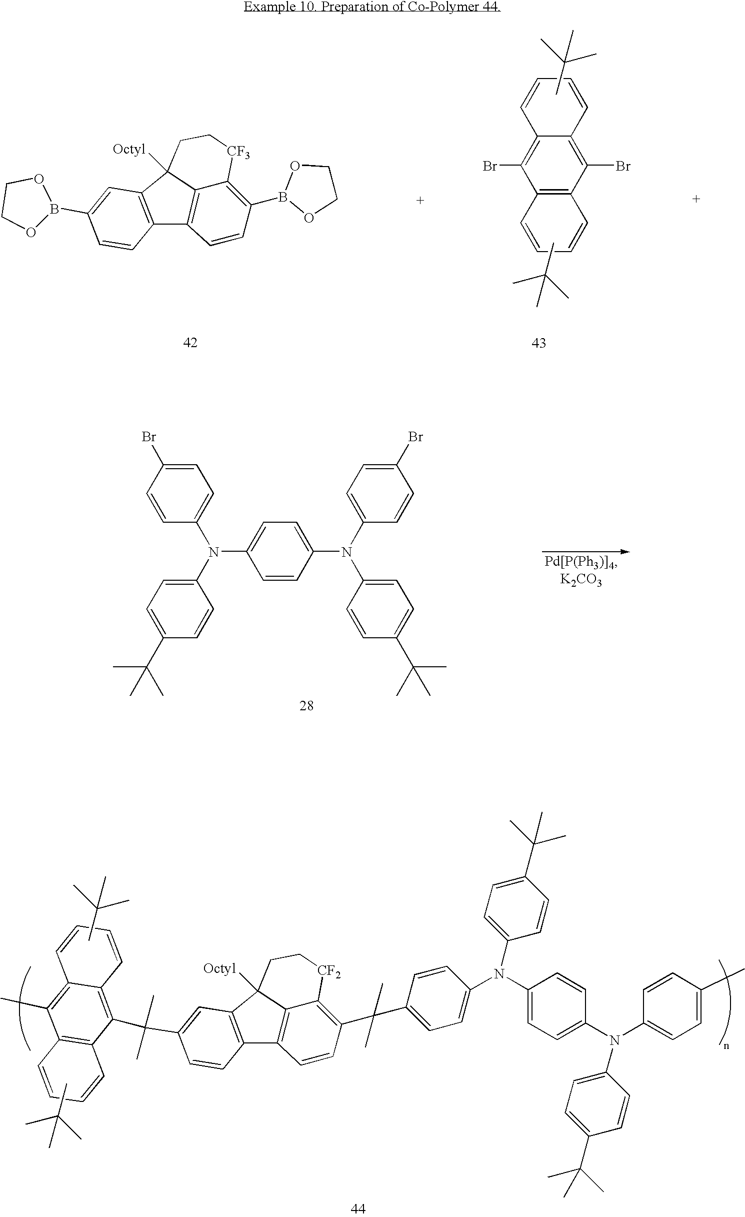

Preparation of Co-Polymer 44: In an inert atmosphere box a 40 mL glass vial is charged with 42 (0.52 mmol), 9,10-dibromodi-t-butylanthracene (mixed isomers) 43 (0.1 mmol), 28 (0.4 mmol), palladium tetrakistriphenylphosphine (0.0052 mmol, 1 mol % based on the bisboronic ester), three 5 mm glass beads, Aliquat 336 (0.2 mL), and toluene (1.8 mL), and sealed with a septum cap. The vial is removed from the inert atmosphere box and 0.8 mL degassed (with nitrogen) 2M aqueous potassium carbonate is added by syringe. The vial is heated in an orbital shaker at 95° C. for 24 hr. The toluene layer is separated, diluted to 10 mL, filtered through 0.2 micron filter, and coagulated into 9/1-methanol/water. The coagulated polymer is then twice redissolved and coagulated into methanol/acetone 75/25, then dried in a vacuum oven at 60° C. overnight.

Preparation of 43: A 250 mL three neck round bottom flask is charged with 9,10-dibromoanthracene (0.05 mol), t-butylbromide (0.12 mol), and carbon disulfide (100 mL). Under a nitrogen atmosphere aluminum chloride (0.005 mol) is added in several portions. The mixture is stirred for 3 hr at room temperature. The reaction mixture is poured into ice water, and isolated by filtration. The product is purified by chromatography on silica gel.

### Example 11

### P-OLED Devices From Polymers 29, 31, 34, and 44

Standard polymer organic light emitting devices are fabricated by depositing a layer of Baytron P® (Bayer) polyethylenedioxythiophene/polystyrene sulfonate onto a cleaned, ITO coated, pane of glass, followed by spin coating a layer of the polymer (29, 31, 34, or 44) to a thickness of about 100 nm, followed by vacuum evaporation of a 5 nm layer of CsF, followed by vacuum evaporation of a 1 micron layer of aluminum. Devices using polymers 29, 31, and 44 emit blue light, and the device using polymer 34 emits green light on application of a voltage of 5 to 10 V.

### Comparative Example 1

A) A film is cast from a solution of CN-PPP (100 mg) in chloroform (10 mL) onto a quartz plate, and is dried at 40° C. under nitrogen. The photoluminescence spectrum of the film shows an intense peak in the 400-450 nm region characteristic of polyphenylene and and essentially zero emission in the region 550-650 nm.

B) A film is cast from a solution of CN-PPP (100 mg) and Eu(acac)₃phen (5 mg) in chloroform (10 mL) onto a quartz plate, and is dried at 40° C. under nitrogen. The photoluminescence spectrum of the film shows an intense peak in the 400-450 nm region characteristic of polyphenylene and a very small peak (less than about 5% of the integrated area from 400 to 650 nm) in the region 600-620 nm characteristic of Eu3+ ion. Essentially no energy is transferred to the Eu3+ion from CN-PPP, in theory because the energy level of Eu(acac)₃phen is to high to accept energy from CN-PPP.

C) A film is cast from a solution of CN-PPP (100 mg) and Eu(dnm)₃phen (5 mg) in chloroform (10 mL) onto a quartz plate, and is dried at 40° C. under nitrogen. The photoluminescence spectrum of the film shows intense peaks in the 600-620 nm region characteristic of Eu3+ ion and essentially zero emission in the region 400-550 nm. Essentially all of the energy of CN-PPP excited state is transferred to the Eu3+ ion because the energy level of Eu(dnm)₃phen is low enough to accept energy from the first singlet excited state of CN-PPP. 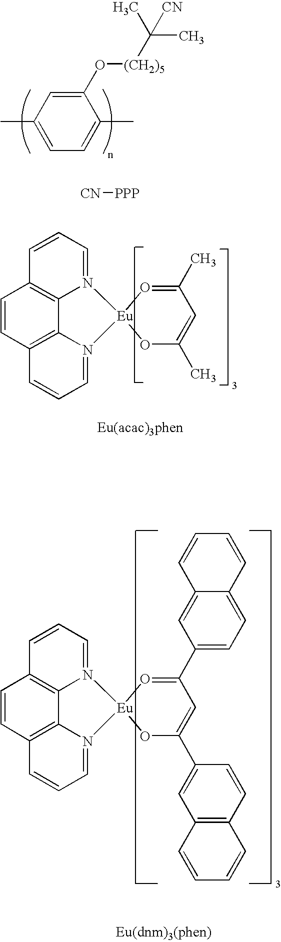
In this example, Eu(dnm)₃(phen) quenches CN-PPP luminescence, but Eu(acac)₃(phen) does not effectively quench CN-PPP luminescence.

The above descriptions of exemplary embodiments of bridged biphenyl polymers, copolymers, articles prepared therefrom, and processes for making and using the same are illustrative of the present invention. Because of variations which will be apparent to those skilled in the art, however, the present invention is not intended to be limited to the particular embodiments described above. The scope of the invention is defined in the following claims

What is claimed is:

1. A polymer composition comprising at least one type of repeat unit selected from the group consisting of: 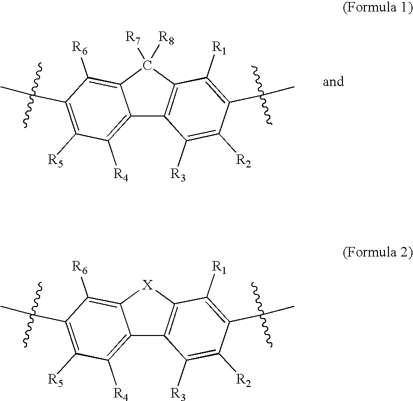
where X is selected from the group consisting of: 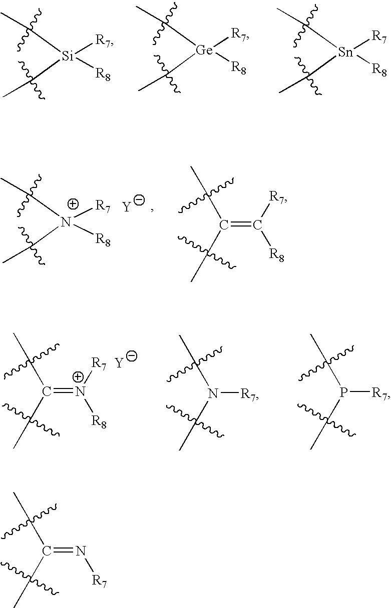
wherein R₁-R₈ are independently selected from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently selected from the group consisting of H, alkyl, substituted alkyl, aryl, substituted aryl, heteroaryl, and substituted heteroaryl;
adjacent R groups may or may not form a ring structure;
R₇ and R₈ taken together may or may not form a ring structure;
any R₁-R₈ may or may not form ring structures with adjacent repeat units in the polymer;
any Rₐ and R_{b} (if present) taken together may or may not form one or more ring structures;
Y⁻ is any mono-valent anionic atom or group;
and either (1) R₇ forms a ring system with R₆ or (2) R₇ forms a ring system with R₆ and R₈ forms a ring system with R₁ in which the two ring systems may or may not share more than one atom,
and optionally comprising 1-99% by weight of one or more types of repeating units independently selected from the group consisting of conjugated units of the formulas: 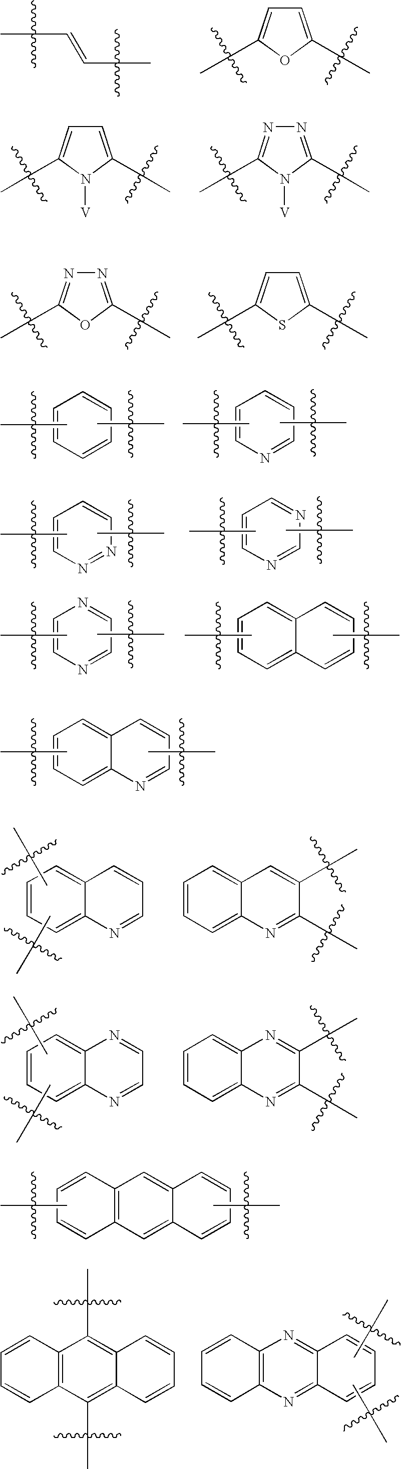 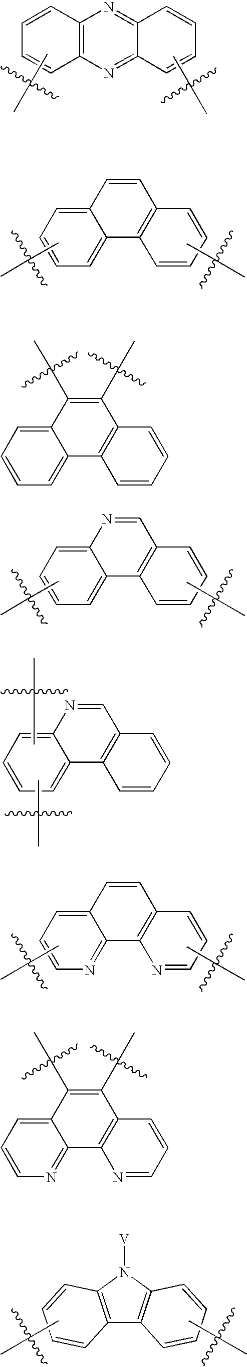 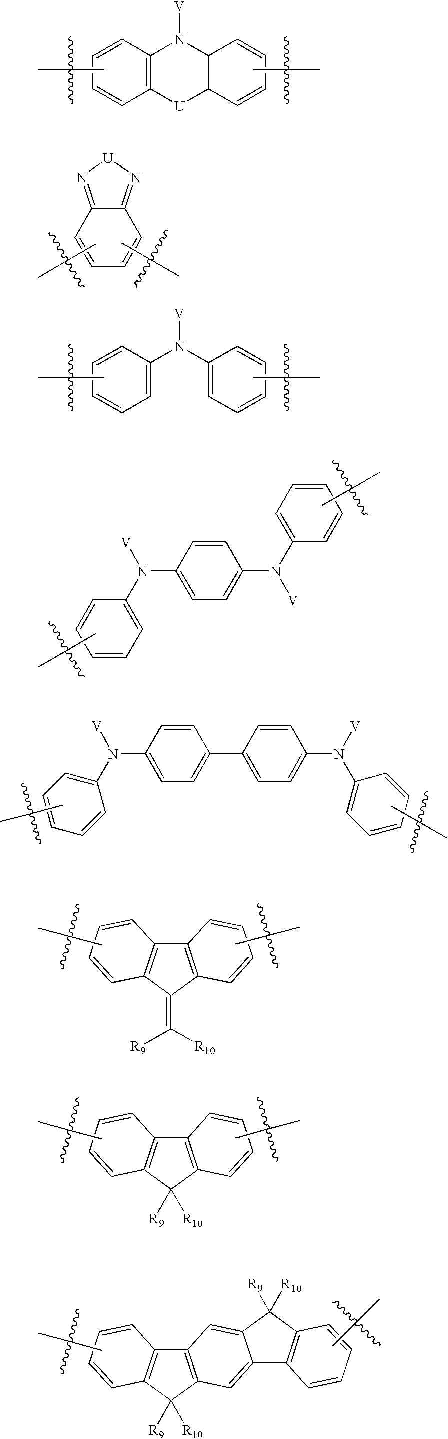 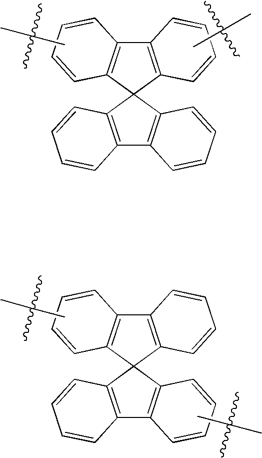
wherein the conjugated units may bear substitutents independently selected from the group consisting of alkyl, substituted alkyl, perfluoro alkyl, alkoxy, substituted alkoxy, aryl, substituted aryl, aryloxy, substituted aryloxy, heteroaryl, substituted heteroaryl, alkyl carbonyloxy, cyano, and fluoro;
U is independently selected from —O— and —S—;
and V, R₉, and R₁₀ are each independently chosen from the group consisting of alkyl, substituted alkyl, aryl, substituted aryl, heteroaryl, or substituted heteroaryl.

2. The polymer composition of claim 1 wherein the polymer comprises two or more of the types of repeat unit represented by Formula 1
where R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
adjacent R groups may or may not form a ring structure;
R₇ and R₈ taken together may or may not form a ring structure;
any R₁-R₈ may or may not form ring structures with adjacent repeat units in the polymer;
any Rₐ and R_{b} (if present) taken together may or may not form one or more ring structures;
and either (1) R₇ forms a ring system with R₆ or (2) R₇ forms a ring system with R₆ and R₈ forms a ring system with R₁ in which the two ring systems may or may not share more than one atom.

3. The polymer composition of claim 1 comprising a copolymer comprising 1-99% by weight of one type of repeat unit represented by Formula 1
where R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
adjacent R groups may or may not form a ring structure;
R₇ and R₈ (if present) taken together may or may not form a ring structure;
any R₁-R₈ may or may not form ring structures with adjacent repeat units in the polymer;
any Rₐ and R_{b} (if present) taken together may or may not form one or more ring structures;
and either (1) R₇ forms a ring system with R₆ or (2) R₇ forms a ring system with R₆ and R₈ forms a ring system with R₁ wherein the two ring systems may or may not share more than one atom;
and comprising 1-99% by weight of one or more types of repeating units independently selected from the group of conjugated units of the formulas: 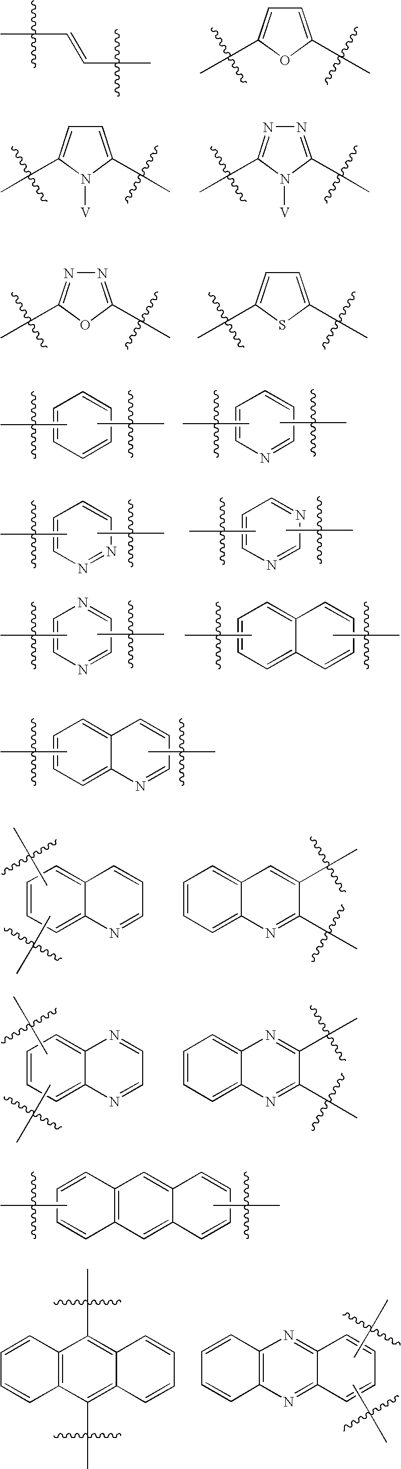 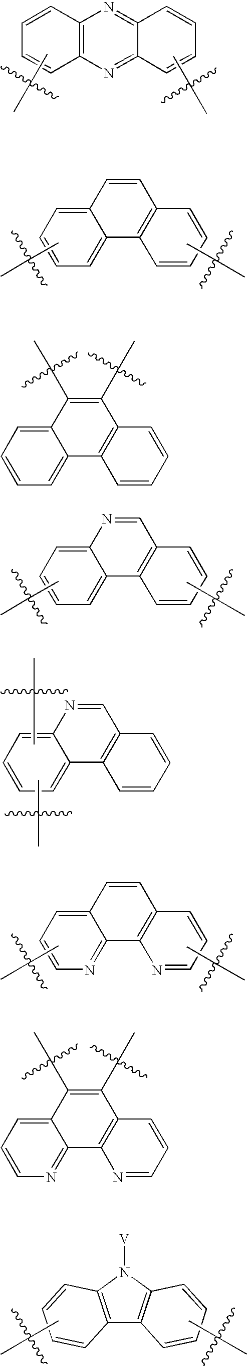 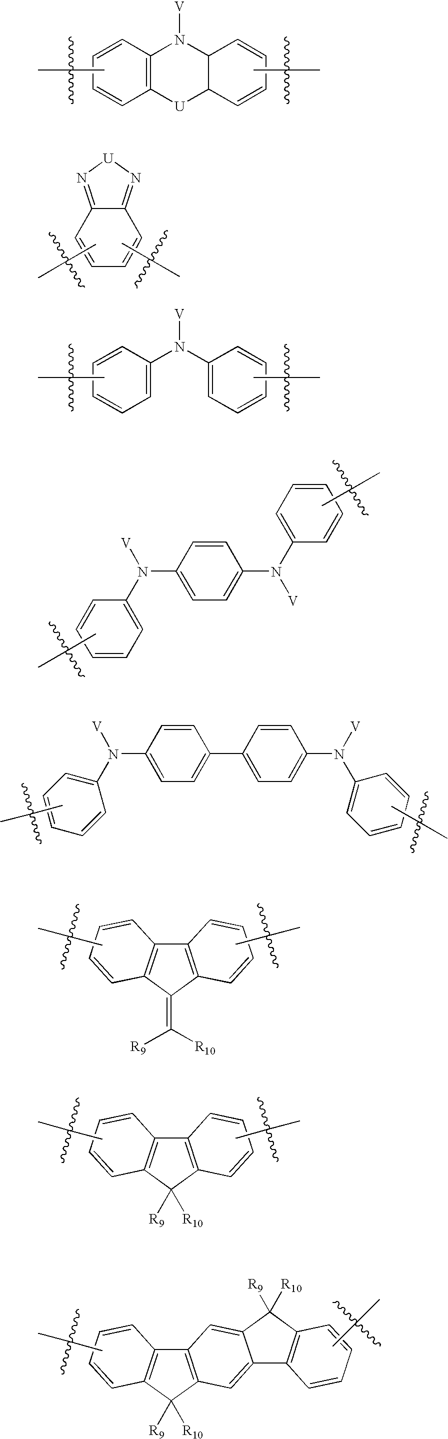 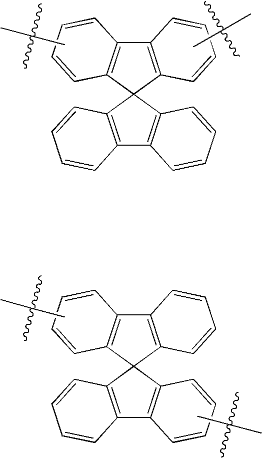
wherein the conjugated units may bear substitutents independently chosen from the group consisting alkyl, substituted alkyl, perfluoro alkyl, alkoxy, substituted alkoxy, aryl, substituted aryl, aryloxy, substituted aryloxy, heteroaryl, substituted heteroaryl, alkyl carbonyloxy, cyano, and fluoro;
U is independently selected from —O— and —S—;
and V, R₉, and R₁₀ are each independently chosen from the group consisting of alkyl, substituted alkyl, aryl, substituted aryl, heteroaryl, or substituted heteroaryl.

4. The polymer composition of claim 1 comprising a copolymer comprising 1-99% by weight of two or more types of repeat units represented by Formula 1
where R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
adjacent R groups may or may not form a ring structure;
R₇ and R₈ (if present) taken together may or may not form a ring structure;
any R₁-R₈ may or may not form ring structures with adjacent repeat units in the polymer;
any Rₐ and R_{b} (if present) taken together may or may not form one or more ring structures;
and either (1) R₇ forms a ring system with R₆ or (2) R₇ forms a ring system with R₆ and R₈ forms a ring system with R₁ in which the two ring systems may or may not share more than one atom;
and comprising 1-99% by weight of one or more types of repeating units independently selected from the group of conjugated units of the formulas: 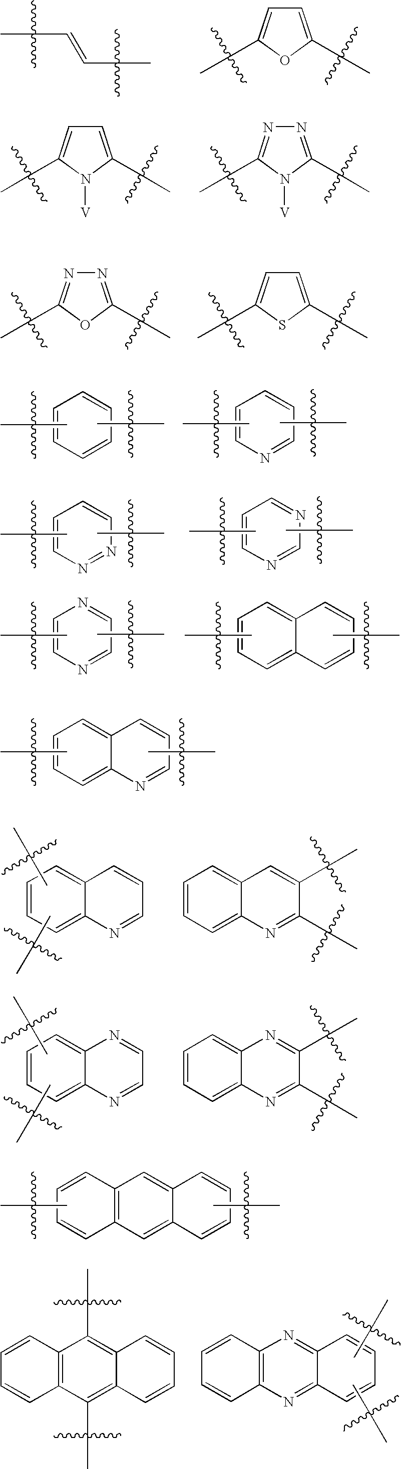 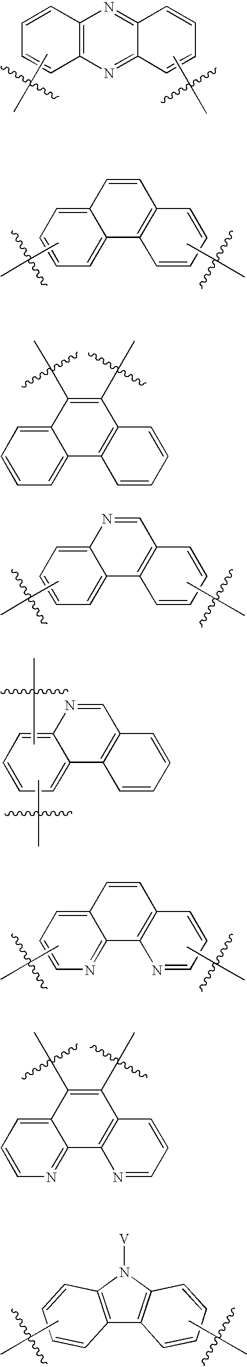 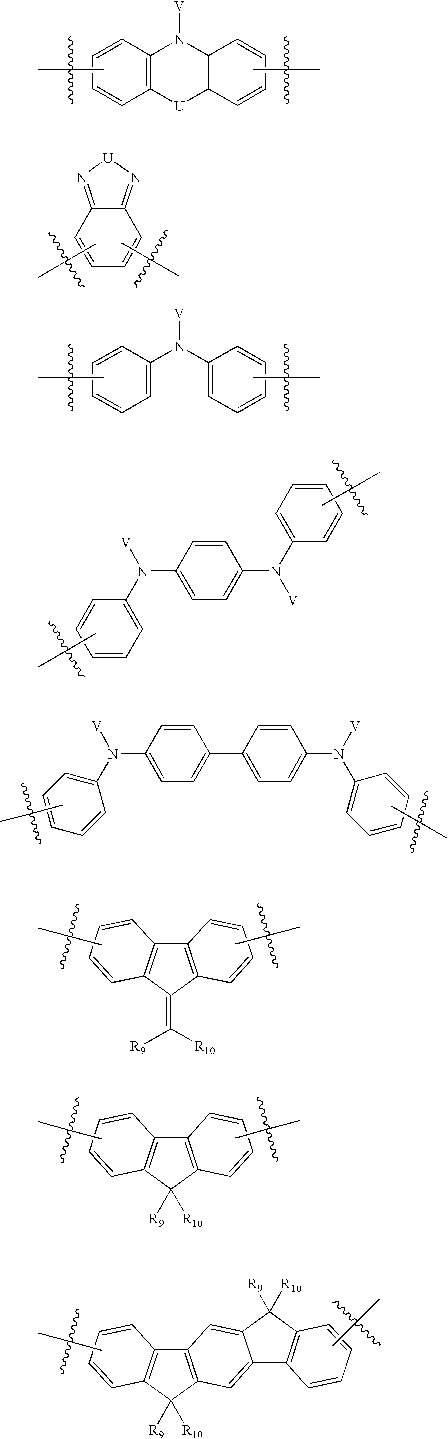 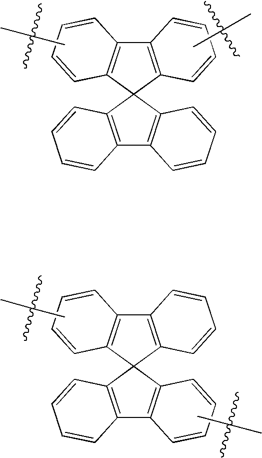
wherein the conjugated units may bear substitutents independently chosen from the group consisting alkyl, substituted alkyl, perfluoro alkyl, alkoxy, substituted alkoxy, aryl, substituted aryl, aryloxy, substituted aryloxy, heteroaryl, substituted heteroaryl, alkyl carbonyloxy, cyano, and fluoro;
U is independently selected from —O— and —S—;
and V, R₉, and R₁₀ are each independently chosen from the group consisting of alkyl, substituted alkyl, aryl, substituted aryl, heteroaryl, or substituted heteroaryl.

5. The polymer composition of claim 1 wherein the polymer comprises one or more repeat units represented by Formula 2
where X is selected from the group consisting of 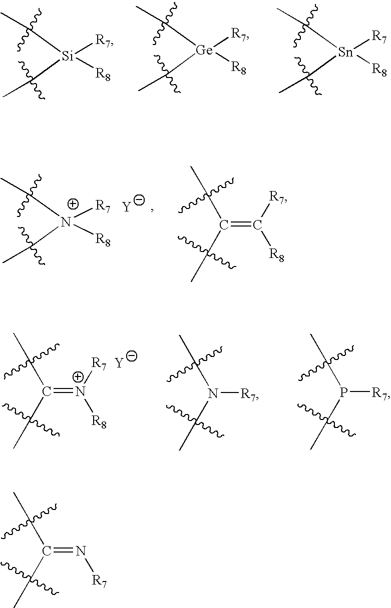
wherein R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
adjacent R groups may or may not form a ring structure;
R₇ and R₈ (if present) taken together may or may not form a ring structure;
any R₁-R₈ may or may not form ring structures with adjacent repeat units in the polymer;
any Rₐ and R_{b} (if present) taken together may or may not form one or more ring structures;
Y⁻ is any mono-valent anionic atom or group;
and either (1) R₇ forms a ring system with R₆ or (2) R₇ forms a ring system with R₆ and R₈ (if present) forms a ring system with R₁ wherein the two ring systems may or may not share more than one atom.

6. The polymer composition of claim 1 comprising a copolymer comprising 1-99% by weight of one or more types of repeat units represented by Formula 2
where X is selected from the group consisting of 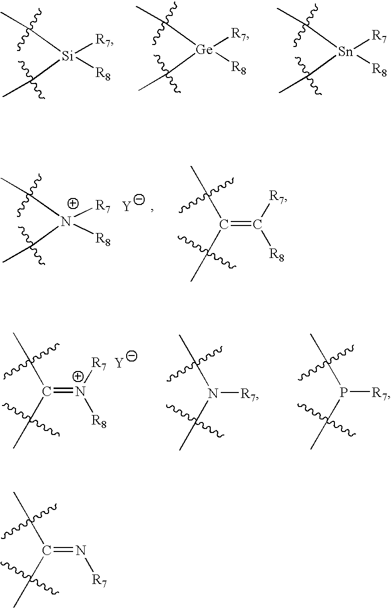
wherein R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
adjacent R groups may or may not form a ring structure;
R₇ and R₈ (if present) taken together may or may not form a ring structure;
any R₁-R₈ may or may not form ring structures with adjacent repeat units in the polymer;
any Rₐ and R_{b} (if present) taken together may or may not form one or more ring structures;
Y⁻ is any mono-valent anionic atom or group;
and either (1) R₇ forms a ring system with R₆ or (2) R₇ forms a ring system with R₆ and R₈ forms a ring system with R₁ wherein the two ring systems may or may not share more than one atom;
and comprising 1-99% by weight of one or more types of repeating units independently selected from the group of conjugated units of the formulas: 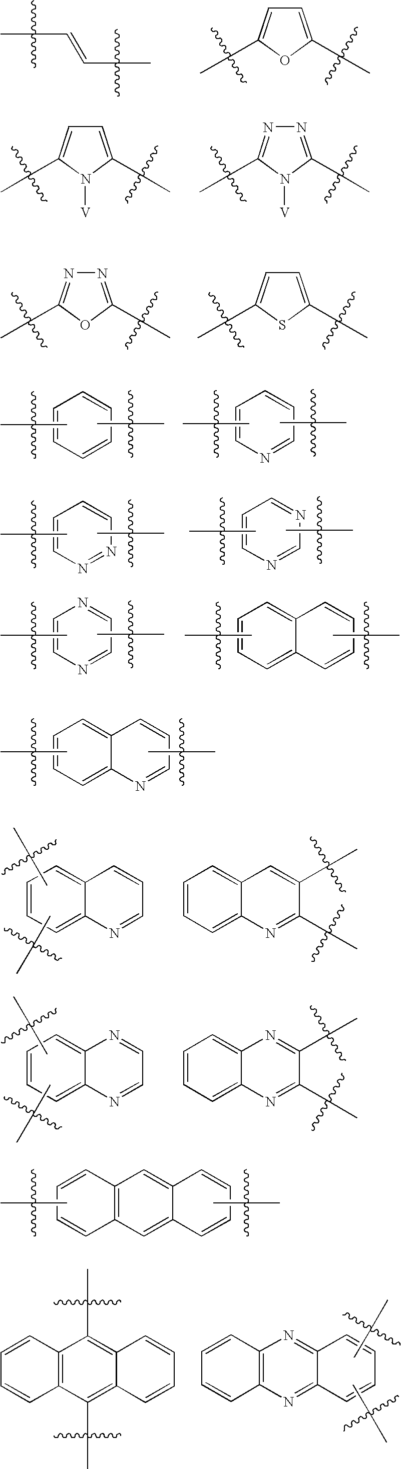 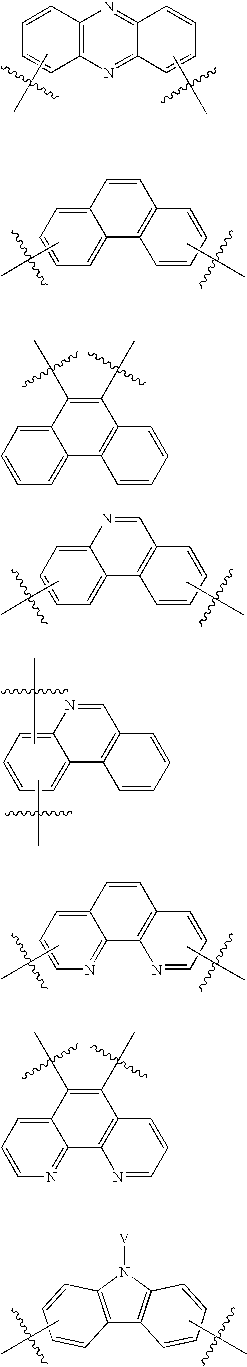 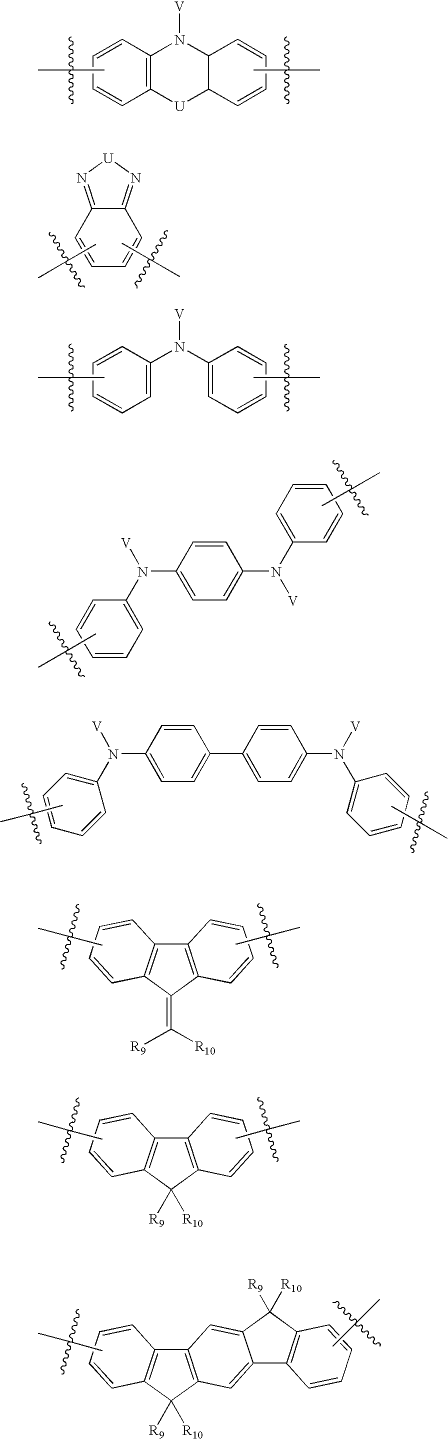 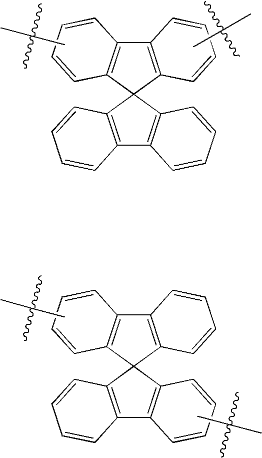
wherein the conjugated units may bear substitutents independently chosen from the group consisting alkyl, substituted alkyl, perfluoro alkyl, alkoxy, substituted alkoxy, aryl, substituted aryl, aryloxy, substituted aryloxy, heteroaryl, substituted heteroaryl, alkyl carbonyloxy, cyano, and fluoro;
U is independently selected from —O— and —S—;
and V, R₉, and R₁₀ are each independently chosen from the group consisting of alkyl, substituted alkyl, aryl, substituted aryl, heteroaryl, or substituted heteroaryl.

7. The composition of claim 1 in which one or more of R₁-R₈, Rₐ, and R_{b} are independently selected from the group consisting alkyl, aryl, heteroaryl, arylalkyl, or heteroarylalkyl groups in which one or more hydrogen atoms are replaced by fluorine, including perfluoro derivatives.

8. The composition of claim 1 in which one or more of V, R₉, and R₁₀ are independently selected from the group consisting alkyl, aryl, heteroaryl, arylalkyl, or heteroarylalkyl groups in which one or more hydrogen atoms are replaced by fluorine, including perfluoro derivatives.

9. The composition of claim 1 in which one or more R₁-R₈, Rₐ, or R_{b} are independently selected from the group consisting of —R_{c}CN, —R_{c}CHO, —R_{c}CORₐ, —R_{c}CRₐ═NR_{b}, —R_{c}ORₐ, —R_{c}SRₐ, —R_{c}SO₂Rₐ, —R_{c}PORₐR_{b}, —R_{c}PO₃Rₐ, —R_{c}OCORₐ, —R_{c}CO₂Rₐ, —R_{c}NRₐR_{b}, —R_{c}N═CRₐR_{b}, —R_{c}NRₐCOR_{b}, and —R_{c}CONRₐR_{b} in which R_{c} is independently selected from the group consisting of alkylene and substituted alkylene, including but not limited to alkylene groups containing heteroatoms and alkylene groups in which one or more hydrogen atoms are replaced by fluorine, including perfluoro derivatives.

10. The composition of claim 1 in which one or more of V, R₉, and R₁₀ are independently selected from the group consisting of —R_{c}CN, —R_{c}CHO, —R_{c}CORₐ, —R_{c}CRₐ═NR_{b}, —R_{c}ORₐ, —R_{c}SRₐ, —R_{c}SO₂Rₐ, —R_{c}PORₐR_{b}, —R_{c}PO₃Rₐ, —R_{c}OCORₐ, —R_{c}CO₂Rₐ, —R_{c}NRₐR_{b}, —R_{c}N═CRₐR_{b}, —R_{c}NRₐCOR_{b}, and —R_{c}CONRₐR_{b} in which R_{c} is independently selected from the group consisting of alkylene and substituted alkylene, including but not limited to alkylene groups containing heteroatoms and alkylene groups in which one or more hydrogen atoms are replaced by fluorine, including perfluoro derivatives.

11. The composition of claim 1 wherein Formula 1 is represented by
where U₁ and U_{1′} are independently selected from the group consisting of nil, —NR′—, —O—, and —S—;
R and R′ are independently selected from the group consisting of hydrogen, alkyl, substituted alkyl, aryl, substituted aryl, heteroaryl, and substituted heteroaryl;
and n=2-5.

12. The composition of claim 1 wherein Formula 1 is represented by 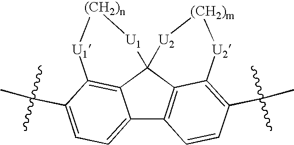
where U₁, U_{1′}, U₂, and U_{2′} are independently selected from the group consisting of nil, —NR′—, —O—, and —S—;
R′ is independently selected from the group consisting of hydrogen, alkyl, substituted alkyl, aryl, substituted aryl, heteroaryl, and substituted heteroaryl;
m=2-5;
and n=2-5.

13. The composition of claim 1 wherein Formula 1 is represented by 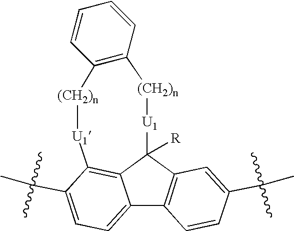
where U₁, and U_{1′} are independently selected from the group consisting of nil, —NR′—, —O—, and —S—;
R and R′ are independently selected from the group consisting of hydrogen, alkyl, substituted alkyl, aryl, substituted aryl, heteroaryl, and substituted heteroaryl;
m=0-3;
and n=0-3.

14. The composition of claim 1 wherein Formula 1 is represented by 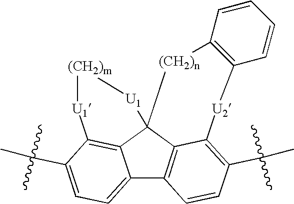
where U₁, U_{1′}, and U_{2′} are independently selected from the group consisting of nil, —NR′—, —O—, and —S— in which R′ is independently chosen from the group consisting of hydrogen, alkyl, substituted alkyl, aryl, substituted aryl, heteroaryl, and substituted heteroaryl;
m=2-5
and n=0-3.

15. The composition of claim 1 wherein Formula 1 is represented by 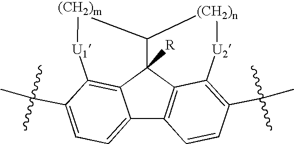
where U_{1′} and U_{2′} are independently selected from the group consisting of nil, —NR′—, —O—, and —S—;
R and R′ are independently chosen from the group consisting of hydrogen, alkyl, substituted alkyl, aryl, substituted aryl, heteroaryl, and substituted heteroaryl;
m=1-4;
and n=1-4.

16. The composition of claim 1 wherein Formula 2 is 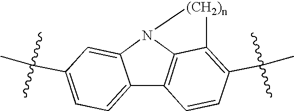
where n=2-5.

17. The composition of claim 1 wherein Formula 2 is represented by 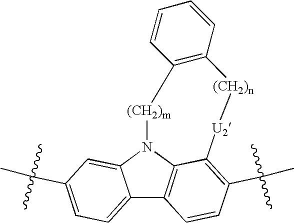
where U_{2′} is independently selected from the group consisting of nil, —NR′—, —O—, and —S— in which R is independently chosen from the group consisting of hydrogen, alkyl, substituted alkyl, aryl, substituted aryl, heteroaryl, and substituted heteroaryl;
m=0-3;
and n=0-3.

18. The composition of claim 1 further comprising endcapping groups comprising an aromatic group.

19. The composition of claim 1 wherein the polymer has a structure that is linear, branched, hyperbranched, star, comb, dendritic, or some combination thereof.

20. The composition of claim 1 wherein the polymer has a structure that is alternating, random, block, or some combination thereof.

21. The composition of claim 1 wherein the polymer contains crosslinkable functional groups

22. The composition of claim 1 wherein the polymer contains chemically reactive end groups that can be used to increased the molecular weight of the material.

23. The composition of claim 1 wherein one or more luminescent groups are either covalently bound, ionically bound, bound by hydrogen bonds, or some combination thereof to the polymer.

24. The composition of claim 1 wherein one or more metals are either chelated, covalently bound, ionically bound, bound by hydrogen bonds, or some combination thereof to the polymer.

25. The composition of claim 24 wherein the metal is independently selected from the group consisting of transition metals.

26. A composition consisting of a blend of one or more of the polymers of claim 1 and one or more other polymers.

27. A composition containing 1% or more by weight of one or more of the polymers of claim 1 and up to 99% by weight of other polymers or additives.

28. The composition of claim 27 in which the other polymers or additives are luminescent molecules, luminescent oligomers, or luminescent polymers.

29. The composition of claim 27 in which the other polymers or additives are luminescent particles or nanoparticles having an average diameter less than about 100 nm.

30. The composition of claim 1 where the polymer is optically active.

31. The polymer composition of claim 30 containing a bridged biphenyl unit that is chiral and present in an enantiomeric excess of greater than 10%.

32. A composition represented by Formula X: 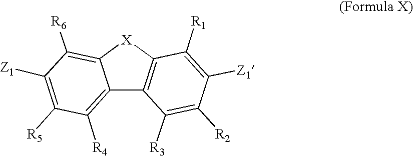
where X is selected from the group consisting of: 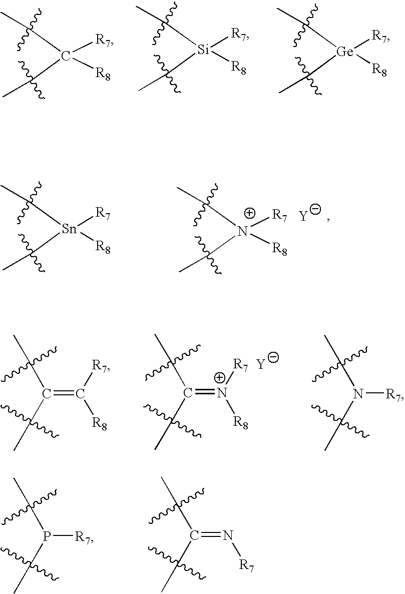
wherein R₁-R₈ are independently selected from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently selected from the group consisting of H, alkyl, substituted alkyl, aryl, substituted aryl, heteroaryl, and substituted heteroaryl;
adjacent R groups may be mutually connected to form a ring structure;
R₇ and R₈ (if present) may or may not form a ring structure;
any Rₐ and R_{b} (if present) may or may not form one or more ring structures;
Y⁻ is any mono-valent anionic atom or group;
Z₁ and Z_{1′} are independently selected from the group consisting of halogen atoms, —ArCl, —ArBr, —ArI, —CORₘ, —ArCORₘ, —B(ORₘ)₂, —ArB(ORₘ)₂, 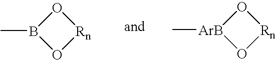
wherein Ar is independently selected from the group consisting of conjugated units of the formulas: 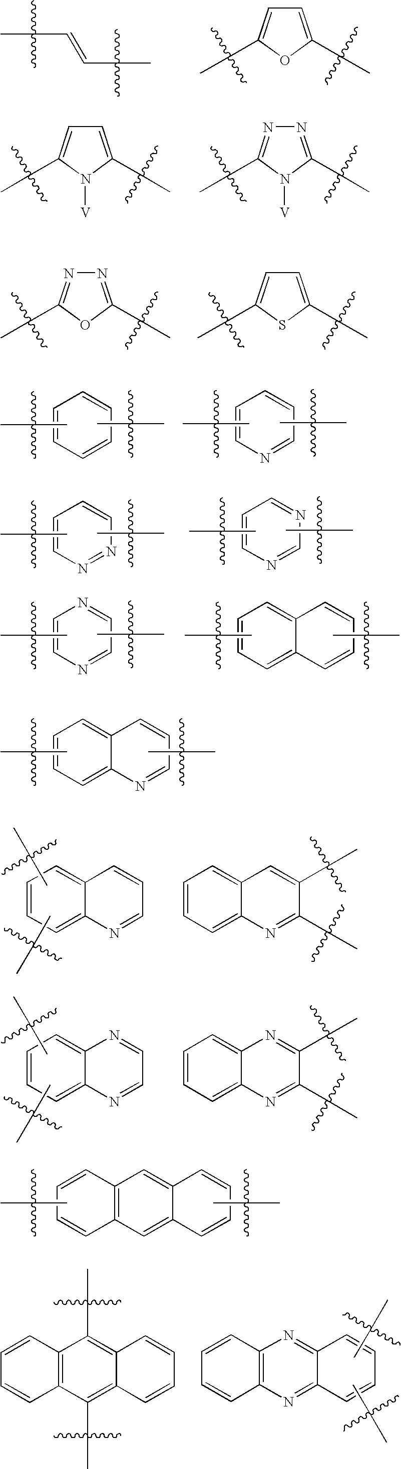 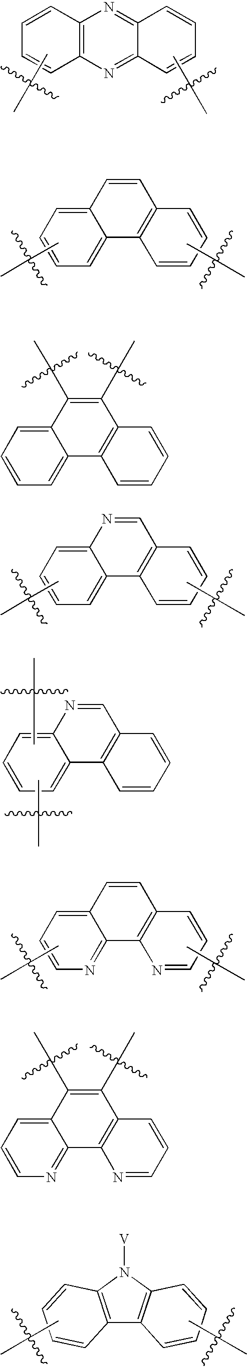 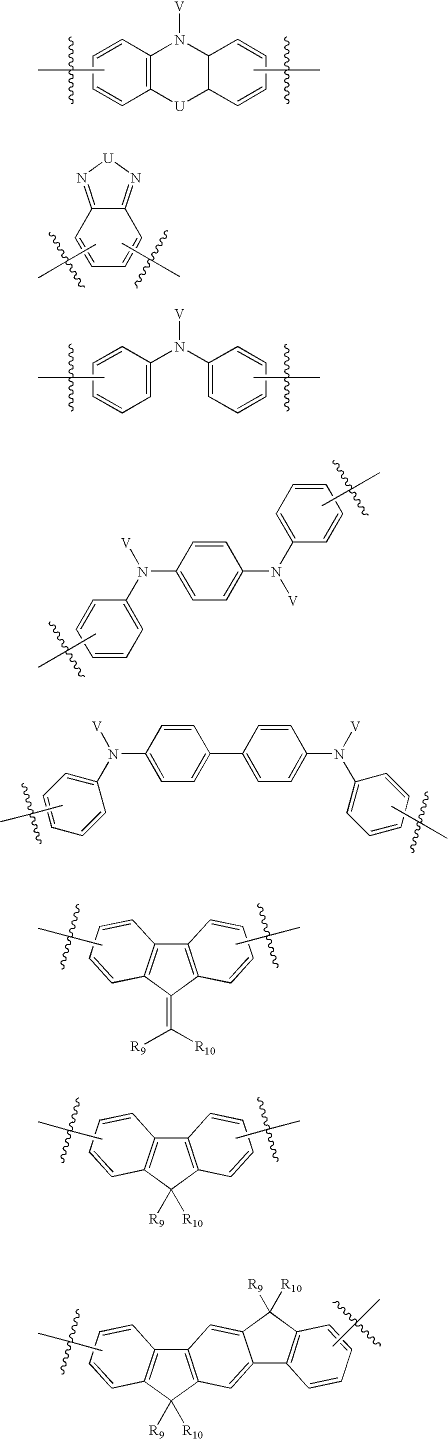 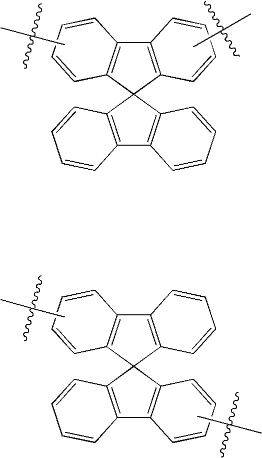
wherein the conjugated units may bear substitutents independently selected from the group consisting alkyl, substituted alkyl, perfluoro alkyl, alkoxy, substituted alkoxy, aryl, substituted aryl, aryloxy, substituted aryloxy, heteroaryl, substituted heteroaryl, alkyl carbonyloxy, cyano, and fluoro; wherein
U is independently selected from —O— and —S—;
and V, R₉, and R₁₀ are each independently chosen from the group consisting of alkyl, substituted alkyl, aryl, substituted aryl, heteroaryl, or substituted heteroaryl;
Rₘ is independently chosen from the group consisting of hydrogen, alkyl, substituted alkyl, aryl, substituted aryl, heteroaryl, and substituted heteroaryl;
Rₙ is independently chosen from the group consisting of alkylene, substituted alkylene, and 1,2-phenylene;
and either (1) R₇ is mutually connected to R₁ to form a ring system or (2) R₇ is mutually connected to R₁ to form a ring system and R₈ is mutually connected to R₆ to form a ring system wherein the two ring systems may or may not share more than one atom.

33. The composition of claim 32 in which Formula X is represented by 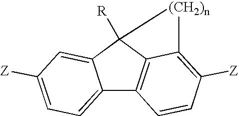
where R are independently chosen from the group consisting of hydrogen, alkyl, substituted alkyl, aryl, substituted aryl, heteroaryl, and substituted heteroaryl;
n=2-5;
and Z is independently selected from the group consisting of —CHO, —Cl, —Br, —I, —B(OH)₂,

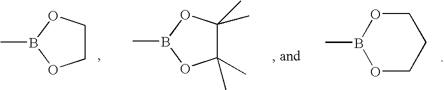

34. The composition of claim 32 in which Formula x is represented by 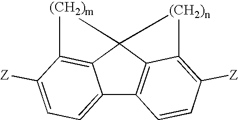
where m=2-5;
n=2-5;
and Z is independently selected from the group consisting of —CHO, —Cl, —Br, —I, —B(OH)₂,

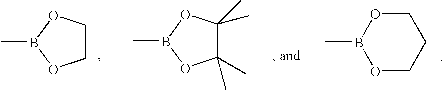

35. The composition of claim 34 where m=n.

36. The composition of claim 32 in which Formula X is represented by: 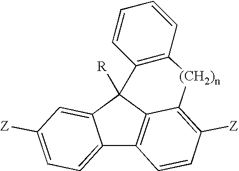
where R are independently selected from the group consisting of hydrogen, alkyl, substituted alkyl, aryl, substituted aryl, heteroaryl, and substituted heteroaryl;
n=0-3;
and Z is independently chosen from the group consisting of —CHO, —Cl, —Br, —I, —B(OH)₂,

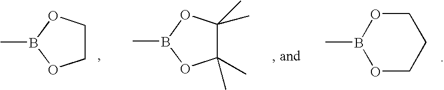

37. The composition of claim 32 in which Formula X is represented by: 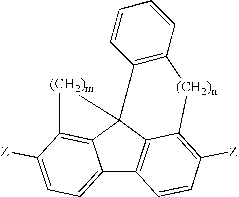
where m=2-5;
n=0-3;
and Z is independently selected from the group consisting of —CHO, —Cl, —Br, —I, —B(OH)₂,

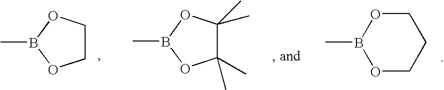

38. The composition of claim 32 in which Formula X is represented by: 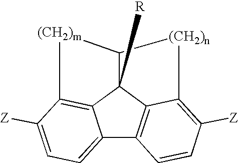
where R are independently selected from the group consisting of hydrogen, alkyl, substituted alkyl, aryl, substituted aryl, heteroaryl, and substituted heteroaryl;
m=1-4;
n=1-4;
and Z is independently selected from the group consisting of —CHO, —Cl, —Br, —I, —B(OH)₂,

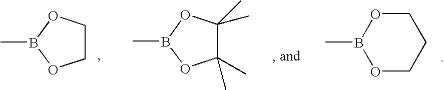

39. A composition represented by Formula XI: 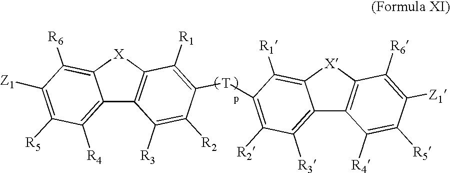
wherein X is independently selected from the group consisting of 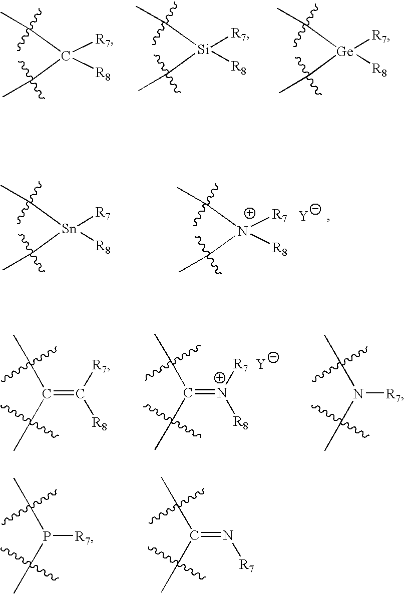
X′ is independently selected from the group consisting of 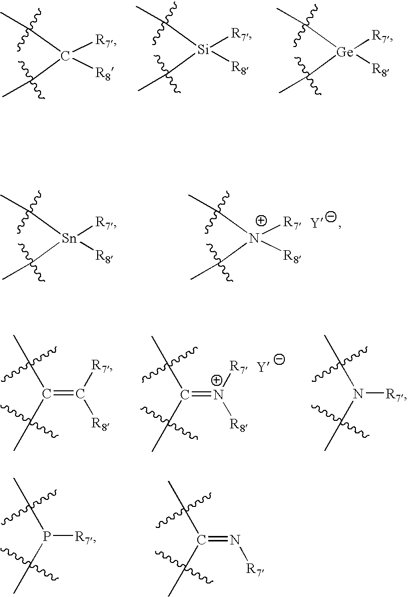
R₁-R₈ and R_{1′}-R_{8′} are independently selected from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently selected from the group consisting of H, alkyl, substituted alkyl, aryl, substituted aryl, heteroaryl, and substituted heteroaryl;
adjacent R groups may be mutually connected to form a ring structure;
either or both R₇ and R₈ (if present) or R₇, and R₈, (if present) may or may not form a ring structure;
any Rₐ and R_{b} (if present) may or may not form one
or more ring structures;
Y⁻ and Y′⁻ are independently selected from the group any consisting of mono-valent anions;
p=0-2;
Z₁ and Z₁, are independently selected from the group consisting of halogen atoms, —ArCl, —ArBr, —ArI, —CORₘ, —ArCORₘ, —B(ORₘ)₂, —ArB(ORₘ)₂,
and T and Ar are independently selected from the 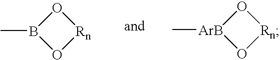
group consisting of conjugated units of the formulas: 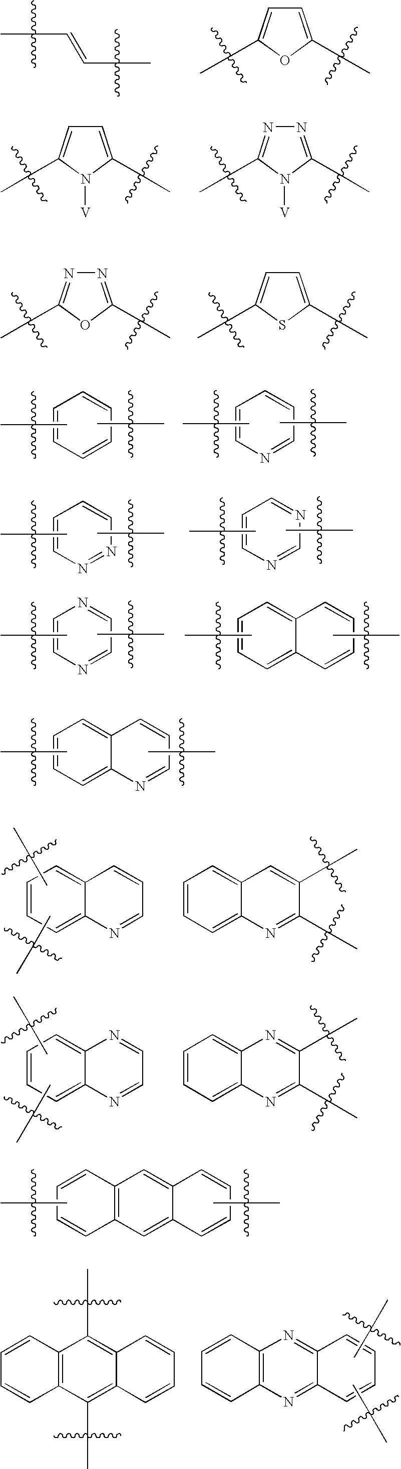 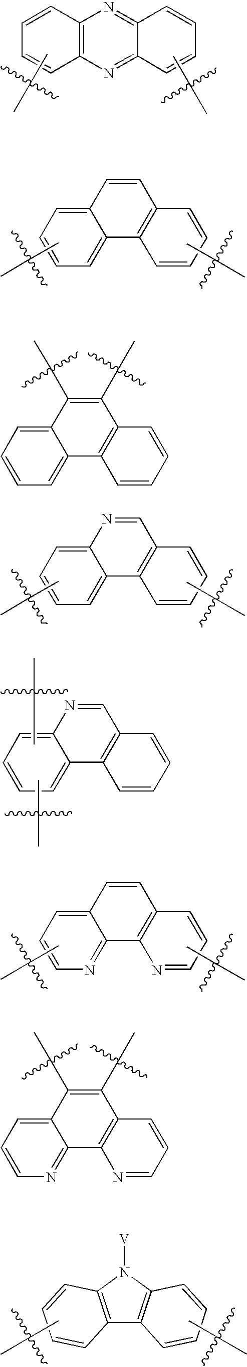 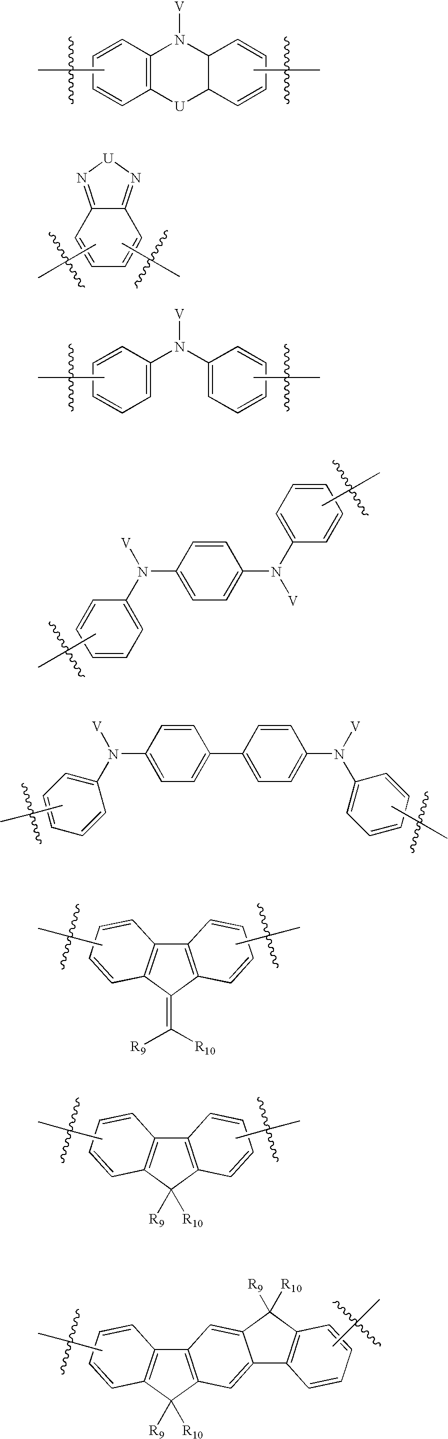 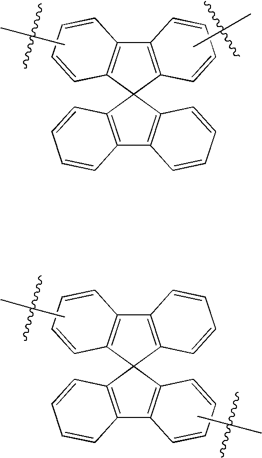
wherein the conjugated units may bear substitutents independently selected from the group consisting alkyl, substituted alkyl, perfluoro alkyl, alkoxy, substituted alkoxy, aryl, substituted aryl, aryloxy, substituted aryloxy, heteroaryl, substituted heteroaryl, alkyl carbonyloxy, cyano, and fluoro in which
U is independently selected from —O— and —S—
and V, R₉, and R₁₀ are each independently chosen from the group consisting of alkyl, substituted alkyl, aryl, substituted aryl, heteroaryl, or substituted heteroaryl;
Rₘ is independently selected from the group consisting of hydrogen, alkyl, substituted alkyl, aryl, substituted aryl, heteroaryl, and substituted heteroaryl;
Rₙ is independently selected from the group consisting of alkylene, substituted alkylene, and 1,2-phenylene;
and one or more R₇, R₈, R₇, or R₈ is mutually connected to R₁, R₆R_{1′}, or R_{6′} to form a ring system.

40. The composition of claims 32 or 39 in which one or more of the groups R₁-R₈, R_{1′}-R_{8′}, Rₐ, and R_{b} are independently selected from the group consisting alkyl, aryl, heteroaryl, arylalkyl, or heteroarylalkyl groups in which one or more hydrogen atoms are replaced by fluorine, including perfluoro derivatives.

41. The composition of claims 32 or 39 in which one or more of the groups V, R₉, and R₁₀ are independently selected from the group consisting alkyl, aryl, heteroaryl, arylalkyl, or heteroarylalkyl groups in which one or more hydrogen atoms are replaced by fluorine, including perfluoro derivatives.

42. The composition of claims 32 or 39 in which one or more R₁-R₈, R_{1′}-R_{8′} Rₐ, R_{b},and R_{b} are independently selected from the group consisting of —R_{c}CN, —R_{c}CHO, —R_{c}CORₐ, —R_{c}CRₐ═NR_{b}, —R_{c}ORₐ, —R_{c}SRₐ, —R_{c}SO₂Rₐ, —R_{c}PORₐR_{b}, —R_{c}PO₃Rₐ, —R_{c}OCORₐ, —R_{c}CO₂Rₐ, —R_{c}NRₐR_{b}, —R_{c}N═CRₐR_{b}, —R_{c}NRₐCOR_{b}, and —R_{c}CONRₐR_{b} in which R_{c} is independently selected from the group consisting of alkylene and substituted alkylene, including but not limited to alkylene groups containing heteroatoms and alkylene groups in which one or more hydrogen atoms are replaced by fluorine, including perfluoro derivatives.

43. The composition of claims 32 or 39 in which one or more V, R₉, and R₁₀ are independently selected from the group consisting of —R_{c}CN, —R_{c}CHO, —R_{c}CORₐ, —R_{c}CRₐ═NR_{b}, —R_{c}ORₐ, —R_{c}SRₐ, —R_{c}SO₂Rₐ, —R_{c}PORₐR_{b}, —R_{c}PO₃Rₐ, —R_{c}OCORₐ, —R_{c}CO₂Rₐ, —R_{c}NRₐR_{b}, —R_{c}N═CRₐR_{b}, —R_{c}NRₐCOR_{b}, and —R_{c}CONRₐR_{b} in which R_{c} is independently selected from the group consisting of alkylene and substituted alkylene, including but not limited to alkylene groups containing heteroatoms and alkylene groups in which one or more hydrogen atoms are replaced by fluorine, including perfluoro derivatives.

44. The composition of claim 32 in which R₇ is mutually connected to R₁ to form a ring system and R₈ is mutually connected to R₆ to form a ring system and the molecule is chiral.

45. The composition of claim 39 wherein X═X′, R₁═R_{1′}, R₂═R_{2′}, R₃═R_{3′}, R₄═R_{4′}, R₅═R_{5′}, R₆═R_{6′}, R₇═R_{7′}, R₈═R_{8′}, and Z₁=Z_{1′}.

46. A process for preparing polymers or copolymers in which one or more compounds of claims 32 or 39 are allowed to react with one or more compounds of the formula:
Z₂-A-Z_{2′}
where A is a wholly- or partially-conjugated group and Z₂ and Z_{2′} are the same or different and independently 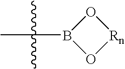
selected from the group consisting of halogen atoms, —B(ORₘ)₂, or
in which Rₘ is independently chosen from the group consisting of hydrogen, alkyl and substituted alkyl and Rₙ is independently chosen from the group consisting of alkylene and substituted alkylene.

47. The process of claim 46 in which the mixture is heated.

48. The process of claims 46 in which a base is added to the polymerization process.

49. The process of claims 46 in which the reaction is promoted by a zero-valent metal, metal complex, metal salt, or some mixture thereof.

50. The process of claim 49 in which the total molar concentration of the zero-valent metal, metal complex, metal salt or some mixture thereof is less than about 10% relative to the total monomer concentration.

51. The process of claims 49 or 50 in which the metal is selected from the group consisting of transition metals.

52. The process of claim 51 in which the metal is selected from the group consisting of nickel and palladium.

53. The process of claims 50-52 in which neutral organic ligands are added to the polymerization process.

54. The process of claim 53 in which the neutral organic ligand is represented by the formula: 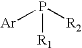
where Ar is chosen from the group consisting of aryl, substituted aryl, heteroaryl, and substituted heteroaryl
and R₁ and R₂ are independently selected from the group consisting of alkyl and substituted alkyl.

55. The process of claim 53 in which the neutral organic ligand are selected from the group consisting of mono-dentate and multi-dentate phosphines.

56. The process of claim 53 in which the neutral organic ligand is triphenylphosphine

57. The process of claim 53 in which the neutral organic ligand is tri(tert-butyl)phosphine.

58. The process of claim 54
where R₁ and R₂ are independently selected from the group consisting of C₃-C₁₂ alkyl groups that have structures that are linear, branched, cyclized, or some combination thereof;
and Ar is chosen from the group consisting of 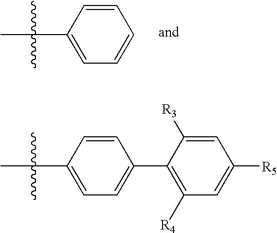
in which R₃, R₄, and R₅ are independently chosen from the group consisting of —H, —H₃, —CH₂CH₃, —CH₂CH₂CH₃, —CH(CH₃)₂, —CH₃, —OCH₂CH₃, OCH₂CH₂CH₃, and —OCH (CH₃)₂.

59. The process of claim 48 in which the base is a carbonate or bicarbonate salt.

60. The process of claim 49 in which a reducing metal is added to the polymerization reaction.

61. The process of claim 60 in which the reducing metal is chosen from the group consisting of lithium, sodium, potassium, magnesium, calcium, and zinc.

62. A film or coating prepared from a composition of claim 1.

63. An electronic device comprising a composition of claim 1.

64. A multi-layer electroluminescent device comprising at least one organic layer, at least one of which is an electroluminescent organic layr, arranged between an anode material and a cathode material, at least one of the anode or cathode is transparent or semitransparent, that emits visible light under an applied voltage, wherein at least one of the organic layers comprises the composition of claim 1.

65. A device according to claim 64 wherein a layer containing a conductive polymer is disposed at least between one electrode and the electroluminescent organic layer such that the layer containing a conductive polymer is adjacent to said electrode.

66. A polymer light-emitting device according to claim 64 wherein an insulating layer having a thickness of 4 nm or less is disposed at least between one electrode and the light-emitting layer such that the insulating layer is adjacent to said electrode.

67. A device according to claim 64 wherein an electron-transporting layer is disposed between the cathode and the light-emitting layer such that the electron-transporting layer is adjacent to said light-emitting layer.

68. A device according to claim 64 wherein a hole-transporting layer is disposed between the anode and the light-emitting layer such that the hole-transporting layer is adjacent to said light-emitting layer.

69. A device according to claim 64 wherein an electron-transporting layer is disposed between the cathode and the light-emitting layer such that the electron-transporting layer is adjacent to said light-emitting layer, and a hole-transporting layer is disposed between the anode and the light-emitting layer such that the hole-transporting layer is adjacent to said light-emitting layer.

70. A device according to claim 64 wherein a hole-blocking layer is disposed between the cathode and the light-emitting layer such that the hole-blocking layer is adjacent to said light-emitting layer.

71. A device according to claim 64 wherein an electron-blocking layer is disposed between the anode and the light-emitting layer such that the electron-blocking layer is adjacent to said light-emitting layer.

72. A device according to claim 71 wherein a hole-blocking layer is disposed between the cathode and the light-emitting layer such that the hole-blocking layer is adjacent to said light-emitting layer, and an electron-blocking layer is disposed between the anode and the light-emitting layer such that the electron-blocking layer is adjacent to said light-emitting layer.

73. A device according to claim 64 wherein the electroluminescent organic layer emits polarized light.

74. A liquid crystalline display using a device of claim 64 as a back light and using no additional polarizers to polarize the light entering the liquid crystalline layer.

75. A flat light source using any of the devices of claims 63 or 64.

76. A segment display using any of the devices of claims 63 or 64.

77. A dot-matrix display using any of the devices of claims 63 or 64.

78. A liquid crystal display using any of the devices of claims 63 or 64 as a back light.

79. An organic field effect transistor comprising a composition of claim 1.

80. An organic field effect transistor device containing a semiconductor layer wherein the semiconductor layer comprises a composition of claim 1.

81. A photovoltaic device comprising an electroactive layer comprising a composition of claim 1.

82. A photodetector device comprising an electroactive layer comprising a composition of claim 1.

83. An electrical switching device comprising a composition of claim 1.

84. An optoelectronic device comprising a composition of claim 1.

85. An organic thin film transistor device comprising a composition of claim 1.

86. The composition of claim 1 where the peak emitted electroluminescent light is at least 0.08 eV lower than any peak emitted electroluminescent light in the same composition devoid of the luminescent group.

87. The composition of claim 1 where the peak emitted electroluminescent light is at least 0.1 eV lower than any peak emitted electroluminescent light in the same composition devoid of the luminescent group.

88. A film or coating prepared from a composition of claim 1.

89. A composition of claim 1 having general structure selected from the group consisting of: 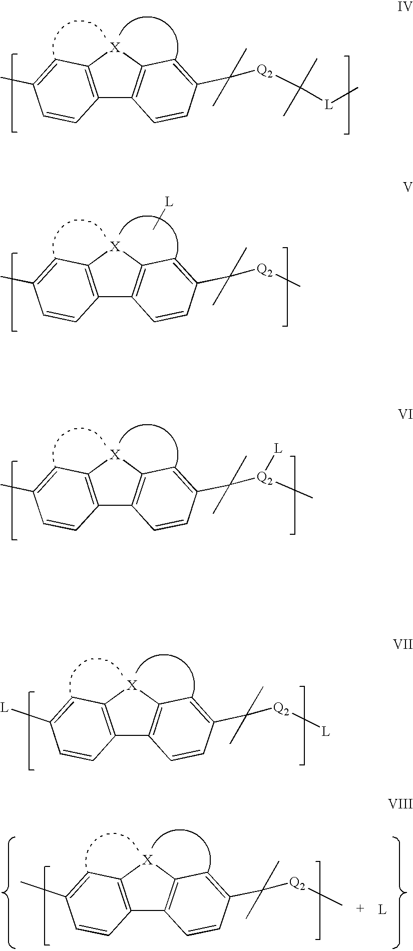
where X is selected from the group consisting of: 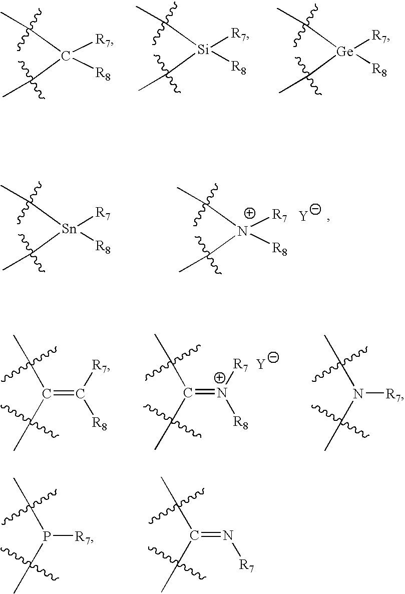
wherein R₁-R₈ are independently chosen from the group consisting of hydrogen, halogen, alkyl, substituted alkyl, aryl, substituted aryl, heteroaryl, substituted heteroaryl, —CN, —CHO, —CORₐ, —CRₐ═NR_{b}, —ORₐ, —SRₐ, —SO₂Rₐ, —PORₐR_{b}, —PO₃Rₐ, —OCORₐ, —CO₂Rₐ, —NRₐR_{b}, —N═CRₐR_{b}, —NRₐCOR_{b}, and —CONRₐR_{b} in which Rₐ and R_{b} are independently chosen from the group consisting of H, alkyl, substituted alkyl, aryl, substituted aryl, heteroaryl, and substituted heteroaryl;
adjacent R groups may or may not form a ring structure;
R₇ and R₈ (if present) taken together may or may not form a ring structure;
any R₁-R₈ may or may not form ring structures with adjacent repeat units in the polymer;
any Rₐ and R_{b} (if present) taken together may or may not form one or more ring structures;
Y⁻ is any mono-valent anionic atom or group;
and either (1) R₇ forms a ring system with R₆ or (2) R₇ forms a ring system with R₆ and R₈ forms a ring system with R₁ wherein the two ring systems may or may not share more than one atom;
the solid semicircle represents a bridging linkage;
the dotted semicircle represents an optional bridging linkage;
Q₂ is nil or any conjugated repeat unit; and
L is any luminescent compound, group, or unit.

90. A composition of claim 89 where the visible electroluminescent emission spectrum of model polymer (MBB-/-Q₂) devoid of L and having structure: 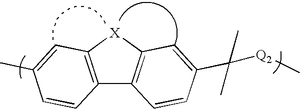
differs from the original polymer comprising L, in that the major emission band of (MBB-/-Q₂) is absent or reduced (quenched) by at least 80% in the emission spectrum of the original polymer composition comprising L,
and where X, Q₂, and the bridges represented by solid and dotted semicircles are as defined in claim 90, and are the same in the model polymer and original polymer.

91. The composition of claim 1 where a model compound Ph-MBB-Ph has higher energy emission than a model compound Ph-L-Ph, where Ph is phenyl, Ph-MBB-Ph is given by the structure:

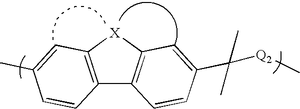

92. The composition of claim 91 where the visible emission peaks of Ph-MBB-Ph and Ph-L-Ph are separated by 0.1 eV or more, and where X and the bridges represented by solid and dotted semicircles are as defined in claim 89.

93. A polymer composition having a luminescence peak of P nm, comprising multiply bridged biphenylene repeat units and at least one second repeat unit, wherein 1) the corresponding multiply bridged biphenylene homopolymer has a fluorescence peak of Q nm, where P is greater than Q, and if more than one type of multiply bridged biphenylene unit is present, each of the corresponding multiply bridged biphenylene homopolymers will have a fluorescence peak of shorter wavelength than P nm.

94. The composition of claim 92 where P is greater than Q+10 nm.

95. The composition of claim 92 where P is greater than Q+25 nm.

96. An electroluminescent composition comprising a polymer comprising multiply bridged biphenylene repeat units and a luminescent group where the maximum intensity in the visible electroluminescence spectrum occurs at an energy at least 0.6 eV lower than the maximum intensity in the visible electroluminescence spectrum of the same composition devoid of the luminescent group.
